(19) United States
(12) Patent Application Publication
(10) Pub. No.: US 2026/0023320 A1
(43) Pub. Date: Jan. 22, 2026

(54) RESIST COMPOSITION AND METHOD FOR PRODUCING RESIST PATTERN

(71) Applicant: SUMITOMO CHEMICAL COMPANY, LIMITED, Tokyo (JP)

(72) Inventors: Michihisa TOYA, Osaka (JP); Masako Sugihara, Osaka (JP)

(73) Assignee: SUMITOMO CHEMICAL COMPANY, LIMITED, Tokyo (JP)

(21) Appl. No.: 19/266,939

(22) Filed: Jul. 11, 2025

(30) Foreign Application Priority Data
Jul. 16, 2024 (JP) 2024-113260

(51) Int. Cl. G03F 7/004; G03F 7/16; G03F 7/38

(52) U.S. Cl. CPC G03F 7/0045; G03F 7/168; G03F 7/38

(57) ABSTRACT

A resist composition that allows production of a resist pattern having excellent resolution, a favorable shape, and resistance to cracking includes resin (A) containing a structural unit having an acid labile group, and acid generator (B) represented by formula (b1). The resin (A) contains: resin (A1): a resin containing a structural unit represented by formula (a2-2) and a structural unit represented by formula (a1-1), but not containing a structural unit represented by formula (a1-2) or a structural unit represented by formula (a2-1); and resin (A2): a resin containing a structural unit represented by formula (a1-1) and a structural unit represented by formula (a2-1), but not containing a structural unit represented by formula (a1-2):

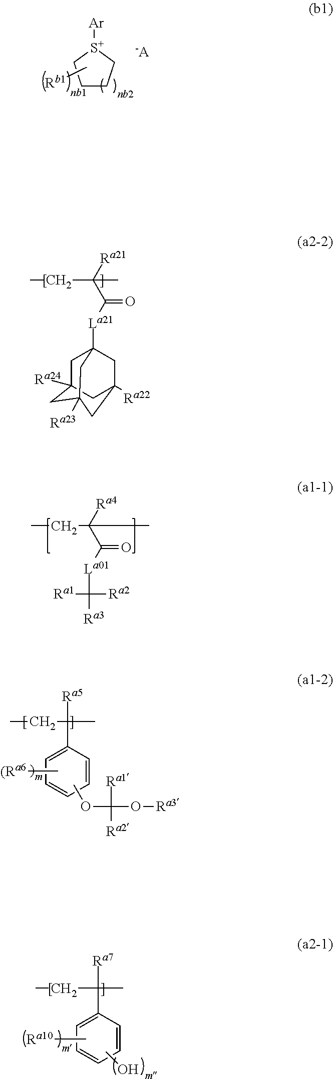

### CROSS REFERENCE TO RELATED APPLICATION

This application claims priority under 35 U.S.C. § 119(b) to Japanese Patent Application No. 2024-113260, filed on Jul. 16, 2024, the disclosure of which is incorporated herein by reference in its entirety.

### TECHNICAL FIELD

The present invention relates to a resist composition and a method for producing a resist pattern.

### BACKGROUND ART

Patent Literature 1 discloses a resist composition that includes a resin in which the phenolic hydroxy group of polyhydroxystyrene is protected and a resin that includes an acid labile group but does not have an aromatic hydrocarbon group.

### CITATION LIST

### Patent Literature

Patent Literature 1: Japanese Patent Laid-Open No. 2014-21470

### SUMMARY OF INVENTION

### Problems to be Solved by Invention

As disclosed in Patent Literature 1, when a thick-film resist pattern with 5 μm or more was fabricated using a resist composition including a resin having a structural unit represented by formula (a2-2) and a structural unit represented by formula (a1-1), but not including a structural unit represented by formula (a1-2) or a structural unit represented by formula (a2-1), and a resin having a structural unit represented by formula (a2-1) and a structural unit represented by formula (a1-2), but not including a structural unit represented by formula (a1-1), and having a triphenylsulfonium cation as an acid generator, the resolution after development was insufficient, and resist residues were sometimes generated.

Thus, an object of the present invention is to provide a resist composition capable of forming a resist pattern with excellent resolution.

### Means to Solve the Problems

The present invention includes the following inventions:
[1]A resist composition comprising:
   resin (A) including a structural unit having an acid labile group and acid generator (B) represented by formula (b1), wherein
   the resin (A) is a resist composition including resin (A1) and resin (A2),
   the resin (A1) is resin including a structural unit represented by formula (a1-1) and a structural unit represented by formula (a2-2), but not including a structural unit represented by formula (a1-2) or a structural unit represented by formula (a2-1),
   the resin (A2) is resin including a structural unit represented by formula (a1-1) and a structural unit represented by formula (a2-1), but not including a structural unit represented by formula (a1-2),

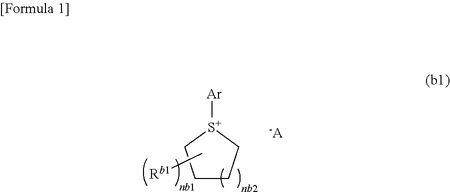

wherein
R^{b1} represents a hydroxy group or a hydrocarbon group having 1 to 12 carbon atoms, and —CH₂— included in the hydrocarbon group is optionally replaced with —O— or —CO—,
Ar represents an aromatic hydrocarbon group having 6 to 18 carbon atoms and optionally having a substituent, —CH₂— included in a ring constituting a cation is optionally replaced with —O—, —S—, or —CO—,
nb1 represents an integer of 0 to 3 and when nb1 is 2 or more, a plurality of R^{b1}s are the same or different,
nb2 represents an integer of 1 to 3,
A⁻ represents a sulfonate anion,

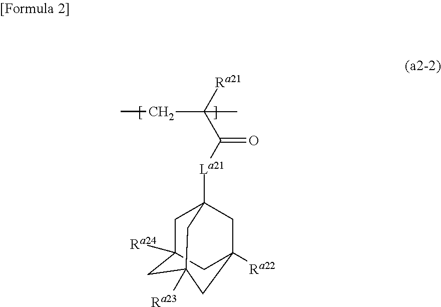

wherein
R^{a21} represents a hydrogen atom or a methyl group,
L^{a21} represents —O— or *—O—(CH₂)ₖ₀₁—CO—O—, k01 represents an integer of 1 to 7, and * represents a bonding site with —CO—,
R^{a22} represents a hydroxy group or a carboxy group,
R^{a23} and R^{a24} each independently represent a hydrogen atom, a methyl group, a hydroxy group, or a carboxy group,

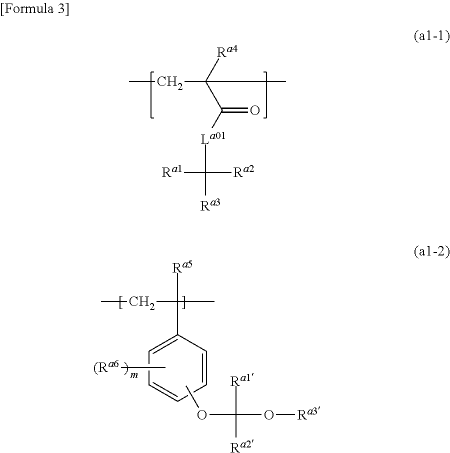

Wherein
R^{a1}, R^{a2}, and R^{a3} each independently represent an alkyl group having 1 to 8 carbon atoms or an alicyclic hydrocarbon group having 3 to 20 carbon atoms, or Rai and R^{a2} are bonded to each other to form a ring having 3 to 20 carbon atoms together with carbon atoms to which they are bonded, and R^{a3} represents an alkyl group having 1 to 8 carbon atoms or an alicyclic hydrocarbon group having 3 to 20 carbon atoms,
R^{a1′} and R^{a2′} each independently represent a hydrogen atom or a hydrocarbon group having 1 to 20 carbon atoms, R^{a3′} represents a hydrocarbon group having 1 to 20 carbon atoms, or R^{a1′} represents a hydrogen atom or a hydrocarbon group having 1 to 20 carbon atoms, and R^{a2′} and R^{a3′} are bonded to each other to form a heterocycle having 3 to 20 carbon atoms together with carbon atoms and oxygen atoms to which they are bonded, the —CH₂— included in the hydrocarbon group having 1 to 20 carbon atoms and the heterocycle having 3 to 20 carbon atoms is optionally replaced with —O— or —S—,
L^{a01} represents —O— or *—O—(CH₂)ₖ₀₁—CO—O—, where k01 represents an integer of 1 to 7, and * represents a bonding site with —CO—,
R^{a4} and R^{a5} each independently represent a hydrogen atom or a methyl group,
R^{a6} represents an alkyl group having 1 to 6 carbon atoms or an alkoxy group having 1 to 6 carbon atoms,
m represents an integer of 0 to 4, and when m is 2 or more, a plurality of R^{a6}s are the same or different from each other,

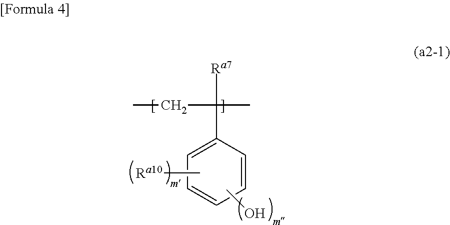

wherein
R^{a7} represents a hydrogen atom or a methyl group,
R^{a10} represents a hydroxy group, a carboxy group, an alkyl group having 1 to 6 carbon atoms, or an alkoxy group having 1 to 6 carbon atoms,
m′ represents an integer of 0 to 4, and when m′ is 2 or more, a plurality of R^{a10}s are the same or different from each other,
m″ represents an integer of 1 to 4, and with the proviso that a total of m′ and m″ is 5 or less.
[2] The resist composition according to [1], wherein A⁻ in formula (b1) is represented by formula (bA),

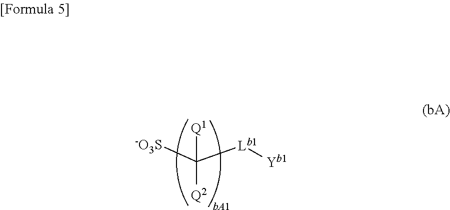

wherein
Q¹ and Q² each independently represent a hydrogen atom, a fluorine atom, an alkyl group having 1 to 6 carbon atoms, or a perfluoroalkyl group having 1 to 6 carbon atoms,
L^{b1} represents a saturated hydrocarbon group having 1 to 24 carbon atoms and optionally having a substituent, and —CH₂— included in the saturated hydrocarbon group is optionally replaced with —O— or —CO—,
Y^{b1} represents an aliphatic hydrocarbon group having 1 to 18 carbon atoms and optionally having a substituent, or an aromatic hydrocarbon group having 6 to 24 carbon atoms and optionally having a substituent, —CH₂— included in the aliphatic hydrocarbon group is optionally replaced with —O—, —S—, —CO—, or —SO₂—,
bA1 represents an integer of 1 to 6, and when bA1 is 2 or more, a plurality of groups in parentheses are the same or different from each other.
[3] The resist composition according to [1] or [2], wherein a content of the resin (A1) is 40% by mass or more and 80% by mass or less with respect to a total amount of the resins.
[4]A method for producing a resist pattern, comprising:
   (1) a step of applying the resist composition according to any one of [1] to [3] onto a substrate;
   (2) a step of drying the applied resist composition to form a composition layer;
   (3) a step of exposing the composition layer;
   (4) a step of heating the composition layer after exposure; and
   (5) a step of developing the composition layer after heating.

### Effects of Invention

Using the resist composition of the present invention allows a resist pattern with excellent resolution to be formed with high precision. In addition, using the resist composition of the present invention allows a pattern with excellent shape and crack resistance to be formed.

### BRIEF DESCRIPTION OF THE DRAWINGS

FIG. 1(a) to FIG. 1(c) are each a schematic view showing a pattern shape of a trench pattern of a resist pattern.

### EMBODIMENTS FOR CARRYING OUT INVENTION

Unless otherwise specified, in the description of the structural formula of a compound in the present specification, an “aliphatic hydrocarbon group” means a straight-chain or branched aliphatic hydrocarbon group, and an “alicyclic hydrocarbon group” means a group in which a number of hydrogen atoms corresponding to the valence has been removed from an alicyclic hydrocarbon ring. An “aromatic hydrocarbon group” also includes a group in which a hydrocarbon group is bonded to an aromatic ring. When stereoisomers exist, all stereoisomers are included.

In the present specification, “(meth)acrylic acid” means “at least one of acrylic acid and methacrylic acid”, and “(meth)acrylate” means “at least one of acrylate and methacrylate”.

Among the groups described in the present specification, those that can have both a straight-chain structure and a branched structure are interpreted as including both. When —CH₂— included in a hydrocarbon group or the like is replaced by —O— or the like, the same example applies to each group, and the number of carbon atoms before replacement is defined as the number of carbon atoms in the hydrocarbon group or the like. The “combined group” means a group in which two or more of the exemplified groups are bonded together, and the valence of these groups may be changed appropriately depending on the bonding form. The “derived from” or “induced from” refer to a polymerizable C═C bond included in the molecule that is polymerized to a —C—C— group (single bond). The number of carbon atoms in a substituent is not included in the number of carbon atoms in the substituted group.

In the present specification, the “solid content of a resist composition” means the sum of the components excluding the solvent (E), which will be described later, from the total amount of the resist composition.

### 1. Resist Composition

The resist composition of the present invention contains a resin including a structural unit having an acid labile group (hereinafter may be referred to as “resin (A)”) and an acid generator represented by formula (b1) (hereinafter may be referred to as “acid generator (B)”).

The resin (A) includes a resin including a structural unit represented by formula (a1-1) and a structural unit represented by formula (a2-2), but not including a structural unit represented by formula (a1-2) or a structural unit represented by formula (a2-1) (hereinafter may be referred to as “resin (A1)”), and a resin including a structural unit represented by formula (a1-1) and a structural unit represented by formula (a2-1), but not including a structural unit represented by formula (a1-2) (hereinafter may be referred to as “resin (A2)”).

In addition to the resin (A1), the resin (A2) and the acid generator (B), the resist composition of the present invention preferably further includes a quencher (hereinafter may be referred to as “quencher (C)”) and/or a solvent (hereinafter may be referred to as “solvent (E)”).

### <Resin (A)>

The resin (A) includes a structural unit having an acid labile group (hereinafter may be referred to as “structural unit (a1)”).

An acid labile group means a group including a group (may be referred to as a leaving group) that can be eliminated by contact with an acid (for example, trifluoromethanesulfonic acid). When the resin (A) comes into contact with an acid, the leaving group is eliminated from the acid labile group, forming a hydrophilic group (for example, a hydroxy group (phenolic hydroxy group and the like) or a carboxy group). The solubility of the resin (A) in an alkaline aqueous solution increases by contact with an acid. That is, it is preferable that the resin (A) be insoluble or poorly soluble in an alkaline aqueous solution before contact with an acid, and become soluble in an alkaline aqueous solution after contact with an acid. Examples of the acid that eliminates the leaving group included in the acid labile group include a carboxylic acid and a sulfonic acid. In the composition of the present invention, carboxylic acid compounds, sulfonic acid compounds, and the like produced by irradiating (exposing) the acid generator (B) described later with light in the photolithography process are exemplified.

The resin (A) may include, in addition to a structural unit having an acid labile group, structural units known in the art, such as a structural unit not having an acid labile group (hereinafter may be referred to as “structural unit (a2)”), as long as it has the above-described properties.

Examples of the acid labile group include a group represented by formula (10) and a group represented by formula (20).

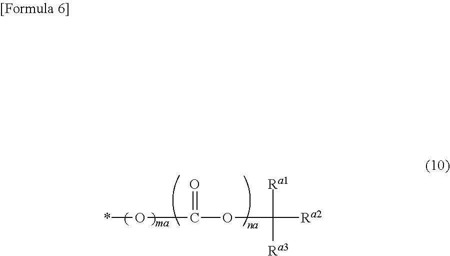

[In formula (10), R^{a1}, R^{a2}, and R^{a3} each independently represent an alkyl group having 1 to 8 carbon atoms, an alicyclic hydrocarbon group having 3 to 20 carbon atoms, or a combination thereof, or R^{a1} and R^{a2} are bonded to each other to form a ring having 3 to 20 carbon atoms together with the carbon atom to which they are bonded, and R^{a3} represents an alkyl group having 1 to 8 carbon atoms, an alicyclic hydrocarbon group having 3 to 20 carbon atoms, or a combination thereof. ma and na each independently represent 0 or 1, and at least one of ma and na represents 1. * represents a bonding site]

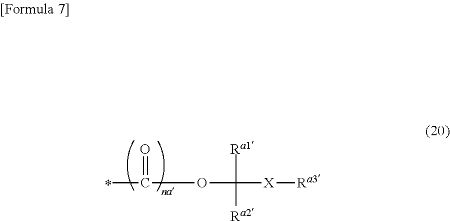

[In formula (20), R^{a1′} and R^{a2′} each independently represent a hydrogen atom or a hydrocarbon group having 1 to 20 carbon atoms, and R^{a3′} represents a hydrocarbon group having 1 to 20 carbon atoms, alternatively, R^{a1′} represents a hydrogen atom or a hydrocarbon group having 1 to 20 carbon atoms, and R^{a2′} and R^{a3′} are bonded to each other to form a heterocycle having 3 to 20 carbon atoms together with the carbon atom and X to which they are bonded. The methylene group included in the hydrocarbon group having 1 to 20 carbon atoms and the heterocycle having 3 to 20 carbon atoms is optionally replaced with an oxygen atom or a sulfur atom. X represents an oxygen atom or a sulfur atom. na′ represents 0 or 1. * represents a bond.]

The alkyl groups R^{a1} to R^{a3} having 1 to 8 carbon atoms and represented by formula (10) may be either linear or branched, and examples thereof include methyl, ethyl, propyl, butyl, pentyl, hexyl, heptyl, and octyl groups. The alkyl groups R^{a1} to R^{a3} having 1 to 8 carbon atoms preferably have 1 to 6 carbon atoms, and more preferably have 1 to 4 carbon atoms. The alicyclic hydrocarbon groups R^{a1} to R^{a3} having 3 to 20 carbon atoms may be either monocyclic or polycyclic. Examples of the monocyclic alicyclic hydrocarbon group include a cycloalkyl group such as a cyclopentyl group, a cyclohexyl group, a cycloheptyl group, and a cyclooctyl group. Examples of the polycyclic alicyclic hydrocarbon group include a decahydronaphthyl group, an adamantly group, a norbornyl group, and the following group (* represents a bond).

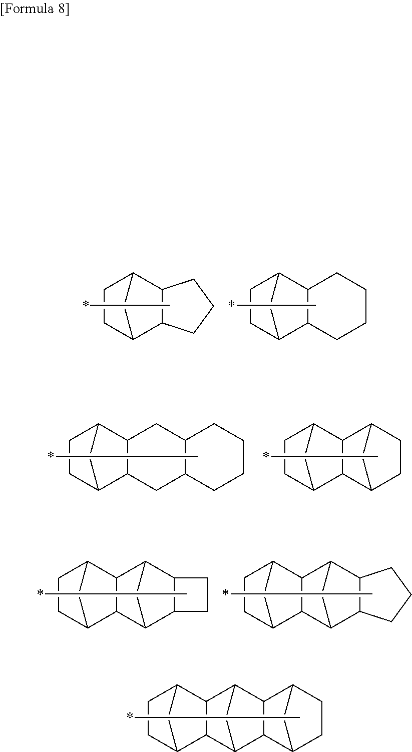

The alicyclic hydrocarbon group having 3 to 20 carbon atoms for R^{a1} to R^{a3} preferably has 3 to 18 carbon atoms, more preferably has 3 to 16 carbon atoms, and further preferably has 3 to 12 carbon atoms.

Examples of the group combining an alkyl group with an alicyclic hydrocarbon group include an alkylcycloalkyl group or a cycloalkylalkyl group such as a methylcyclohexyl group, a dimethylcyclohexyl group, a methylnorbornyl group, a cyclohexylmethyl group, an isobornyl group, an adamantylmethyl group, an adamantyldimethyl group, and a norbornylethyl group.

When R^{a1} and R^{a2} are bonded to each other to form a ring having 3 to 20 carbon atoms together with the carbon atom to which they are bonded, examples of —C(R^{a1}) (R^{a2}) (R^{a3}) include the groups below. The ring having 3 to 20 carbon atoms preferably has 3 to 18 carbon atoms, more preferably 3 to 16 carbon atoms, and further preferably 3 to 12 carbon atoms. * represents a bonding site with —O—.

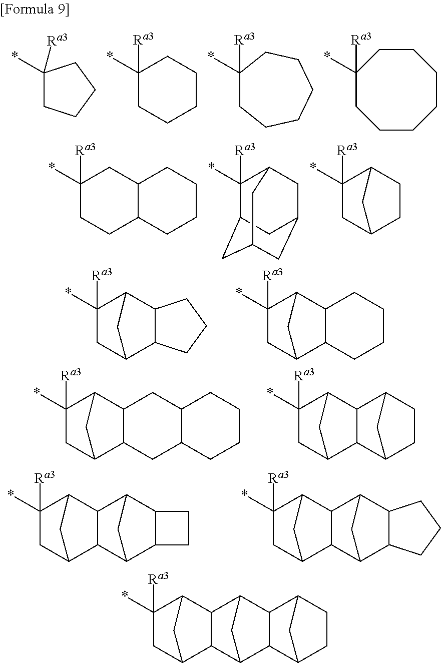

R^{a1} is preferably an alkyl group having 1 to 6 carbon atoms or an alicyclic hydrocarbon group having 3 to 18 carbon atoms, or is bonded to R^{a2} to form a ring having 3 to 18 carbon atoms together with the carbon atom to which they are bonded, and more preferably an alkyl group having 1 to 4 carbon atoms or an alicyclic hydrocarbon group having 3 to 12 carbon atoms, or is bonded to R^{a2} to form a ring having 3 to 12 carbon atoms together with the carbon atom to which they are bonded.

R^{a2} is preferably an alkyl group having 1 to 6 carbon atoms or an alicyclic hydrocarbon group having 3 to 18 carbon atoms, or is bonded to R^{a1} to form a ring having 3 to 18 carbon atoms together with the carbon atom to which they are bonded, and more preferably an alkyl group having 1 to 4 carbon atoms or an alicyclic hydrocarbon group having 3 to 12 carbon atoms, or is bonded to R^{a1} to form a ring having 3 to 12 carbon atoms together with the carbon atom to which they are bonded.

R^{a3} is preferably an alkyl group having 1 to 6 carbon atoms or an alicyclic hydrocarbon group having 3 to 18 carbon atoms, and more preferably an alkyl group having 1 to 4 carbon atoms or an alicyclic hydrocarbon group having 3 to 12 carbon atoms.

ma is preferably 0. na is preferably 1.

Examples of the group represented by formula (10) include: a group in which Ral, R^{a2}, and R^{a3} each independently represent an alkyl group having 1 to 3 carbon atoms (preferably a tert-butoxycarbonyl group); a group in which R^{a1} and R^{a2} are each independently an alkyl group having 1 to 3 carbon atoms, and R^{a3} is a cyclopentyl group or a cyclohexyl group; and a group in which R^{a1} and R^{a2} are bonded to each other to form a cyclopentane ring or a cyclohexane ring together with the carbon atom to which they are bonded, and R^{a3} is an alkyl group having 1 to 3 carbon atoms.

Specific examples of the group represented by formula (10) include the following groups.

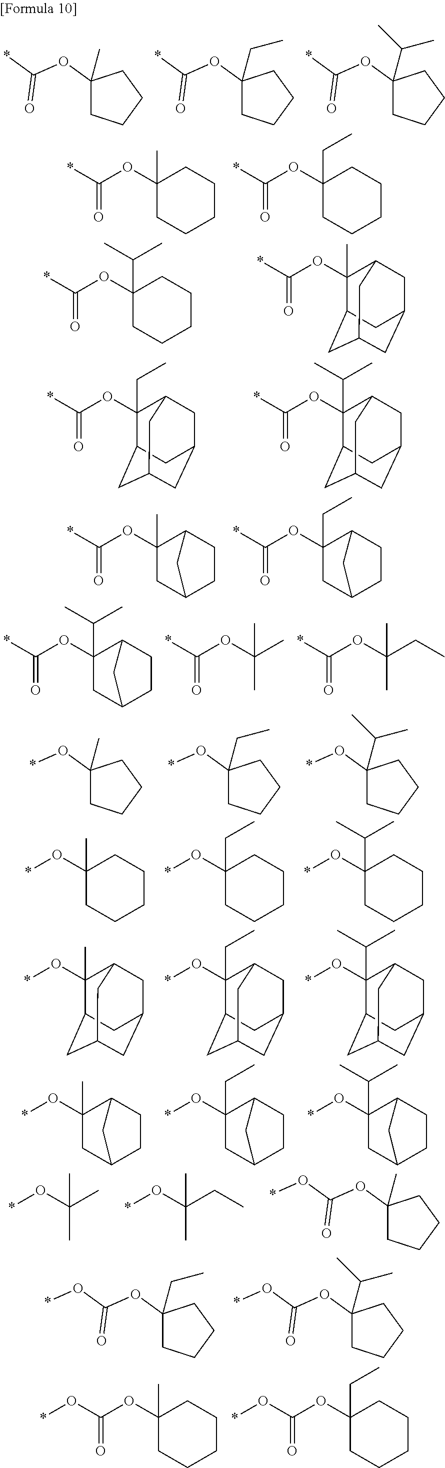

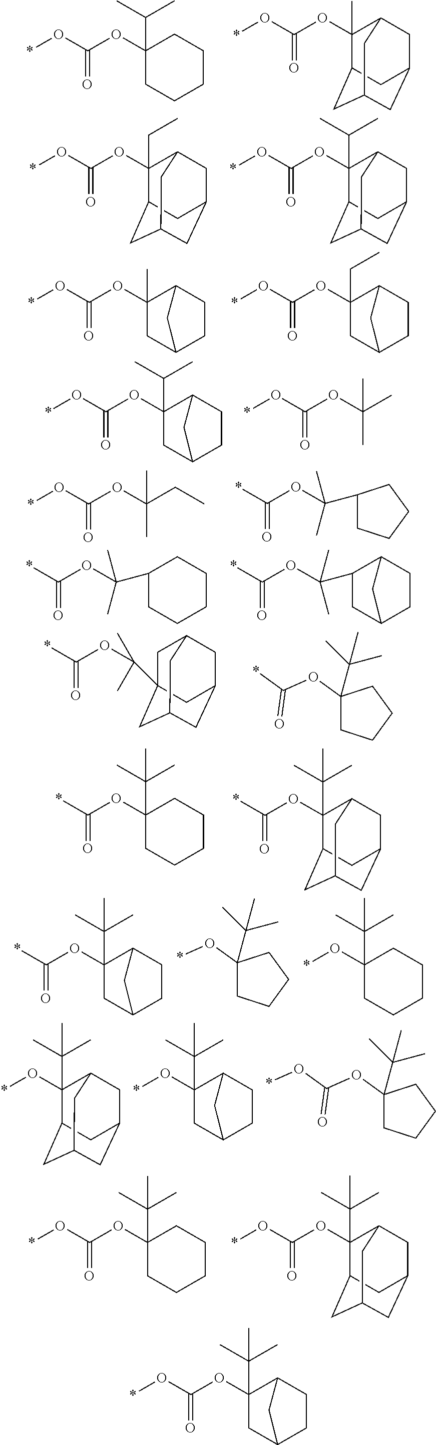

The hydrocarbon groups having 1 to 20 carbon atoms for R^{a1′} to R^{a3′} in the group represented by formula (20) include a chain hydrocarbon group having 1 to 20 carbon atoms (an alkyl group, an alkenyl group, an alkynyl group, and the like), an alicyclic hydrocarbon group having 3 to 20 carbon atoms, an aromatic hydrocarbon group having 6 to 20 carbon atoms, as well as a group having 4 to 20 carbon atoms, the group being a combinations thereof.

Examples of the alkyl group having 1 to 20 carbon atoms include a methyl group, an ethyl group, a propyl group, a butyl group, a pentyl group, a hexyl group, a heptyl group, an octyl group, a decyl group, and a dodecyl group.

Examples of the alkenyl group having 2 to 20 carbon atoms include an ethenyl group, a propenyl group, an isopropenyl group, a butenyl group, an isobutenyl group, a tert-butenyl group, a pentenyl group, a hexenyl group, a heptenyl group, an octenyl group, an isooctenyl group, and a nonenyl group.

Examples of the alkynyl group having 2 to 20 carbon atoms include an ethynyl group, a propynyl group, an isopropynyl group, a butynyl group, an isobutynyl group, a tert-butynyl group, a pentynyl group, a hexynyl group, an octynyl group, and a nonynyl group.

The chain hydrocarbon group having 1 to 20 carbon atoms preferably has 1 to 18 carbon atoms, more preferably has 1 to 16 carbon atoms, still more preferably has 1 to 12 carbon atoms, even more preferably has 1 to 8 carbon atoms, and yet even more preferably has 1 to 6 carbon atoms.

Examples of the alicyclic hydrocarbon group having 3 to 20 carbon atoms include a monocyclic alicyclic hydrocarbon group such as a cycloalkyl group including a cyclopentyl group, a cyclohexyl group, a cycloheptyl group, and a cyclooctyl group; and a polycyclic alicyclic hydrocarbon group such as a decahydronaphthyl group, an adamantyl group, and a norbornyl group. The alicyclic hydrocarbon group having 3 to 20 carbon atoms preferably has 3 to 18 carbon atoms, more preferably has 3 to 16 carbon atoms, and still more preferably has 3 to 12 carbon atoms.

Examples of the aromatic hydrocarbon group having 6 to 20 carbon atoms include an aryl group such as a phenyl group, a naphthyl group, an anthryl group, a biphenyl group, and a phenanthryl group. The aromatic hydrocarbon group may further have a substituent, and examples of the substituent include an aryloxy group having 6 to 10 carbon atoms. The aromatic hydrocarbon group having 6 to 20 carbon atoms preferably has 6 to 18 carbon atoms, more preferably has 6 to 14 carbon atoms, and still more preferably has 6 to 10 carbon atoms.

Among the groups having 4 to 20 carbon atoms in which the above groups are combined, examples of the group in which an alkyl group and an alicyclic hydrocarbon group are combined (group having 4 to 20 carbon atoms) include a methylcyclohexyl group, a dimethylcyclohexyl group, a methylnorbornyl group, an isobornyl group, a 2-alkyladamantan-2-yl group, and a 1-(adamantan-1-yl)alkane-1-yl group.

Examples of the group in which an alkyl group and an aromatic hydrocarbon group are combined (group having 7 to 20 carbon atoms) include an aromatic hydrocarbon group having an aralkyl group or an alkyl group, and specific examples thereof include a benzyl group, a phenethyl group, a phenylpropyl group, a trityl group, a naphthylmethyl group, a naphthylethyl group, a p-methylphenyl group, a p-tert-butylphenyl group, a tolyl group, a xylyl group, a cumenyl group, a mesityl group, a 2,6-diethylphenyl group, and a 2-methyl-6-ethylphenyl group.

Examples of the group in which an alicyclic hydrocarbon group and an aromatic hydrocarbon group are combined (group having 9 to 20 carbon atoms) include an aromatic hydrocarbon group having an alicyclic hydrocarbon group and an alicyclic hydrocarbon group having an aromatic hydrocarbon group, and specific examples thereof include a p-cyclohexylphenyl group, a p-adamantylphenyl group, and a phenylcyclohexyl group.

When R^{a2′} and R^{a3′} are bonded to each other to form a heterocycle having 3 to 20 carbon atoms together with the carbon atom to which they are bonded and X, examples of —C(R^{a1′}) (R^{a2′})—X—R^{a3′} include the following groups. The heterocycle having 3 to 20 carbon atoms preferably has 3 to 18 carbon atoms, more preferably 3 to 16 carbon atoms, and further preferably 3 to 12 carbon atoms. * represents the binding site.

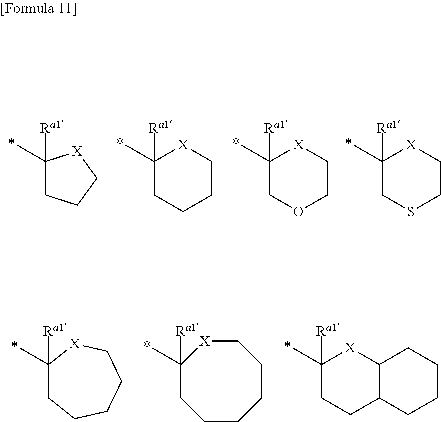

R^{a1′} is preferably a hydrogen atom or a hydrocarbon group having 1 to 18 carbon atoms, more preferably a hydrogen atom or a hydrocarbon group having 1 to 12 carbon atoms, and still more preferably a hydrogen atom.

R^{a2′} is preferably a hydrogen atom or a hydrocarbon group having 1 to 18 carbon atoms, or is bonded to R^{a3′} to form a heterocycle having 3 to 18 carbon atoms together with the carbon atom and X to which they are bonded, more preferably a hydrogen atom or a hydrocarbon group having 1 to 12 carbon atoms, or is bonded to R^{a3′} to form a heterocycle having 3 to 12 carbon atoms together with the carbon atom and X to which they are bonded, still more preferably a hydrocarbon group having 1 to 12 carbon atoms, and even more preferably a methyl group or an ethyl group.

R^{a3′} is preferably a hydrocarbon group having 1 to 18 carbon atoms, or is bonded to R^{a2′} to form a heterocycle having 3 to 18 carbon atoms together with the carbon atom and X to which they are bonded, and more preferably a hydrocarbon group having 1 to 12 carbon atoms, or is bonded to R^{a2′} to form a heterocycle having 3 to 12 carbon atoms together with the carbon atom and X to which they are bonded.

The hydrocarbon groups include an alkyl group having 1 to 18 carbon atoms, an alicyclic hydrocarbon group having 3 to 18 carbon atoms, an aromatic hydrocarbon group having 6 to 18 carbon atoms, or the group having 4 to 18 carbon atoms, being a combination thereof. These groups can be optionally selected from those listed above.

X is preferably an oxygen atom.

na′ is preferably 0.

Specific examples of the group represented by formula (20) include the following groups.

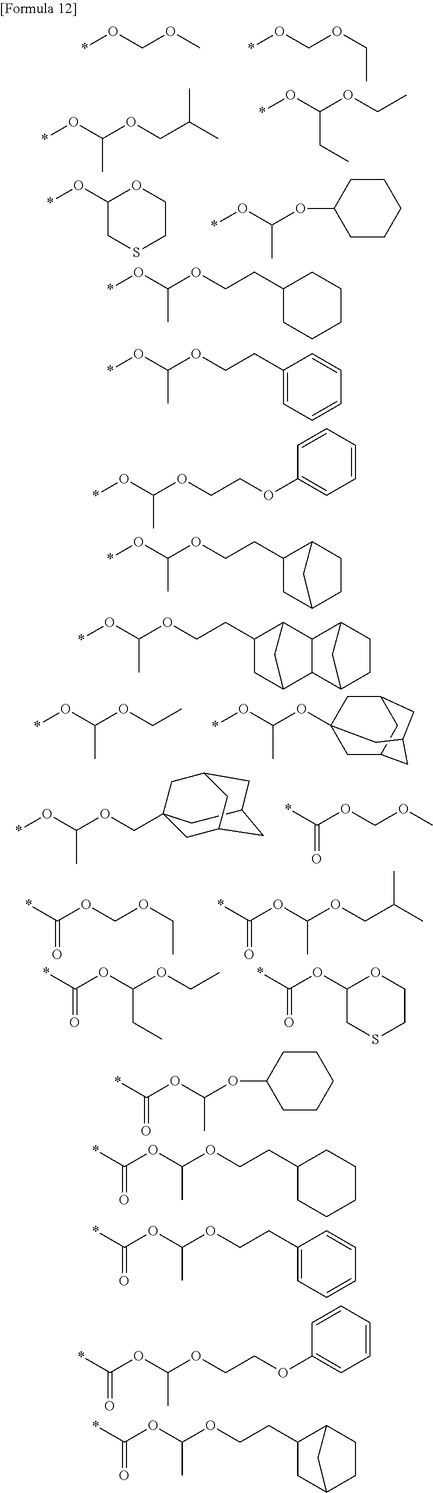

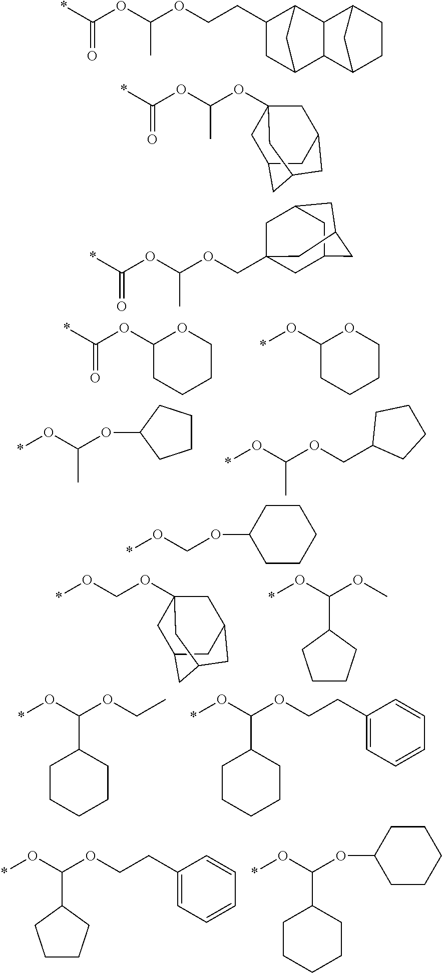

Specific examples of the group represented by formula (10) include the group represented by formula (1) and the group represented by formula (1′).

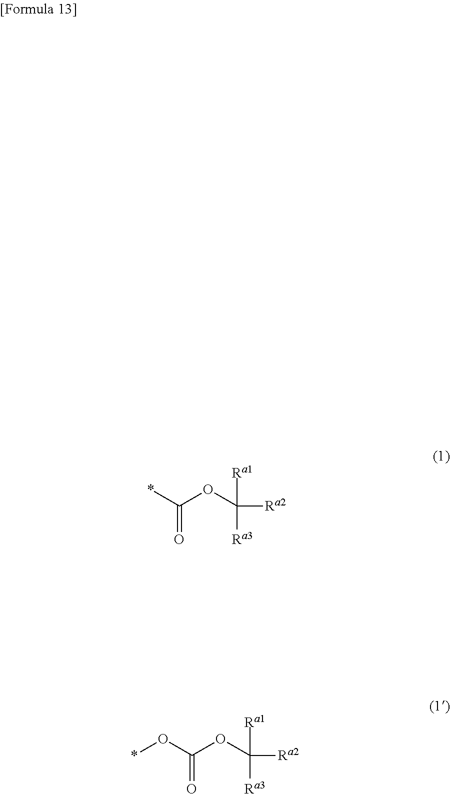

[In formula (1) and formula (1′), all symbols have the same meanings as defined above]

Specific examples of the group represented by formula (20) include a group represented by formula (2) and a group represented by formula (2′).

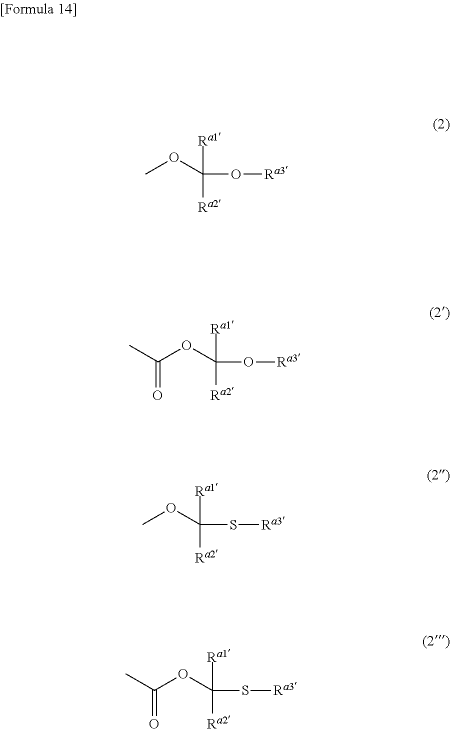

[In formula (2), formula (2′), formula (2″), and formula (2′″), all symbols have the same meanings as defined above]

<Structural Unit (a1)>

The resin (A) including structural unit (a1) can be produced, for example, by polymerizing a monomer component including an ethylenically unsaturated compound that leads to structural unit (a1). As the acid labile group included in structural unit (a1), a group represented by the above formula (10) and/or a group represented by formula (20) is preferable.

The resin (A) may have only one type of structural unit (a1), or may have a plurality of types.

As structural unit (a1), a structural unit represented by formula (a1-1) (hereinafter may be referred to as “structural unit (a1-1)”) and a structural unit represented by formula (a1-2) (hereinafter may be referred to as “structural unit (a1-2)”) are preferable.

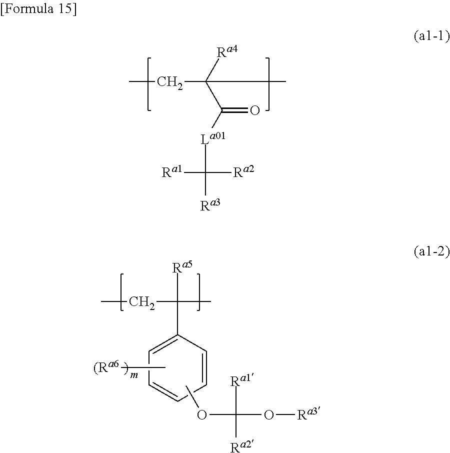

[In formula (a1-1) and formula (a1-2), R^{a1}, R^{a2}, and R^{a3} each independently represent an alkyl group having 1 to 8 carbon atoms or an alicyclic hydrocarbon group having 3 to 20 carbon atoms, or R^{a1} and R^{a2} are bonded to each other to form a ring having 3 to 20 carbon atoms together with the carbon atom to which they are bonded, and R^{a3} represents an alkyl group having 1 to 8 carbon atoms or an alicyclic hydrocarbon group having 3 to 20 carbon atoms.

R^{a1′} and R^{a2′} each independently represent a hydrogen atom or a hydrocarbon group having 1 to 20 carbon atoms, and R^{a3′} represents a hydrocarbon group having 1 to 20 carbon atoms, or R^{a1′} represents a hydrogen atom or a hydrocarbon group having 1 to 20 carbon atoms, and R^{a2′} and R^{a3′} are bonded to each other to form a heterocycle having 3 to 20 carbon atoms together with the carbon atom and oxygen atom to which they are bonded. The methylene group included in the hydrocarbon group having 1 to 20 carbon atoms and the heterocycle having 3 to 20 carbon atoms are optionally replaced with an oxygen atom or a sulfur atom.

L^{a01} represents —O— or *—O—(CH₂)ₖ₀₁—CO—O—, where k01 represents an integer from 1 to 7, and * represents the bonding site with —CO—.

R^{a4} and R^{a5} each independently represent a hydrogen atom or a methyl group.

R^{a6} represents an alkyl group having 1 to 6 carbon atoms or an alkoxy group having 1 to 6 carbon atoms.

m represents an integer of 0 to 4. When m is 2 or more, a plurality of R^{a6}s are the same or different from each other]

In formula (a1-1), R^{a4} is preferably a methyl group.

R^{a1} is preferably an alkyl group having 1 to 6 carbon atoms or an alicyclic hydrocarbon group having 3 to 18 carbon atoms, or is bonded to R^{a2} to form a ring having 3 to 18 carbon atoms together with the carbon atom to which they are bonded, and more preferably an alkyl group having 1 to 4 carbon atoms or an alicyclic hydrocarbon group having 3 to 12 carbon atoms, or is bonded to R^{a2} to form a ring having 3 to 12 carbon atoms together with the carbon atom to which they are bonded.

R^{a2} is preferably an alkyl group having 1 to 6 carbon atoms or an alicyclic hydrocarbon group having 3 to 18 carbon atoms, or is bonded to R^{a1} to form a ring having 3 to 18 carbon atoms together with the carbon atom to which they are bonded, and more preferably an alkyl group having 1 to 4 carbon atoms or an alicyclic hydrocarbon group having 3 to 12 carbon atoms, or is bonded to R^{a1} to form a ring having 3 to 12 carbon atoms together with the carbon atom to which they are bonded.

R^{a3} is preferably an alkyl group having 1 to 6 carbon atoms or an alicyclic hydrocarbon group having 3 to 18 carbon atoms, and more preferably an alkyl group having 1 to 4 carbon atoms or an alicyclic hydrocarbon group having 3 to 12 carbon atoms.

L^{a01} is preferably an oxygen atom or *—O—(CH₂)ₖ₀₁—CO—O— (wherein k₀₁ is preferably an integer of 1 to 4, more preferably 1), and is more preferably an oxygen atom.

In formula (a1-2), R^{a5} is preferably a hydrogen atom.

R^{a1′} is preferably a hydrogen atom or a hydrocarbon group having 1 to 18 carbon atoms, more preferably a hydrogen atom or a hydrocarbon group having 1 to 12 carbon atoms, and further preferably a hydrogen atom.

R^{a2′} is preferably a hydrogen atom or a hydrocarbon group having 1 to 18 carbon atoms, or is bonded to R^{a3′} to form a heterocycle having 3 to 18 carbon atoms together with the carbon atom and oxygen atom to which they are bonded, more preferably a hydrogen atom or a hydrocarbon group having 1 to 12 carbon atoms, or is bonded to R^{a3′} to form a heterocycle having 3 to 12 carbon atoms together with the carbon atom and oxygen atom to which they are bonded, further preferably a hydrocarbon group having 1 to 12 carbon atoms, and further preferably a methyl group or an ethyl group.

R^{a3′} is preferably a hydrocarbon group having 1 to 18 carbon atoms, or is bonded to R^{a2′} to form a heterocycle having 3 to 18 carbon atoms together with the carbon atom and oxygen atom to which they are bonded, and more preferably a hydrocarbon group having 1 to 12 carbon atoms, or is bonded to R^{a2′} to form a heterocycle having 3 to 12 carbon atoms together with the carbon atom and oxygen atom to which they are bonded.

Examples of the above hydrocarbon group include an alkyl group having 1 to 18 carbon atoms, an alicyclic hydrocarbon group having 3 to 18 carbon atoms, an aromatic hydrocarbon group having 6 to 18 carbon atoms, or a combination of these groups and having 4 to 18 carbon atoms. These groups can be arbitrarily selected from those listed above. The hydrocarbon group is preferably an alkyl group having 1 to 18 carbon atoms, an alicyclic hydrocarbon group having 3 to 18 carbon atoms, or an aralkyl group having 7 to 18 carbon atoms. The alkyl group and the alicyclic hydrocarbon group are preferably unsubstituted.

When the aromatic hydrocarbon group has a substituent, the substituent is preferably an aryloxy group having 6 to 10 carbon atoms.

Examples of the alkyl group having 1 to 6 carbon atoms for R^{a6} include a methyl group, an ethyl group, a propyl group, a butyl group, a pentyl group, and a hexyl group. The alkyl group having 1 to 6 carbon atoms is preferably an alkyl group having 1 to 4 carbon atoms, and more preferably an alkyl group having 1 to 3 carbon atoms. Examples of the alkoxy group having 1 to 6 carbon atoms for R^{a6} include a methoxy group, an ethoxy group, a propoxy group, a butoxy group, a pentyloxy group, and a hexyloxy group. The alkoxy group having 1 to 6 carbon atoms is preferably an alkoxy group having 1 to 4 carbon atoms, and more preferably an alkoxy group having 1 to 3 carbon atoms.

R^{a6} is preferably an alkyl group having 1 to 4 carbon atoms or an alkoxy group having 1 to 4 carbon atoms, more preferably an alkyl group having 1 to 3 carbon atoms or an alkoxy group having 1 to 3 carbon atoms, still more preferably a methyl group, an ethyl group, a methoxy group, or an ethoxy group, and even more preferably a methyl group or a methoxy group.

m is preferably 0 to 2, more preferably 0 or 1, and further preferably 0.

In formula (a1-2), the group represented by —O—C(R^{a1′}) (R^{a2′})—O—R^{a3′} is preferably bonded to the 3- or 4-position of the benzene ring (the m-position or p-position with respect to the main chain bonded to the benzene ring), and more preferably bonded to the 4-position (p-position) of the benzene ring.

Examples of structural unit (a1-1) include structural units represented by any of formulas (a1-1-1) to (a1-1-18). Specific examples of structural unit (a1-1) include structural units in which the hydrogen atoms or methyl groups corresponding to R^{a4} and R^{a5} in the following structural units are replaced with methyl groups or hydrogen atoms.

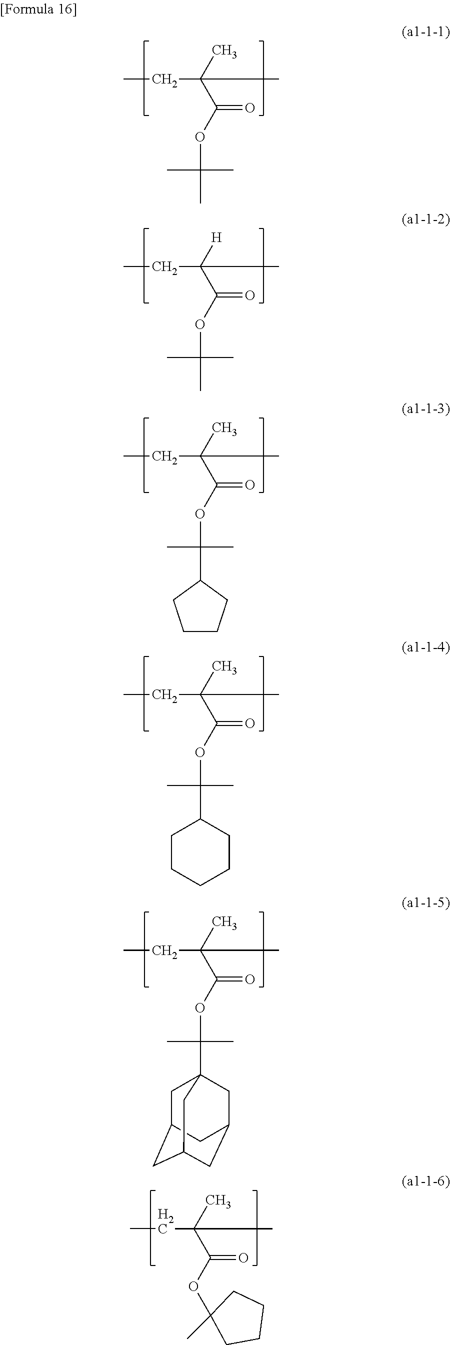

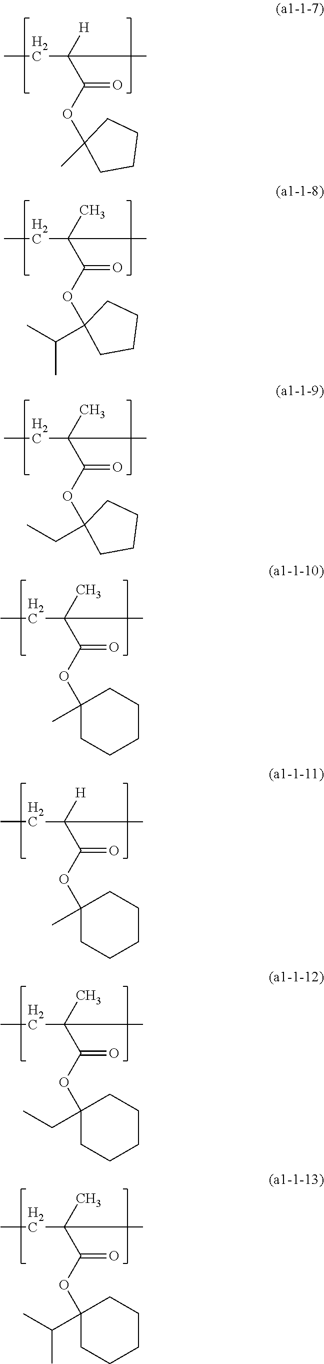

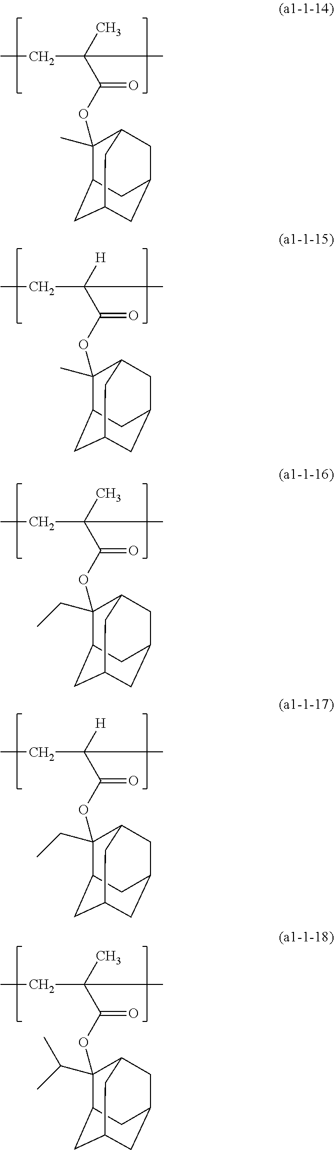

Examples of structural unit (a1-2) include structural units represented by any of formulas (a1-2-1) to (a1-2-22). In the following structural units, specific examples of structural unit (a1-2) include structural units in which the hydrogen atom corresponding to R^{a5} is replaced with a methyl group.

Structural unit (a1-2) is preferably a structural unit represented by formula (a1-2-2), (a1-2-3), (a1-2-4), (a1-2-9), or (a1-2-14), and more preferably a structural unit represented by formula (a1-2-2), (a1-2-3), (a1-2-4), or (a1-2-9).

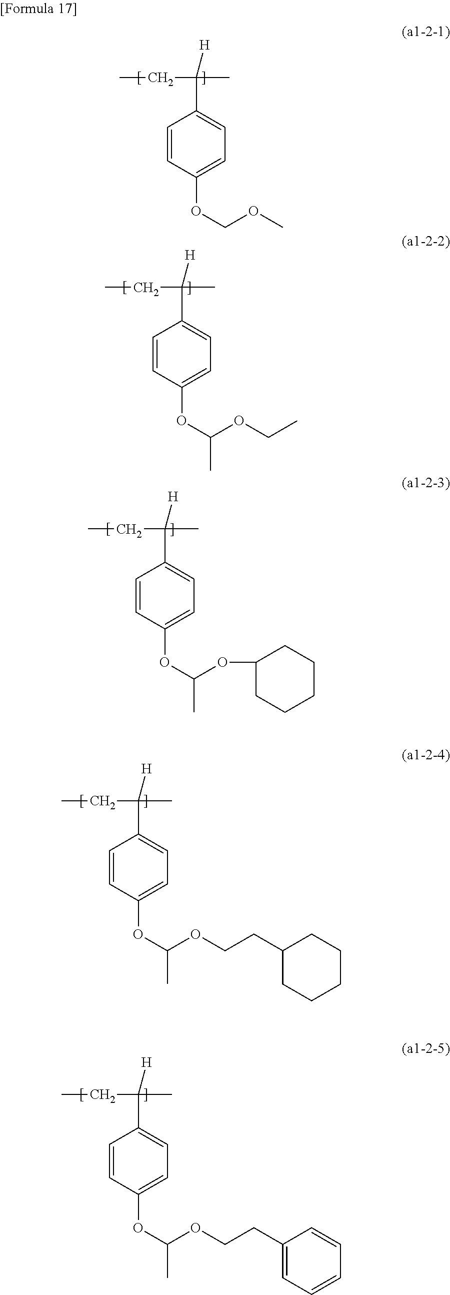

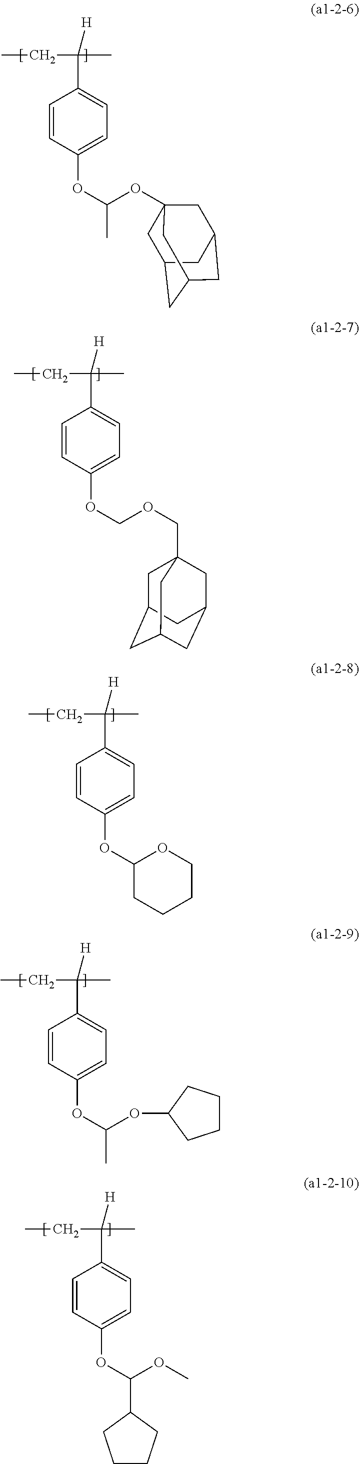

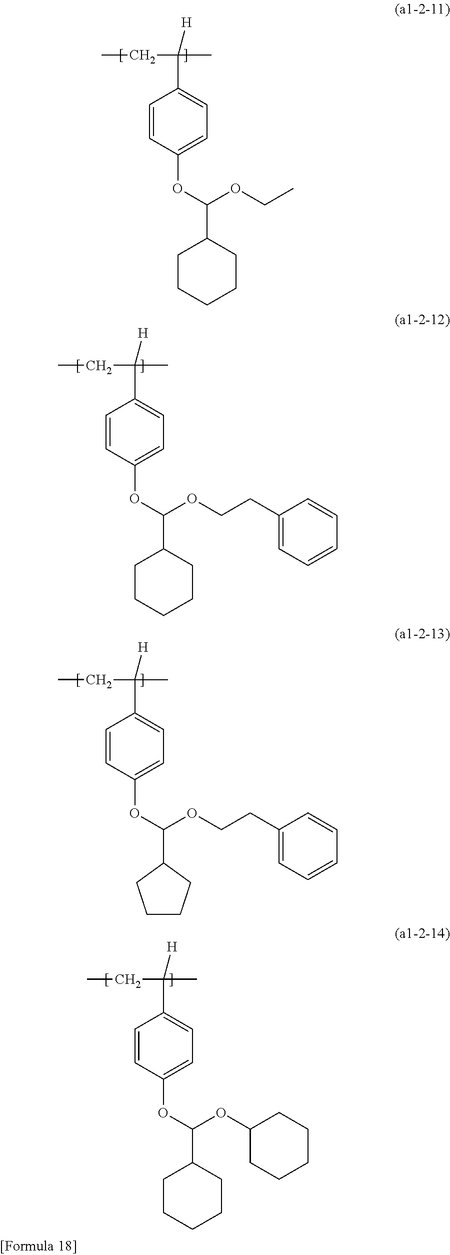

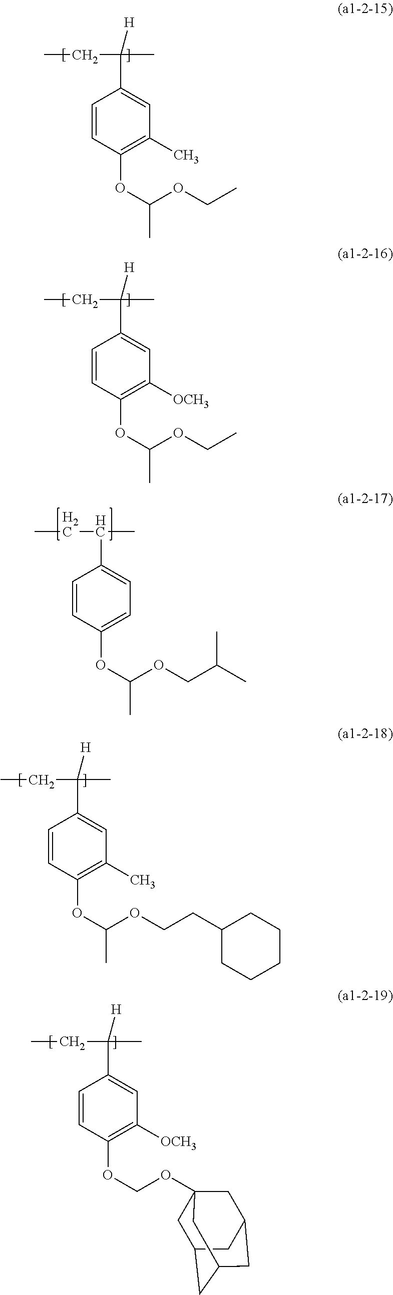

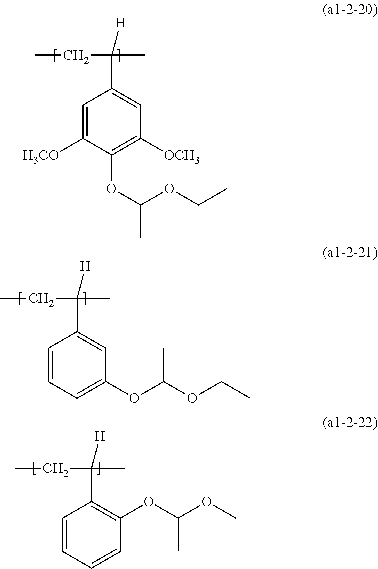

The resin (A) includes a resin (A) and a resin (A2).

The resin (A1) and the resin (A2) include structural unit (a1-1) as structural unit (a1) having an acid labile group, but do not include structural unit (a1-2).

The total content of structural units (a1) having an acid labile group in the resin (A1) is preferably 5 to 99 mol %, more preferably 10 to 95 mol %, further preferably 15 to 90 mol %, still more preferably 20 to 85 mol %, and further more preferably 25 to 80 mol %, with respect to the total amount of the structural units of the resin (A1).

The total content of structural units (a1) having an acid labile group in the resin (A2) is preferably 3 to 80 mol %, more preferably 5 to 60 mol %, further preferably 10 to 55 mol %, still more preferably 15 to 50 mol %, and further more preferably 20 to 45 mol %, with respect to all structural units in the resin (A1).

In this case, not including structural unit (a1-2) means that no monomer that derives structural unit (a1-2) is used when synthesizing the resin (A1) and the resin (A2), and specifically, the total content is 1 mol % or less, preferably 0.5 mol % or less, and more preferably 0 mol %, with respect to all structural units in the resin (A1) or the resin (A2).

<Structural Unit (s) that does not have Acid Labile Group>

The resin (A) may include structural unit (a1) that has an acid labile group and, as necessary, structural unit (s) that does not have an acid labile group (hereinafter may be referred to as “structural unit (s)”).

Structural unit (s) preferably has a hydroxy group, a carboxy group, or a lactone ring. Using a resin including a structural unit that has a hydroxy group or a carboxy group and no acid labile group (hereinafter may be referred to as “structural unit (a2)”) and/or a structural unit that has a lactone ring and no acid labile group (hereinafter may be referred to as “structural unit (a3)”) in the resist composition of the present invention, the resolution of the resist pattern and adhesion to the substrate can be improved.

The resin (A) may include only one type of structural unit (s) that does not have an acid labile group, or may include a plurality of types.

<Structural Unit (a2)>

Structural unit (a2) has an alcoholic hydroxy group, a phenolic hydroxy group, or a carboxy group.

As structural unit (a2), a structural unit represented by formula (a2-1) (hereinafter may be referred to as “structural unit (a2-1)”) and a structural unit represented by formula (a2-2) (hereinafter may be referred to as “structural unit (a2-2)”) are preferable.

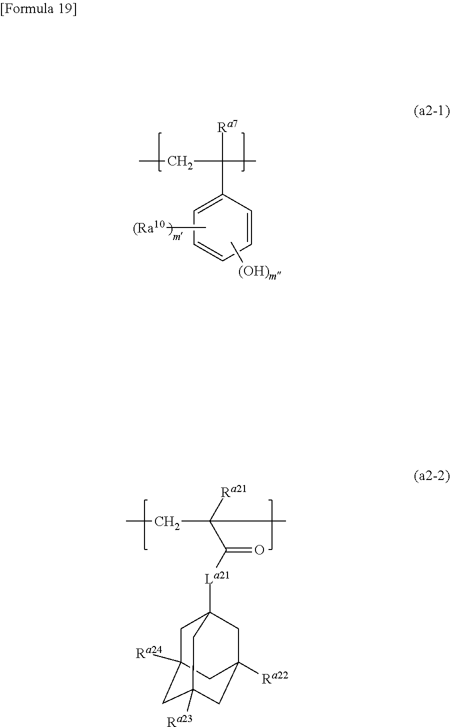

[In formula (a2-1) and formula (a2-2),

R^{a7} and R^{a21} each independently represent a hydrogen atom or a methyl group.

R^{a10} represents a hydroxy group, a carboxy group, an alkyl group having 1 to 6 carbon atoms, or an alkoxy group having 1 to 6 carbon atoms.

m′ represents an integer of 0 to 4. When m′ is 2 or more, a plurality of R^{a10}s are the same or different from each other.

m″ represents an integer of 1 to 4.

With the proviso that the sum of m′ and m″ is 5 or less.

L^{a21} represents —O— or *—O—(CH₂)ₖ₀₁—CO—O—, where k01 represents an integer of 1 to 7, and * represents the bonding site with —CO—.

R^{a22} represents a hydroxy group or a carboxy group.

R^{a23} and R^{a24} represent a hydrogen atom, a methyl group, a hydroxy group, or a carboxy group.]

Examples of the alkyl group having 1 to 6 carbon atoms represented by R^{a10} include a methyl group, an ethyl group, a propyl group, a butyl group, a pentyl group, and a hexyl group. The alkyl group having 1 to 6 carbon atoms preferably has 1 to 4 carbon atoms, and more preferably has 1 to 3 carbon atoms.

Examples of the alkoxy group having 1 to 6 carbon atoms represented by R^{a10} include a methoxy group, an ethoxy group, a propoxy group, a butoxy group, a pentyloxy group, and a hexyloxy group. The alkoxy group having 1 to 6 carbon atoms preferably has 1 to 4 carbon atoms, and more preferably has 1 to 3 carbon atoms.

L^{a21} is preferably an oxygen atom, —O—, or *—O—CH₂—CO—O—, and more preferably an oxygen atom.

R^{a7} is preferably a hydrogen atom.

R^{a21} is preferably a methyl group.

R^{a23} and R^{a24} are preferably a hydrogen atom or a hydroxy group.

Examples of structural unit (a2-1) include the following structural units. Among them, structural units represented by the formula (a2-1-1), the formula (a2-1-2), the formula (a2-1-3), or the formula (a2-1-4) are preferable. In addition, the monomer from which structural unit (a2-1) is derived is disclosed, for example, in Japanese Patent Laid-Open No. 2010-204634.

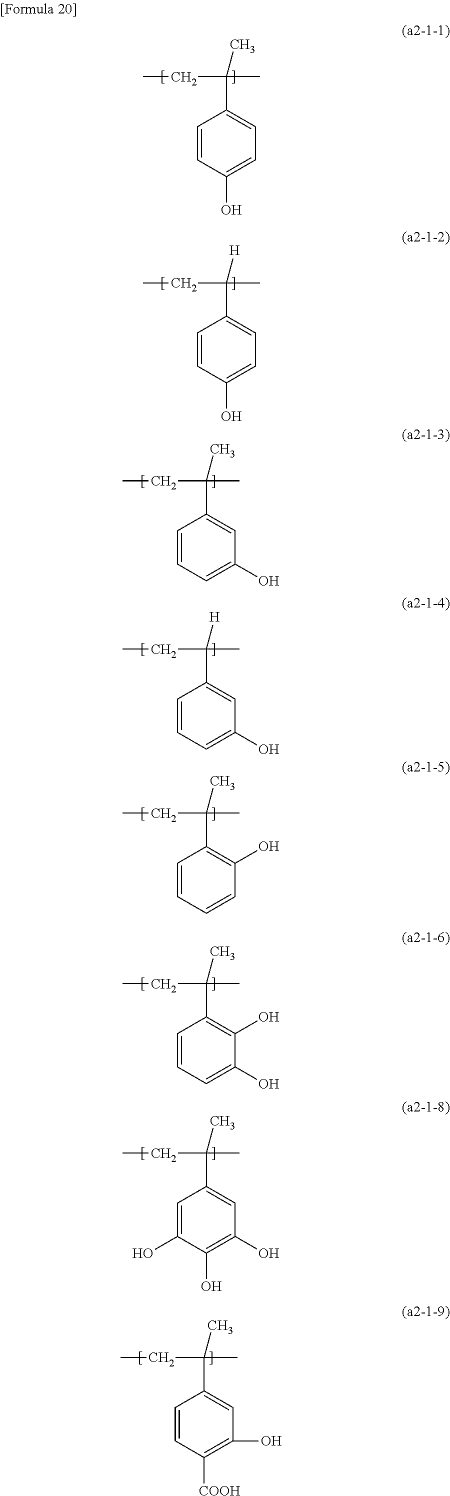

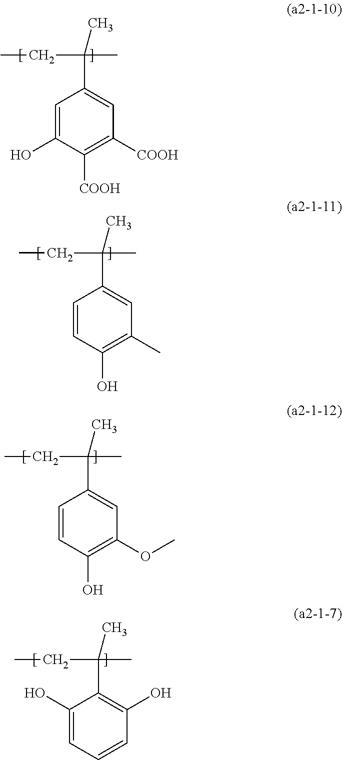

Examples of structural unit (a2-2) include a structural unit derived from a monomer disclosed in Japanese Patent Laid-Open No. 2010-204646. Among these, the structural unit represented by any one of formulas (a2-2-1) to (a2-2-9) is preferable.

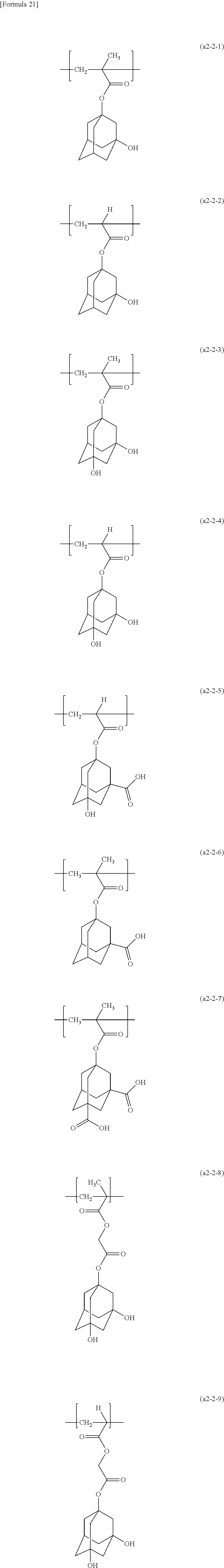

As structural unit (a2), structural unit (a2-1) is not included in the resin (A1) but is included in the resin (A2). The content of structural unit (a2-1) in the resin (A2) is preferably 5 to 99 mol %, more preferably 10 to 95 mol %, further preferably 15 to 90 mol %, still more preferably 20 to 85 mol %, and further more preferably 25 to 80 mol %, with respect to the total amount of the structural units of the resin (A2).

Structural unit (a2-2) may be included in the resin (A1) and may also be included in the resin (A2). The content of structural unit (a2-2) in the resin (A1) and the resin (A2) is preferably 1 to 50 mol %, more preferably 2 to 45 mol %, further preferably 3 to 40 mol %, still more preferably 4 to 35 mol %, and further more preferably 5 to 30 mol %, with respect to the total amount of each of the structural units.

<Structural Unit (a3)>

The lactone ring of structural unit (a3) may be a monocyclic ring such as a β-propiolactone ring, a γ-butyrolactone ring, or a δ-valeractone ring, or may be a condensed ring of a monocyclic lactone ring and another ring. Preferably, a γ-butyrolactone ring, an adamantane lactone ring, or a bridged ring including a γ-butyrolactone ring (for example, a structural unit represented by formula (a3-2)) is exemplified.

Structural unit (a3) is preferably a structural unit represented by formula (a3-1), formula (a3-2), formula (a3-3), or formula (a3-4). One of these may be contained singly, or two or more of these may be contained.

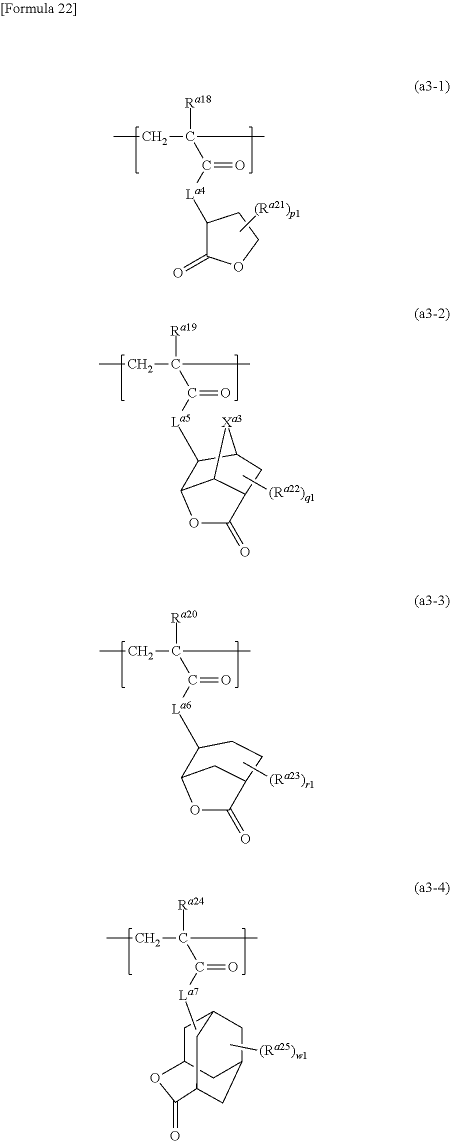

[In formula (a3-1), formula (a3-2), formula (a3-3), and formula (a3-4),

L^{a4}, L^{a5}, and L^{a6} each independently represent a group represented by —O— or *—O—(CH₂)ₖ₃—CO—O— (k3 represents an integer of 1 to 7).

L^{a7} represents —O—, *—O-L^{a8}-O—, *—O-L^{a8}-CO—O—, *—O-L^{a8}-CO—O-L^{a9}-CO—O—, or *—O-L^{a8}-O—CO-L^{a9}-O—.

L^{a8} and L^{a9} each independently represent an alkanediyl group having 1 to 6 carbon atoms.

* represents the bonding site with the carbonyl group.

R^{a18}, R^{a19}, R^{a20}, and R^{a24} each independently represent a hydrogen atom, a halogen atom, or an alkyl group having 1 to 6 carbon atoms and optionally having a halogen atom.

X^{a3} represents —CH₂— or an oxygen atom.

R^{a21} represents an aliphatic hydrocarbon group having 1 to 4 carbon atoms.

R^{a22}, R^{a23}, and R^{a25} each independently represent a carboxy group, a cyano group, or an aliphatic hydrocarbon group having 1 to 4 carbon atoms.

p1 represents an integer of 0 to 5.

q1 represents an integer of 0 to 3.

r1 represents an integer of 0 to 3.

w1 represents an integer of 0 to 8.

When p1, q1, r1, and/or w1 are 2 or more, a plurality of R^{a21}, R^{a22}, R^{a23} and/or R^{a25} are the same or different from each other.]

Examples of the aliphatic hydrocarbon groups in R^{a21}, R^{a22}, R^{a23}, and R^{a25} include alkyl groups such as a methyl group, an ethyl group, a propyl group, an isopropyl group, a butyl group, a sec-butyl group, and a tert-butyl group.

Examples of the halogen atoms in R^{a18}, R^{a19}, R^{a20}, and R^{a24} include a fluorine atom, a chlorine atom, a bromine atom, and an iodine atom.

Examples of the alkyl groups in R^{a18}, R^{a19}, R^{a20}, and R^{a24} include a methyl group, an ethyl group, a propyl group, an isopropyl group, a butyl group, a sec-butyl group, a tert-butyl group, a pentyl group, and a hexyl group, preferably an alkyl group having 1 to 4 carbon atoms, more preferably a methyl group or an ethyl group.

Examples of the alkyl group having a halogen atom in R^{a18}, R^{a19}, R^{a20}, and R^{a24} include a trifluoromethyl group, a perfluoroethyl group, a perfluoropropyl group, a perfluoroisopropyl group, a perfluorobutyl group, a perfluorosec-butyl group, a perfluorotert-butyl group, a perfluoropentyl group, a perfluorohexyl group, a trichloromethyl group, a tribromomethyl group, and a triiodomethyl group.

Examples of the alkanediyl group in L^{a8} and L^{a9} include a methylene group, an ethylene group, a propane-1,3-diyl group, a propane-1,2-diyl group, a butane-1,4-diyl group, a pentane-1,5-diyl group, a hexane-1,6-diyl group, a butane-1,3-diyl group, a 2-methylpropane-1,3-diyl group, a 2-methylpropane-1,2-diyl group, a pentane-1,4-diyl group, and a 2-methylbutane-1,4-diyl group.

In formulas (a3-1) to (a3-3), L^{a4} to L^{a6} each independently preferably represent —O— or *—O—(CH₂)ₖ₃—CO—O— where k3 is an integer of 1 to 4, more preferably —O— and *—O—CH₂—CO—O—, and further preferably an oxygen atom.

R^{a18} to R^{a21} preferably represent a methyl group.

R^{a22} and R^{a23} each independently preferably represent a carboxy group, a cyano group, or a methyl group.

p1, q1, and r1 each independently preferably represent an integer of 0 to 2, more preferably 0 or 1.

In formula (a3-4), R^{a24} preferably represents a hydrogen atom or an alkyl group having 1 to 4 carbon atoms, more preferably a hydrogen atom, a methyl group, or an ethyl group, and further preferably a hydrogen atom or a methyl group.

R^{a25} preferably represents a carboxy group, a cyano group, or a methyl group.

L^{a7} preferably represents —O— or *—O-L^{a8}-CO—O—, more preferably —O—, —O—CH₂—CO—O—, or —O—C₂H₄—CO—O—.

w1 preferably represents an integer of 0 to 2, more preferably 0 or 1.

In particular, as the structural unit represented by formula (a3-4), the structural unit represented by formula (a3-4)′ is preferable.

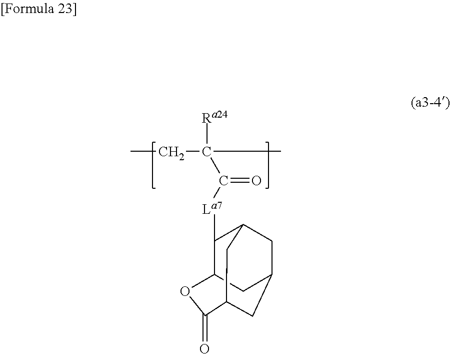

(In the formula, R^{a24} and L^{a7} have the same meanings as above)

Examples of structural unit (a3) include structural units derived from the monomers disclosed in Japanese Patent Laid-Open No. 2010-204646, Japanese Patent Laid-Open No. 2000-122294, and Japanese Patent Laid-Open No. 2012-41274. As structural unit (a3), structural units represented by any one of formulas (a3-1-1), (a3-1-2), (a3-2-1), (a3-2-2), (a3-3-1), (a3-3-2), and (a3-4-1) to (a3-4-12) as well as structural units in which the methyl groups corresponding to R^{a18}, R^{a19}, R^{a20}, and R^{a24} in the structural units (a3-1) to (a3-4) are replaced with hydrogen atoms are preferable.

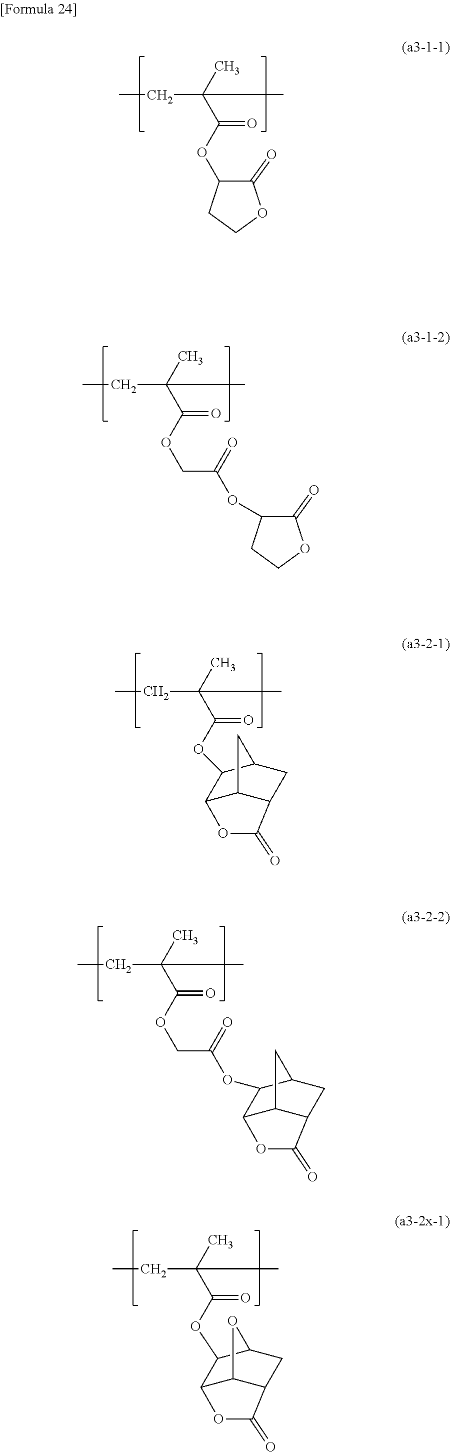

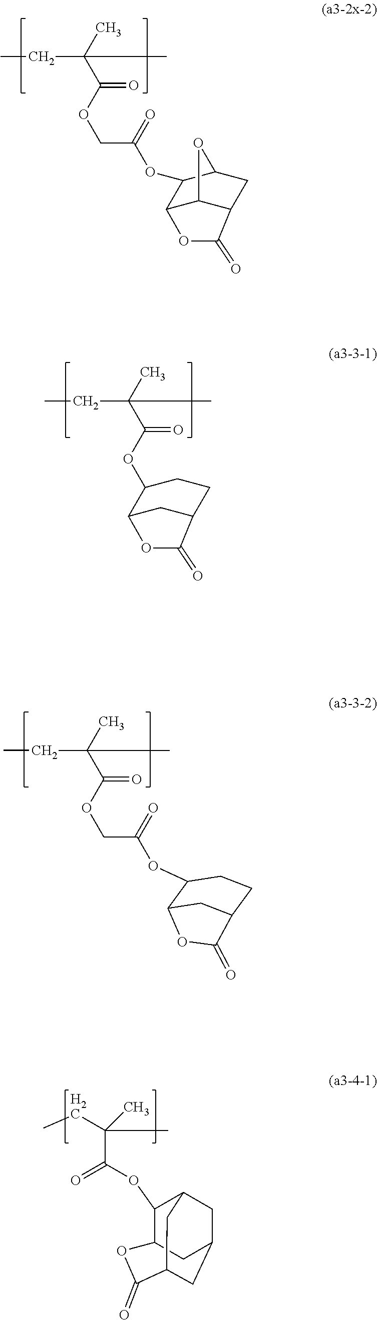

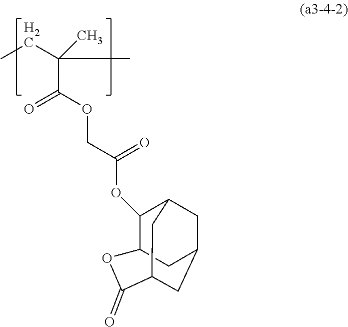

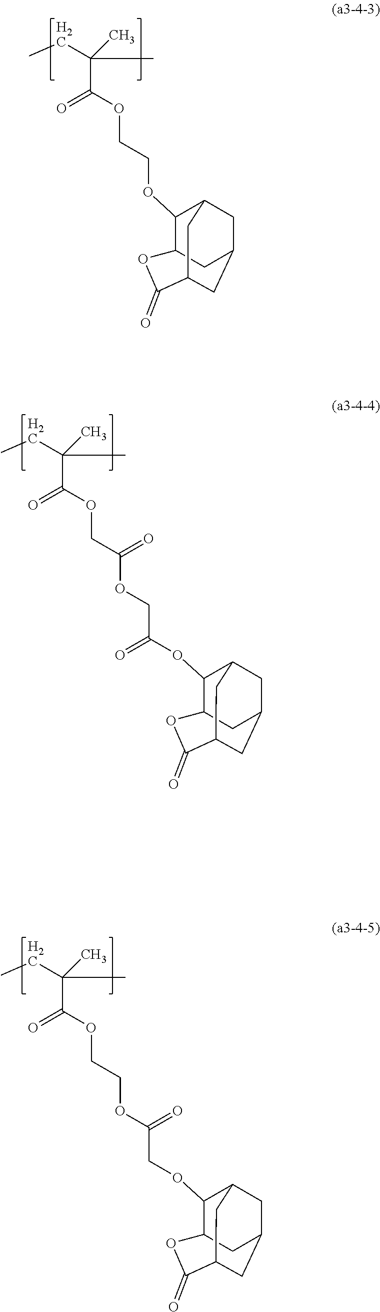

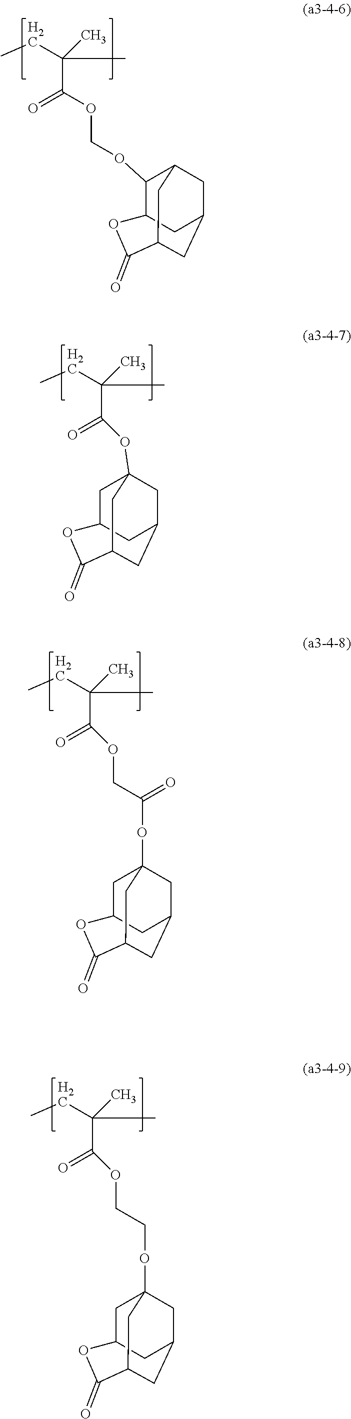

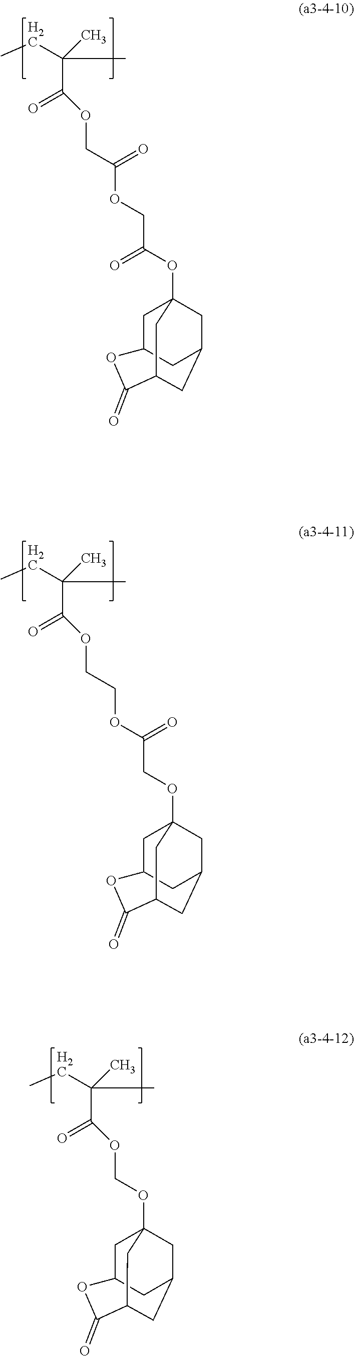

When the resin (A1) and the resin (A2) have structural unit (a3), the content of structural unit (a3) in the resin (A1) and the resin (A2) is preferably 5 to 70 mol %, more preferably 5 to 60 mol %, further preferably 5 to 50 mol %, and still more preferably 5 to 40 mol %, with respect to the total amount of each of the structural units.

<Structural Unit (a4)>

The resin (A) may have a structural unit other than the above one (hereinafter may be referred to as “structural unit (a4)”).

Examples of the monomer from which structural unit (a4) is derived include an acrylate having a non-leaving hydrocarbon group. Examples of the non-leaving hydrocarbon group include a group having a linear, branched, or cyclic hydrocarbon group.

Among these, structural unit (a4) is preferably a group having an alicyclic hydrocarbon group.

Examples of structural unit (a4) include a structural unit represented by formula (a4-1).

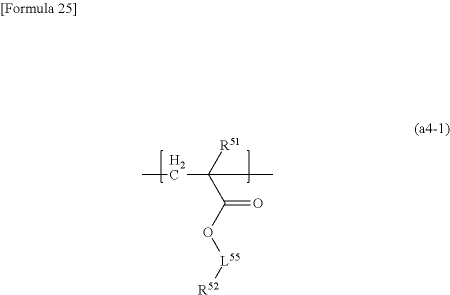

[In formula (a4-1),

R⁵¹ represents a hydrogen atom or a methyl group.

R⁵² represents a chain hydrocarbon group having 1 to 20 carbon atoms or an alicyclic hydrocarbon group having 3 to 18 carbon atoms, and a hydrogen atom included in the chain hydrocarbon group and the alicyclic hydrocarbon group are optionally replaced with an aliphatic hydrocarbon group having 1 to 8 carbon atoms.

L⁵⁵ represents a single bond or a divalent saturated hydrocarbon group having 1 to 18 carbon atoms, and —CH₂— included in the saturated hydrocarbon group is optionally replaced with —O— or —CO—]

Examples of the chain hydrocarbon group include a linear or branched alkyl group having 1 to 20 carbon atoms, such as those exemplified in R^{a1′} to R^{a3′} in formula (20).

Examples of the alicyclic hydrocarbon group include the same as those exemplified in R^{a1′} to R^{a3′} in formula (20).

Examples of the aliphatic hydrocarbon group include the chain hydrocarbon group and alicyclic hydrocarbon group described above, within the acceptable range of the upper limit of the number of carbon atoms.

Examples of the saturated hydrocarbon group include an aliphatic hydrocarbon group.

Examples of the group in which —CH₂— in a saturated hydrocarbon group is replaced with —O— or —CO— include a hydroxy group, a carboxy group, a carbonyl group, an oxy group, an alkoxy group, an alkoxycarbonyl group, an alkylcarbonyl group, an alkylcarbonyloxy group, an alkanediyloxy group, an alkanediyloxycarbonyl group, an alkanediylcarbonyl group, an alkanediylcarbonyloxy group, a cycloalkoxy group, a cycloalkylalkoxy group, and a group combining two or more of these groups. These replaced groups include those similar to the groups exemplified in the present specification, in the acceptable range of the upper limit of the carbon number.

Examples of structural unit (a4-1) include isobornyl (meth)acrylate, cyclohexyl (meth)acrylate, tricyclodecanyl (meth)acrylate, and tetracyclododecenyl (meth)acrylate, as well as the structural unit shown below and a structural unit in which the methyl group corresponding to R⁵¹ in structural unit (a4-1) is replaced with a hydrogen atom.

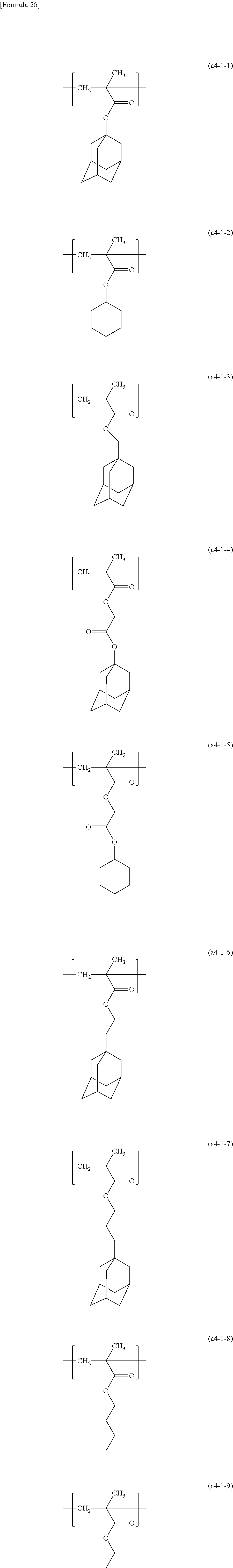

When the resin (A) has such structural unit (a4), the content thereof is preferably 1 to 40 mol %, more preferably 3 to 30 mol %, and further preferably 5 to 20 mol %, with respect to the total amount of the structural units of the resin (A1).
<Structural Unit (a5)>

The structural unit represented by formula (a5) is shown below.

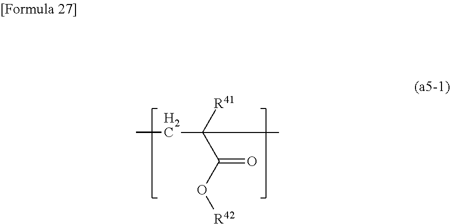

[In formula (a5-1),

R⁴¹ represents a hydrogen atom or a methyl group.

R⁴² represents an aliphatic hydrocarbon group having 1 to 48 carbon atoms and a halogen atom, and —CH₂— included in the aliphatic hydrocarbon group is optionally replaced with —O— or —CO—]

Examples of the halogen atom, the aliphatic hydrocarbon group, and the group in which —CH₂— included in the aliphatic hydrocarbon group is replaced with —O— or —CO— include the above-described group and a group known in the field, within the acceptable range of the upper limit of the number of carbon atoms.

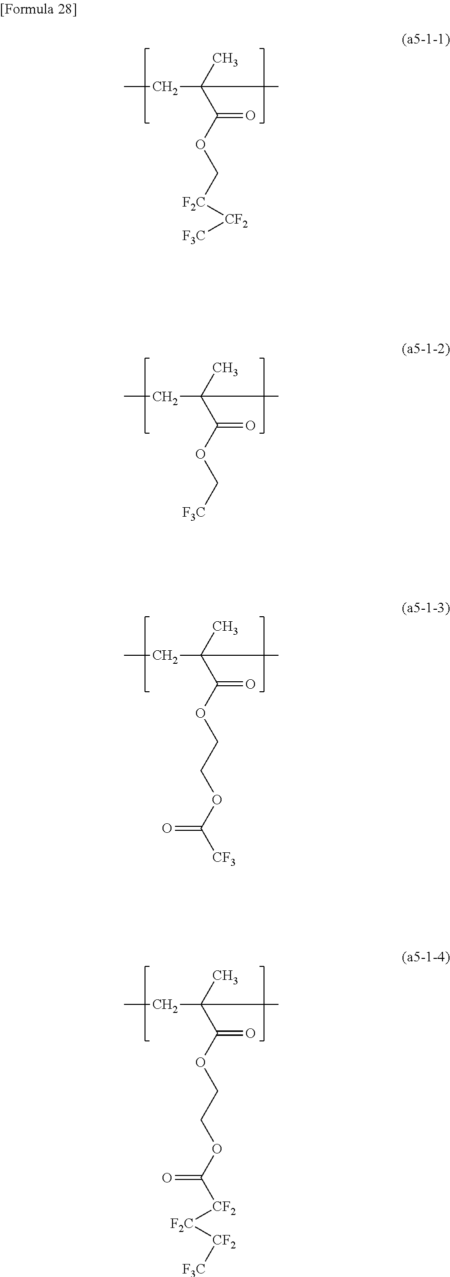

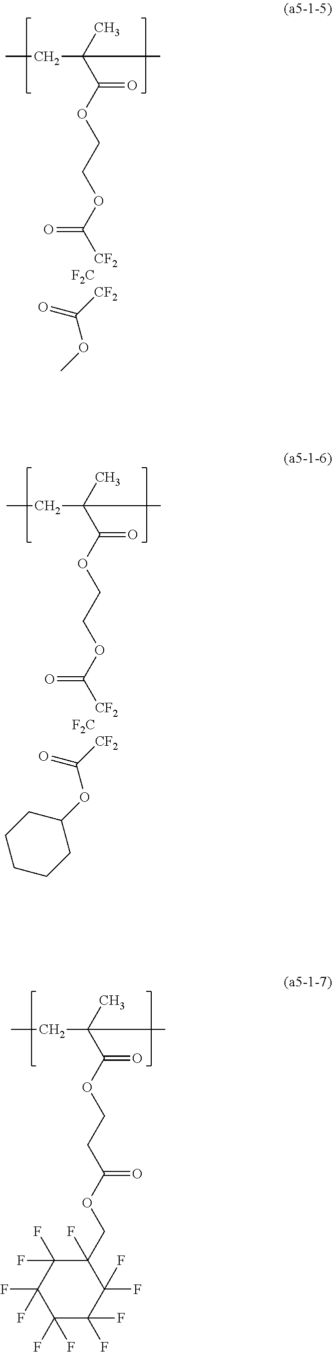

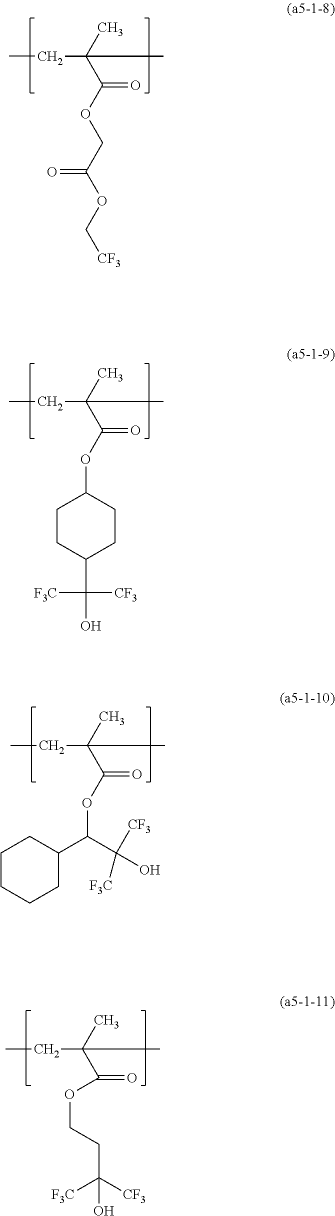

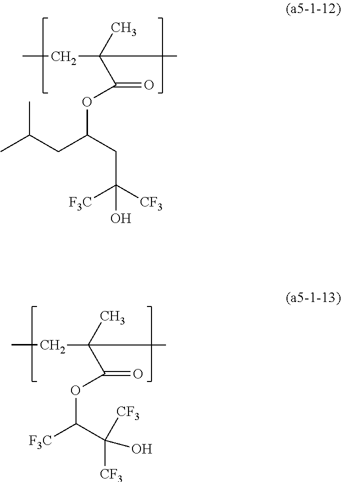

<Structural Unit (a6)>

Structural unit (a6) is a structural unit having a —SO₂— group, and preferably has a —SO₂— group in the side chain.

The structural unit having a —SO₂— group may have a linear structure having a —SO₂— group, a branched structure having a —SO₂— group, or a cyclic structure (monocyclic and polycyclic structures) having a —SO₂— group.

Structural unit (a6) is preferably a structural unit represented by formula (a6-0).

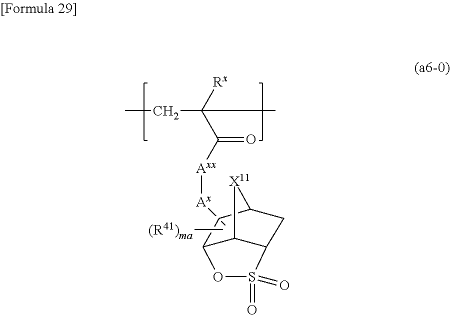

[In formula (a6-0),

R^{x} represents a hydrogen atom or a methyl group.

A^{xx} represents an oxygen atom or a sulfur atom.

A^{x} represents a single bond or a divalent saturated hydrocarbon group having 1 to 18 carbon atoms, and —CH₂— included in the saturated hydrocarbon group is optionally replaced with —O— or —CO—.

X¹¹ represents an oxygen atom, a sulfur atom, or a methylene group.

R⁴¹ represents an alkyl group having 1 to 12 carbon atoms and optionally having a halogen atom or a hydroxy group, a halogen atom, a hydroxy group, a cyano group, an alkoxy group having 1 to 12 carbon atoms, an aryl group having 6 to 12 carbon atoms, an aralkyl group having 7 to 12 carbon atoms, a glycidyloxy group, an alkoxycarbonyl group having 2 to 12 carbon atoms, or an alkylcarbonyl group having 2 to 4 carbon atoms. ma represents an integer of 0 to 9. When ma is 2 or more, a plurality of R⁴¹s are the same or different]

The saturated hydrocarbon group, the group in which —CH₂— in the saturated hydrocarbon group is replaced with —O— or —CO—, the alkyl group, the halogen atom, the alkoxy group, the aryl group, the aralkyl group, the alkoxycarbonyl group, and the alkylcarbonyl group may be the above-described group or a group known in the field, within the range permitted by the upper limit of the carbon number.

Examples of structural unit (a6-0) include a structural unit shown below and a structural unit in which the methyl group corresponding to R^{x} in structural unit (a6-1) in the structural unit shown below is replaced with a hydrogen atom.

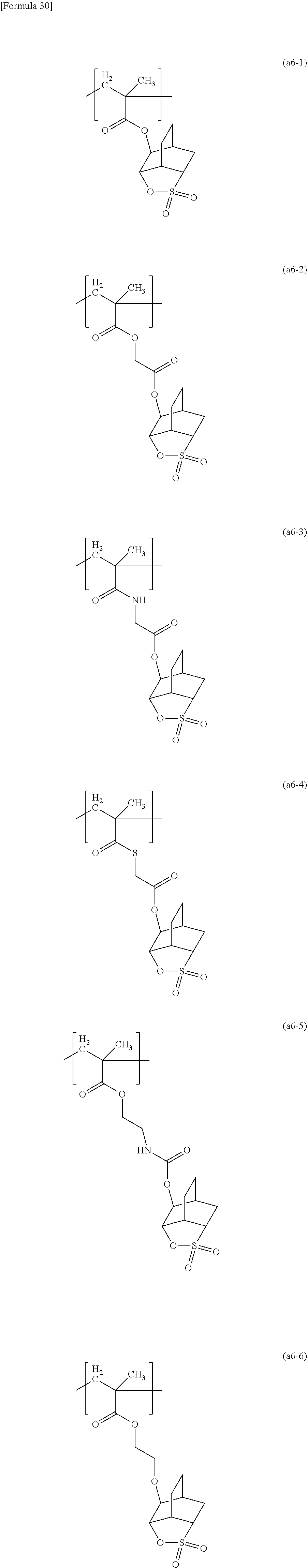

Each structural unit constituting the resin (A) can be produced by a known polymerization method (for example, a radical polymerization method) using a monomer that leads to these structural units. The content of each structural unit can be adjusted by the amount of monomer used in producing the resin (A).

When resin (A1) includes structural unit (a2), the content ratio between structural unit (a1) and structural unit (a2) [structural unit (a1):structural unit (a2)] is preferably 20:80 to 90:10, more preferably 30:70 to 90:10, and still more preferably 40:60 to 90:10, on a molar basis.

In the resin (A1), the content ratio between structural unit (a1-1) and structural unit (a2-2) [structural unit (a1-1):structural unit (a2-2)] is, on a molar basis, 99:1 to 1:99, preferably 90:10 to 10:90, more preferably 90:10 to 60:40, and further preferably 90:10 to 70:30.

When the resin (A2) includes structural unit (a2), the content ratio between structural unit (a1) and structural unit (a2) [structural unit (a1):structural unit (a2)] is, on a molar basis, preferably 15:90 to 90:10, more preferably 20:80 to 80:20, and further preferably 25:75 to 75:25.

In the resin (A2), the content ratio between structural unit (a1-1) and structural unit (a2-1) [structural unit (a1-1):structural unit (a2-2)] is, on a molar basis, 100:0 to 0:100, and preferably 100:0 to 20:80.

The weight average molecular weight of resin (A1) and resin (A2) is preferably 3,000 or more, more preferably 4,000 or more, and preferably 600,000 or less, more preferably 500,000 or less. The weight average molecular weight is determined by gel permeation chromatography analysis as a converted value based on standard polystyrene. Detailed analysis conditions for this analysis are described in the example.

The mass ratio ((A1):(A2)) between the resin (A1) and the resin (A2) included in the resist composition is typically 20:80 to 90:10, and preferably 30:70 to 80:20. Setting within this range is preferable because it is possible to further improve the crack resistance.

The content of the resin (A1) is preferably 10% by mass or more, more preferably 15% by mass or more, further preferably 30% by mass or more, and preferably 95% by mass or less, more preferably 90% by mass or less, and further preferably 85% by mass or less, with respect to the total amount of the resins included in the resist composition.

The content of the resin (A2) is preferably 10% by mass or more, more preferably 15% by mass or more, further preferably 30% by mass or more, and preferably 90% by mass or less, more preferably 80% by mass or less, and further preferably 70% by mass or less, with respect to the total amount of the resins included in the resist composition.

In the resist composition of the present invention, the content of resin (A1) and resin (A2) is preferably 80% by mass or more and 99% by mass or less, with respect to the total amount of solid contents of the resist composition. The content of resin (A1) is preferably 1% by mass or more and 98% by mass or less, and more preferably 5% by mass or more and 90% by mass or less, with respect to the total amount of solid contents of the resist composition. The content of resin (A2) is preferably 1% by mass or more and 98% by mass or less, more preferably 5% by mass or more and 90% by mass or less, with respect to the total amount of solid contents in the resist composition. The solid content and the content of each component included in the resist composition of the present invention can be measured by known analysis means, such as liquid chromatography or gas chromatography.

### <Acid Generator (B)>

Acid generator (B) is a compound that can decompose upon irradiation (exposure) with light to generate an acid. The generated acid can eliminate a leaving group included in the acid labile group of resin (A1), converting the acid labile group into a hydrophilic group (e.g., a carboxy group, a hydroxy group (phenolic hydroxyl group or the like)). That is, exposing a resist composition including resin (A1) to light allows the resist to be made soluble in a developer (alkaline aqueous solution).

Acid generator (B) may be either a nonionic type or an ionic type.

Examples of the non-ionic acid generator include: an organic halide, sulfonate esters (e.g., 2-nitrobenzyl ester, aromatic sulfonate, oxime sulfonate, N-sulfonyloxyimide, sulfonyloxyketone, and diazonaphthoquinone 4-sulfonate); and sulfones (e.g., disulfone, ketosulfone, and sulfonyldiazomethane). Representative examples of the ionic acid generator include an onium salt including an onium cation (e.g., diazonium salt, phosphonium salt, sulfonium salt, and iodonium salt). Examples of the anion of the onium salt include a sulfonate anion, a sulfonylimide anion, and a sulfonylmethide anion.

As acid generator (B), there can be used the compounds that generate an acid when exposed to radiation, such as those described in Japanese Patent Laid-Open No. 63-26653, Japanese Patent Laid-Open No. 55-164824, Japanese Patent Laid-Open No. 62-69263, Japanese Patent Laid-Open No. 63-146038, Japanese Patent Laid-Open No. 63-163452, Japanese Patent Laid-Open No. 62-153853, Japanese Patent Laid-Open No. 63-146029, U.S. Pat. Nos. 3,779,778, 3,849,137, German Patent No. 3914407, and European Patent No. 126,712. In addition, the compound produced by a known method may be used. Acid generator (B) may be used singly or in combination of two or more.

The acid generator is preferably a salt represented by formula (b1) (hereinafter may be referred to as “acid generator (B1)”). In formula (b1), the side having a positive charge may be referred to as an “organic cation” and the side having a negative charge may be referred to as a “sulfonate anion”.

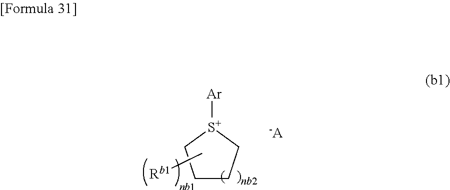

[In formula (b1),

R^{b1} represents a hydroxy group or a hydrocarbon group having 1 to 12 carbon atoms, and —CH₂— included in the hydrocarbon group is optionally replaced with —O— or —CO—.

Ar represents an aromatic hydrocarbon group having 6 to 18 carbon atoms and optionally having a substituent.

The methylene group included in the alicyclic ring including S of the cation is optionally replaced with an oxygen atom, a sulfur atom, or a carbonyl group.

nb1 represents an integer of 0 to 3. When nb1 is 2 or more, a plurality of R^{b1}s are the same or different.

nb2 represents an integer of 1 to 3.

A⁻ represents a sulfonate anion]

In formula (b1), examples of the aromatic hydrocarbon group of Ar include a phenyl group, a naphthyl group, a biphenyl group, an anthryl group, a phenanthryl group, and a binaphthyl group. The aromatic hydrocarbon group preferably has 6 to 14 carbon atoms, and more preferably 6 to 10 carbon atoms.

Examples of the substituent on the aromatic hydrocarbon group of Ar include an alkyl group having 1 to 16 carbon atoms (—CH₂— included in the alkyl group is optionally replaced with —O— or —CO—), a halogen atom, a cyano group, and the group combining two or more of these groups.

Examples of the alkyl group include a methyl group, an ethyl group, a propyl group, an isopropyl group, a butyl group, an isobutyl group, a tert-butyl group, a pentyl group, a hexyl group, an octyl group, and a nonyl group. The alkyl group preferably has 1 to 12 carbon atoms, more preferably 1 to 8 carbon atoms, still more preferably 1 to 6 carbon atoms, and even more preferably 1 to 4 carbon atoms.

Examples of the halogen atom include a fluorine atom, a chlorine atom, a bromine atom, and an iodine atom.

Examples of the group in which —CH₂— in an alkyl group is replaced with —O— or —CO— include a hydroxy group (a group in which —CH₂— in a methyl group is replaced with —O—), a carboxy group (a group in which —CH₂—CH₂— in an ethyl group is replaced with —O—CO—), an alkoxy group (a group in which —CH₂— at any position in an alkyl group is replaced with —O—), an alkoxycarbonyl group (a group in which —CH₂—CH₂— at any position in an alkyl group is replaced with —O—CO—), an alkylcarbonyl group (a group in which —CH₂— at any position in an alkyl group is replaced with —CO—), an alkylcarbonyloxy group (a group in which —CH₂—CH₂— at any position in an alkyl group is replaced with —CO—O—), and a group in which two or more of these groups are combined.

Examples of the alkoxy group include an alkoxy group having 1 to 12 carbon atoms, such as a methoxy group, an ethoxy group, a propoxy group, a butoxy group, a pentyloxy group, a hexyloxy group, an octyloxy group, a 2-ethylhexyloxy group, a nonyloxy group, a decyloxy group, and an undecyloxy group. The alkoxy group preferably has 1 to 8 carbon atoms, more preferably 1 to 6 carbon atoms, and still more preferably 1 to 4 carbon atoms.

Examples of the alkoxycarbonyl group include an alkoxycarbonyl group having 2 to 13 carbon atoms, such as a methoxycarbonyl group, an ethoxycarbonyl group, and a butoxycarbonyl group; examples of the alkylcarbonyl group include an alkylcarbonyl group having 2 to 13 carbon atoms, such as an acetyl group, a propionyl group, and a butyryl group; and examples of the alkylcarbonyloxy group include an alkylcarbonyloxy group having 2 to 13 carbon atoms, such as an acetyloxy group, a propionyloxy group, and a butyryloxy group. The alkoxycarbonyl group preferably has 2 to 8 carbon atoms, more preferably 2 to 6 carbon atoms, and still more preferably 2 to 4 carbon atoms. The alkylcarbonyl group preferably has 2 to 8 carbon atoms, more preferably 2 to 6 carbon atoms, and still more preferably 2 to 4 carbon atoms. The alkylcarbonyloxy group preferably has 2 to 8 carbon atoms, more preferably 2 to 6 carbon atoms, and still more preferably 2 to 4 carbon atoms.

Examples of the combined group include a group that combines an alkoxy group with an alkyl group, a group that combines an alkoxy group with an alkoxy group, a group that combines an alkoxy group with an alkylcarbonyl group, and a group that combines an alkoxy group with an alkylcarbonyl group.

Examples of the combined group of an alkoxy group with an alkyl group include an alkoxyalkyl group having 2 to 13 carbon atoms, such as a methoxymethyl group, a methoxyethyl group, an ethoxyethyl group, and an ethoxymethyl group. The alkoxyalkyl group preferably has 2 to 8 carbon atoms, more preferably 2 to 6 carbon atoms, and still more preferably 2 to 4 carbon atoms.

Examples of the group combining an alkoxy group with an alkoxy group include an alkoxyalkoxy group having 2 to 13 carbon atoms, such as a methoxymethoxy group, a methoxyethoxy group, an ethoxymethoxy group, and an ethoxyethoxy group. The alkoxyalkoxy group preferably has 2 to 8 carbon atoms, more preferably 2 to 6 carbon atoms, and still more preferably 2 to 4 carbon atoms.

Examples of the group combining an alkoxy group with an alkylcarbonyl group include an alkoxyalkylcarbonyl group having 3 to 13 carbon atoms, such as a methoxyacetyl group, a methoxypropionyl group, an ethoxyacetyl group, and an ethoxypropionyl group. The alkoxyalkylcarbonyl group preferably has 3 to 9 carbon atoms, more preferably 3 to 7 carbon atoms, and still more preferably 3 to 5 carbon atoms.

Examples of the group combining an alkoxy group with an alkylcarbonyloxy group include an alkoxyalkylcarbonyloxy group having 3 to 13 carbon atoms, such as a methoxyacetyloxy group, a methoxypropionyloxy group, an ethoxyacetyloxy group, and an ethoxypropionyloxy group. The alkoxyalkylcarbonyloxy group preferably has 3 to 9 carbon atoms, more preferably 3 to 7 carbon atoms, and still more preferably 3 to 5 carbon atoms.

Examples of the hydrocarbon group in R¹ include an aliphatic hydrocarbon group (chain hydrocarbon group and alicyclic hydrocarbon group such as an alkyl group, an alkenyl group, and an alkynyl group), an aromatic hydrocarbon group, and the group formed by combining these.

Examples of the alkyl group include the same ones as those exemplified as the substituent of the aromatic hydrocarbon group in Ar, within the range permitted by the upper limit of the carbon number. The alkyl group preferably has 1 to 9 carbon atoms, more preferably 1 to 6 carbon atoms, and still more preferably 1 to 4 carbon atoms.

Examples of alkenyl group include an ethenyl group, a propenyl group, an isopropenyl group, a butenyl group, an isobutenyl group, a tert-butenyl group, a pentenyl group, a hexenyl group, a heptenyl group, an octynyl group, an isooctynyl group, and a nonenyl group.

Examples of the alkynyl group include an ethynyl group, a propynyl group, an isopropynyl group, a butynyl group, an isobutynyl group, a tert-butynyl group, a pentynyl group, a hexynyl group, an octynyl group, and a nonynyl group.

The alicyclic hydrocarbon group may be monocyclic, polycyclic, or spirocyclic, and may be saturated or unsaturated.

Examples of the monocyclic alicyclic hydrocarbon group include a monocyclic cycloalkyl group such as a cyclopropyl group, a cyclobutyl group, a cyclopentyl group, a cyclohexyl group, a cycloheptyl group, a cyclooctyl group, a cyclononyl group, a cyclodecyl group, and a cyclododecyl group. Examples of the polycyclic alicyclic hydrocarbon group include a polycyclic cycloalkyl group such as a decahydronaphthyl group, an adamantly group, and a norbornyl group. The alicyclic hydrocarbon group preferably has 3 to 10 carbon atoms.

Examples of the aromatic hydrocarbon group include an aryl group such as a phenyl group, a naphthyl group, and a biphenyl group. The aromatic hydrocarbon group preferably has 6 to 10 carbon atoms. In the case of the combined group, the above group may include groups with different valences (an alkanediyl group, an alkanetriyl group, a cycloalkanediyl group, a cycloalkanetriyl group, and the like).

Examples of the group formed by combination include a group in which an aromatic hydrocarbon group and a chain hydrocarbon group are combined (e.g., aromatic hydrocarbon group-alkanediyl group-*, alkyl group-aromatic hydrocarbon group-*), a group in which an alicyclic hydrocarbon group and a chain hydrocarbon group are combined (e.g., alicyclic hydrocarbon group-alkanediyl group-*, alkyl group-alicyclic hydrocarbon group-*), and a group in which an aromatic hydrocarbon group and a alicyclic hydrocarbon group are combined (e.g., aromatic hydrocarbon group-alicyclic hydrocarbon group-*, alicyclic hydrocarbon group-aromatic hydrocarbon group-*). * represents a bonding site.

Examples of the aromatic hydrocarbon group-alkanediyl group-* include an aralkyl group such as a benzyl group and a phenethyl group. Examples of the alkyl group-aromatic hydrocarbon group-* include a tolyl group, a xylyl group, and a cumenyl group.

Examples of the alicyclic hydrocarbon group-alkanediyl group-* include a cycloalkylalkyl group such as a cyclohexylmethyl group, a cyclohexylethyl group, and a 1-(adamantan-1-yl)methyl group.

Examples of the alkyl group-alicyclic hydrocarbon group-* include a cycloalkyl group having an alkyl group such as a methylcyclohexyl group, a dimethylcyclohexyl group, and a 2-alkyladamantan-2-yl group. Examples of the aromatic hydrocarbon group-alicyclic hydrocarbon group-* include a phenylcyclohexyl group. Examples of the alicyclic hydrocarbon group-aromatic hydrocarbon group-* include a cyclohexylphenyl group. The alicyclic hydrocarbon group, aromatic hydrocarbon group, and chain hydrocarbon group may each be combined in a combination of two or more types.

Examples of the group in which —CH₂— in a hydrocarbon group is replaced with —O— or —CO— include: an alkoxy group such as a hydroxy group, a carboxy group, a methoxy group, an ethoxy group, and a butoxy group; a cycloalkoxy group such as a cyclohexyloxy group; a cycloalkylalkoxy group such as a cyclohexylmethoxy group; an alkylcarbonyl group such as an acetyl group; an alkoxycarbonyl group such as a methoxycarbonyl group; an alkylcarbonyloxy group such as an acetyloxy group; an alkoxycarbonyloxy group such as a butoxycarbonyloxy group; and an aromatic hydrocarbon group such as a benzoyloxy group-carbonyloxy group. These replaced groups include the same groups as those exemplified in this specification, within the acceptable range of the upper limit of the number of carbon atoms.

Ar is preferably a phenyl group optionally having an alkyl group having 1 to 8 carbon atoms or a naphthyl group optionally having an alkyl group having 1 to 8 carbon atoms (wherein —CH₂— included in the alkyl group is optionally replaced with —O— or —CO—), more preferably a phenyl group optionally having an alkyl group having 1 to 6 carbon atoms or a naphthyl group optionally having an alkoxy group having 1 to 6 carbon atoms, and further preferably a phenyl group optionally having an alkyl group having 1 to 4 carbon atoms or a naphthyl group optionally having an alkoxy group having 1 to 4 carbon atoms.

nb1 is preferably 0 or 1, and 0 is more preferable.

nb2 is preferably 1 or 2, and 2 is more preferable.

Examples of the organic cation in formula (b1) include cations represented by the following formulas (bC-1) to (bC-23).

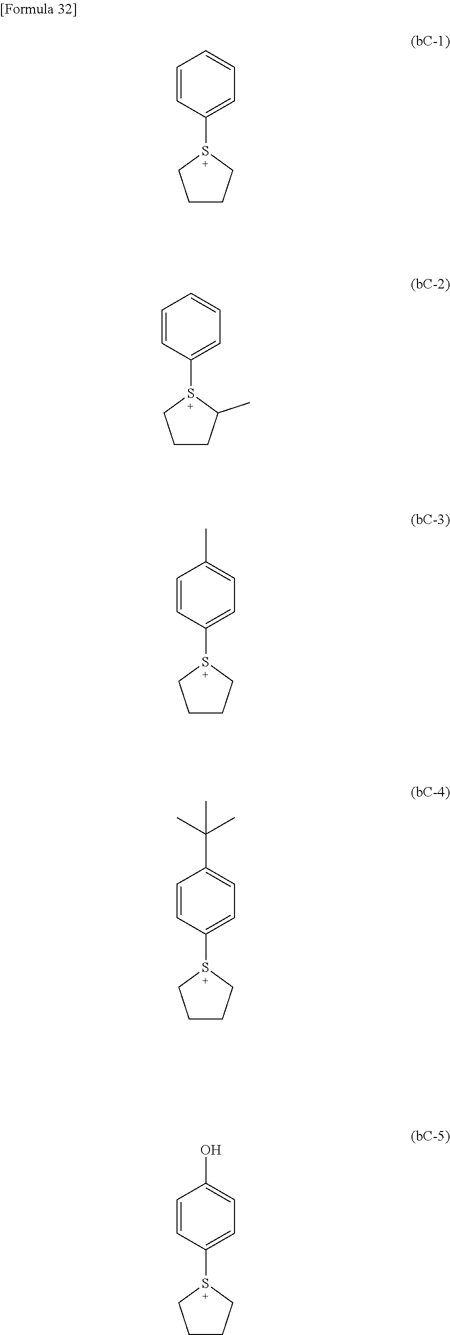

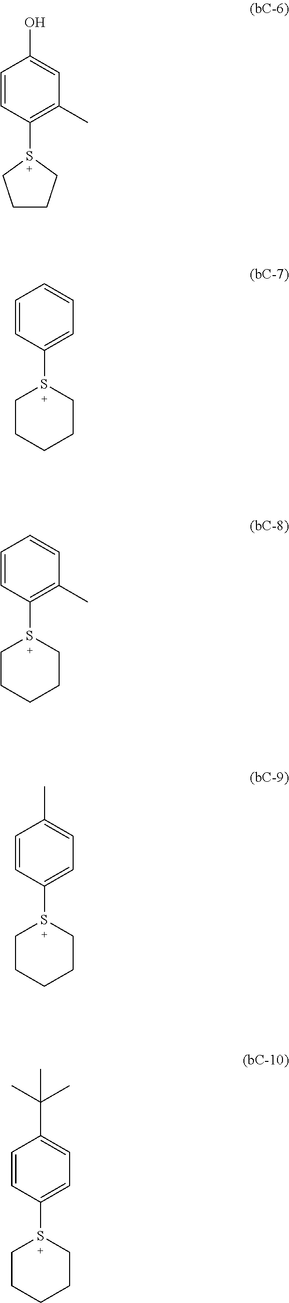

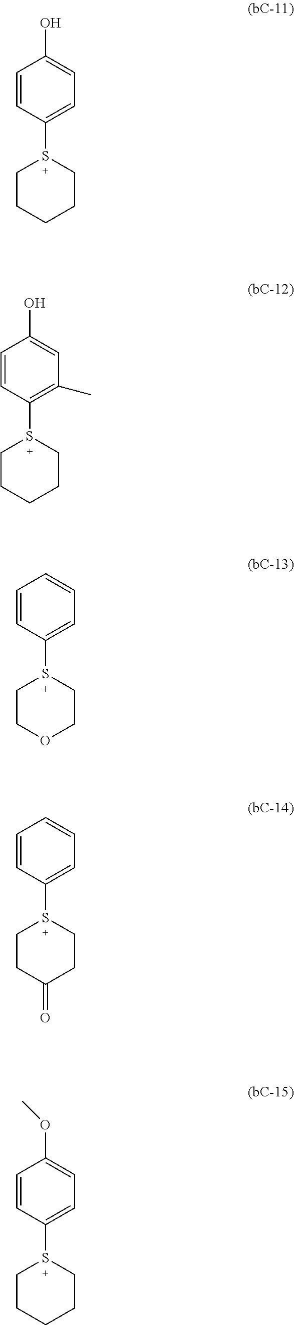

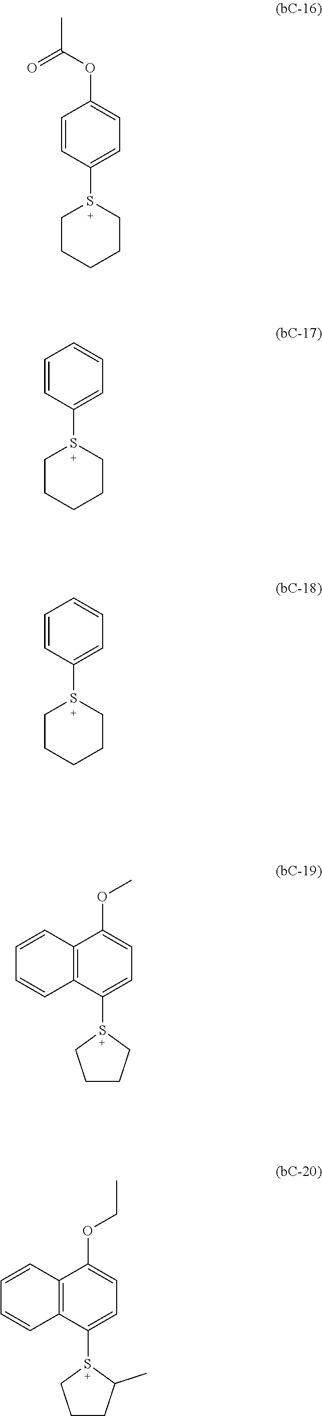

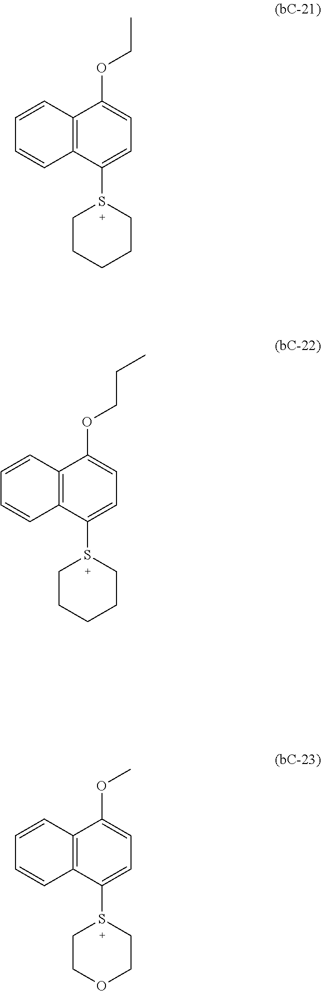

The sulfonate anion represented by A⁻ is preferably an anion represented by formula (bA).

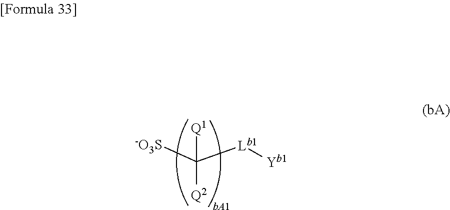

[In formula (bA),

Q¹ and Q² each independently represent a hydrogen atom, a fluorine atom, an alkyl group having 1 to 6 carbon atoms, or a perfluoroalkyl group having 1 to 6 carbon atoms.

L^{b1} represents a saturated hydrocarbon group having 1 to 24 carbon atoms and optionally having a substituent, and —CH₂— included in the saturated hydrocarbon group is optionally replaced with —O— or —CO—.

Y^{b1} represents an aliphatic hydrocarbon group having 1 to 18 carbon atoms and optionally having a substituent, or an aromatic hydrocarbon group having 6 to 24 carbon atoms and optionally having a substituent. The —CH₂— included in the aliphatic hydrocarbon group is optionally replaced with —O—, —S—, —CO—, or —SO₂—.

bA1 represents an integer of 1 to 6. When bA1 is 2 or more, the groups in a plurality of parentheses are the same or different from each other]

Examples of the perfluoroalkyl groups represented by Q¹ and Q² include a trifluoromethyl group, a perfluoroethyl group, a perfluoropropyl group, a perfluoroisopropyl group, a perfluorobutyl group, a perfluorosec-butyl group, a perfluorotert-butyl group, a perfluoropentyl group, and a perfluorohexyl group. It is preferable that Qb1 and Qb2 be each independently a fluorine atom or a trifluoromethyl group, and it is more preferable that both be fluorine atoms.

bA1 is preferably an integer of 1 to 4, more preferably an integer of 1 to 3, further preferably 1 or 2, and still more preferably 1.

Examples of the divalent saturated hydrocarbon group in L^{b1} includes a linear alkanediyl group, a branched alkanediyl group, and a monocyclic or polycyclic divalent alicyclic saturated hydrocarbon group, and may be a group formed by combining two or more of these groups.

Specific examples thereof include: a linear alkanediyl group such as a methylene group, an ethylene group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group, and a heptadecane-1,17-diyl group;
a branched alkanediyl group such as an ethane-1,1-diyl group, a propane-1,1-diyl group, a propane-1,2-diyl group, a propane-2,2-diyl group, a pentane-2,4-diyl group, a 2-methylpropane-1,3-diyl group, a 2-methylpropane-1,2-diyl group, a pentane-1,4-diyl group, and a 2-methylbutane-1,4-diyl group;
a monocyclic divalent alicyclic saturated hydrocarbon group such as a cycloalkanediyl group, such as a cyclobutane-1,3-diyl group, a cyclopentane-1,3-diyl group, a cyclohexane-1,4-diyl group, and a cyclooctane-1,5-diyl group; and
a polycyclic divalent alicyclic saturated hydrocarbon group such as a norbornane-1,4-diyl group, a norbornane-2,5-diyl group, an adamantane-1,5-diyl group, and an adamantane-2,6-diyl group.

Examples of the divalent saturated hydrocarbon group represented by L^{b1} in which —CH₂— is replaced with —O— or —CO— includes a group represented by any of formulas (b1-1) to (b1-3). In the groups represented by formulas (b1-1) to (b1-3) and specific examples thereof represented by formulas (b1-4) to (b1-11), * and ** represent bonding sites, and * represents a bonding site with —Y.

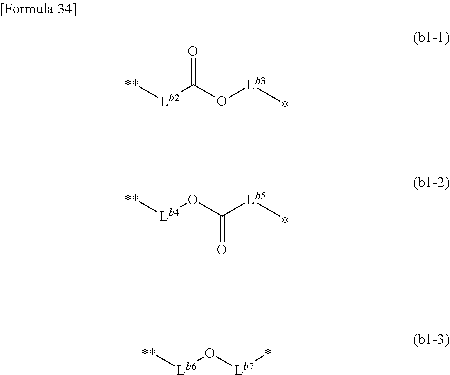

[In formula (b1-1),

L^{b2} represents a single bond or a divalent saturated hydrocarbon group having 1 to 22 carbon atoms, and a hydrogen atom in the saturated hydrocarbon group is optionally replaced with a fluorine atom. L^{b3} represents a single bond or a divalent saturated hydrocarbon group having 1 to 22 carbon atoms, a hydrogen atom included in the saturated hydrocarbon group is optionally replaced with a fluorine atom or a hydroxy group, and —CH₂— included in the saturated hydrocarbon group is optionally replaced with —O— or —CO—.

With the proviso that the total number of carbon atoms in L^{b2} and L^{b3} is 22 or less.

In formula (b1-2),

L^{b4} represents a single bond or a divalent saturated hydrocarbon group having 1 to 22 carbon atoms, and a hydrogen atom included in the saturated hydrocarbon group is optionally replaced with a fluorine atom.

L^{b5} represents a single bond or a divalent saturated hydrocarbon group having 1 to 22 carbon atoms, and a hydrogen atom included in the saturated hydrocarbon group is optionally replaced with a fluorine atom or a hydroxy group, and —CH₂— included in the saturated hydrocarbon group is optionally replaced with —O— or —CO—.

With the proviso that the total number of carbon atoms in L^{b4} and L^{b5} is 22 or less.

In formula (b1-3),

L^{b6} represents a single bond or a divalent saturated hydrocarbon group having 1 to 23 carbon atoms, and a hydrogen atom included in the saturated hydrocarbon group is optionally replaced with a fluorine atom or a hydroxy group.

L^{b7} represents a single bond or a divalent saturated hydrocarbon group having 1 to 23 carbon atoms, and a hydrogen atom included in the saturated hydrocarbon group is optionally replaced with a fluorine atom or a hydroxy group, and —CH₂— included in the saturated hydrocarbon group is optionally replaced with —O— or —CO—.

With the proviso that the total number of carbon atoms in L^{b6} and L^{b7} is 23 or less]

In the groups represented by formulas (b1-1) to (b1-3), when —CH₂— included in the saturated hydrocarbon group is replaced with —O— or —CO—, the number of carbon atoms before replacement is the number of carbon atoms of the saturated hydrocarbon group.

Examples of the divalent saturated hydrocarbon group include the same as the divalent saturated hydrocarbon group of L^{b1}.

L^{b2} is preferably a single bond.

L^{b3} is preferably a divalent saturated hydrocarbon group having 1 to 4 carbon atoms.

L^{b4} is preferably a divalent saturated hydrocarbon group having 1 to 8 carbon atoms, and a hydrogen atom included in the divalent saturated hydrocarbon group is optionally replaced with a fluorine atom.

L^{b5} is preferably a single bond or a divalent saturated hydrocarbon group having 1 to 8 carbon atoms.

L^{b6} is preferably a single bond or a divalent saturated hydrocarbon group having 1 to 4 carbon atoms, and a hydrogen atom included in the saturated hydrocarbon group is optionally replaced with a fluorine atom.

L^{b7} is preferably a single bond or a divalent saturated hydrocarbon group having 1 to 18 carbon atoms, in which a hydrogen atom included in the saturated hydrocarbon group is optionally replaced with a fluorine atom or a hydroxy group, and the —CH₂— included in the divalent saturated hydrocarbon group is optionally replaced with —O— or —CO—.

The group in which the —CH₂— included in the divalent saturated hydrocarbon group represented by L^{b1} is replaced with —O— or —CO— is preferably a group represented by formula (b1-1) or formula (b1-3), and more preferably a group represented by formula (b1-1).

Examples of the group represented by formula (b1-1) includes the groups represented by formulas (b1-4) to (b1-8).

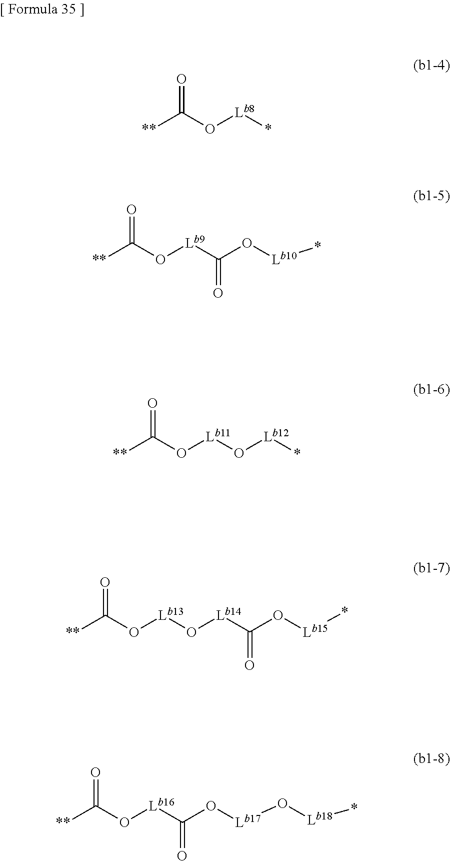

[In formula (b1-4),

L^{b8} represents a single bond or a divalent saturated hydrocarbon group having 1 to 22 carbon atoms, and a hydrogen atom included in the saturated hydrocarbon group is optionally replaced with a fluorine atom or a hydroxy group.

In formula (b1-5),

L^{b9} represents a divalent saturated hydrocarbon group having 1 to 20 carbon atoms, and the —CH₂— included in the divalent saturated hydrocarbon group is optionally replaced with —O— or —CO—.

L^{b10} represents a single bond or a divalent saturated hydrocarbon group having 1 to 19 carbon atoms, and a hydrogen atom included in the divalent saturated hydrocarbon group is optionally replaced with a fluorine atom or a hydroxy group.

With the proviso that the total number of carbon atoms in L^{b9} and L^{b10} is 20 or less.

In formula (b1-6),

L^{b11} represents a divalent saturated hydrocarbon group having 1 to 21 carbon atoms.

L^{b12} represents a single bond or a divalent saturated hydrocarbon group having 1 to 20 carbon atoms, and a hydrogen atom included in the divalent saturated hydrocarbon group is optionally replaced with a fluorine atom or a hydroxy group.

With the proviso that the total number of carbon atoms in L^{b11} and L^{b12} is 21 or less.

In formula (b1-7),

L^{b13} represents a divalent saturated hydrocarbon group having 1 to 19 carbon atoms.

L^{b14} represents a single bond or a divalent saturated hydrocarbon group having 1 to 18 carbon atoms, and a —CH₂— included in the divalent saturated hydrocarbon group is optionally replaced with —O— or —CO—.

L^{b15} represents a single bond or a divalent saturated hydrocarbon group having 1 to 18 carbon atoms, and a hydrogen atom contained in the divalent saturated hydrocarbon group may be substituted with a fluorine atom or a hydroxy group.

However, the total number of carbon atoms of L^{b13} to L^{b15} is 19 or less.

In formula (b1-8),

L^{b16} represents a divalent saturated hydrocarbon group having 1 to 18 carbon atoms, and —CH₂— included in the divalent saturated hydrocarbon group is optionally replaced with —O— or —CO—.

L^{b17} represents a divalent saturated hydrocarbon group having 1 to 18 carbon atoms.

L^{b18} represents a single bond or a divalent saturated hydrocarbon group having 1 to 17 carbon atoms, and a hydrogen atom included in the divalent saturated hydrocarbon group is optionally replaced with a fluorine atom or a hydroxy group.

With the proviso that the total number of carbon atoms of L^{b16} to L^{b18} is 19 or less]

L^{b8} is preferably a divalent saturated hydrocarbon group having 1 to 4 carbon atoms.

L^{b9} is preferably a divalent saturated hydrocarbon group having 1 to 8 carbon atoms.

L^{b10} is preferably a single bond or a divalent saturated hydrocarbon group having 1 to 19 carbon atoms, more preferably a single bond or a divalent saturated hydrocarbon group having 1 to 8 carbon atoms.

L^{b11} is preferably a divalent saturated hydrocarbon group having 1 to 8 carbon atoms.

L^{b12} is preferably a single bond or a divalent saturated hydrocarbon group having 1 to 8 carbon atoms.

L^{b13} is preferably a divalent saturated hydrocarbon group having 1 to 12 carbon atoms.

L^{b14} is preferably a single bond or a divalent saturated hydrocarbon group having 1 to 6 carbon atoms.

L^{b15} is preferably a single bond or a divalent saturated hydrocarbon group having 1 to 18 carbon atoms, more preferably a single bond or a divalent saturated hydrocarbon group having 1 to 8 carbon atoms.

L^{b16} is preferably a divalent saturated hydrocarbon group having 1 to 12 carbon atoms.

L^{b17} is preferably a divalent saturated hydrocarbon group having 1 to 6 carbon atoms.

L^{b19} is preferably a single bond or a divalent saturated hydrocarbon group having 1 to 17 carbon atoms, more preferably a single bond or a divalent saturated hydrocarbon group having 1 to 4 carbon atoms.

Examples of the group represented by formula (b1-3) includes groups represented by formulas (b1-9) to (b1-11).

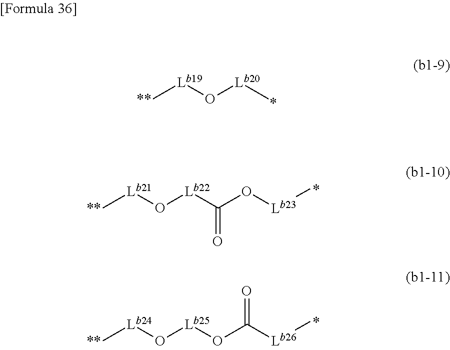

[In formula (b1-9),

L^{b19} represents a single bond or a divalent saturated hydrocarbon group having 1 to 23 carbon atoms, and a hydrogen atom included in the saturated hydrocarbon group is optionally replaced with a fluorine atom.

L^{b20} represents a single bond or a divalent saturated hydrocarbon group having 1 to 23 carbon atoms, and a hydrogen atom included in the saturated hydrocarbon group is optionally replaced with a fluorine atom, a hydroxy group, or an alkylcarbonyloxy group. With the proviso that the —CH₂— included in the alkylcarbonyloxy group is optionally replaced with —O— or —CO—, and a hydrogen atom included in the alkylcarbonyloxy group is optionally replaced with a hydroxy group.

With the proviso that the total number of carbon atoms in L^{b19} and L^{b20} is 23 or less.

In formula (b1-10),

L^{b21} represents a single bond or a divalent saturated hydrocarbon group having 1 to 21 carbon atoms, and a hydrogen atom included in the saturated hydrocarbon group is optionally replaced with a fluorine atom.

L^{b22} represents a single bond or a divalent saturated hydrocarbon group having 1 to 21 carbon atoms.

L^{b23} represents a single bond or a divalent saturated hydrocarbon group having 1 to 21 carbon atoms, and a hydrogen atom contained in the saturated hydrocarbon group is optionally replaced with a fluorine atom, a hydroxy group, or an alkylcarbonyloxy group. The —CH₂— included in the alkylcarbonyloxy group is optionally replaced with —O— or —CO—, and a hydrogen atom included in the alkylcarbonyloxy group is optionally replaced with a hydroxy group.

With the proviso that the total number of carbon atoms in L^{b21}, L^{b22}, and L^{b23} is 21 or less.

In formula (b1-11),

L^{b24} represents a single bond or a divalent saturated hydrocarbon group having 1 to 20 carbon atoms, and a hydrogen atom included in the saturated hydrocarbon group is optionally replaced with a fluorine atom.

L^{b25} represents a divalent saturated hydrocarbon group having 1 to 21 carbon atoms.

L^{b26} represents a single bond or a divalent saturated hydrocarbon group having 1 to 20 carbon atoms, and a hydrogen atom included in the saturated hydrocarbon group is optionally replaced with a fluorine atom, a hydroxy group, or an alkylcarbonyloxy group. —CH₂— included in the alkylcarbonyloxy group is optionally replaced with —O— or —CO—, and a hydrogen atom included in the alkylcarbonyloxy group is optionally replaced with a hydroxy group.

With the proviso that the total number of carbon atoms in L^{b24}, L^{b2}5, and L^{b26} is 21 or less]

In the groups represented by formulas (b1-9) to (b1-11), when a hydrogen atom included in a saturated hydrocarbon group is replaced with an alkylcarbonyloxy group, the number of carbon atoms before replacement is regarded as the number of carbon atoms in the saturated hydrocarbon group.

Examples of the alkylcarbonyloxy group include an acetyloxy group, a propionyloxy group, a butyryloxy group, a cyclohexylcarbonyloxy group, and an adamantylcarbonyloxy group.

Examples of the group represented by formula (b1-4) include the following.

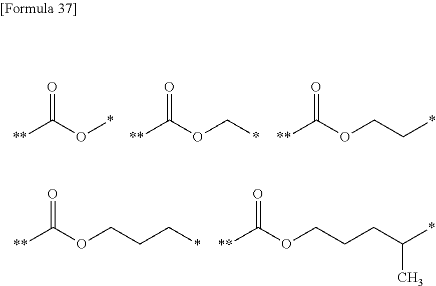

Examples of the group represented by formula (b1-5) include the following.

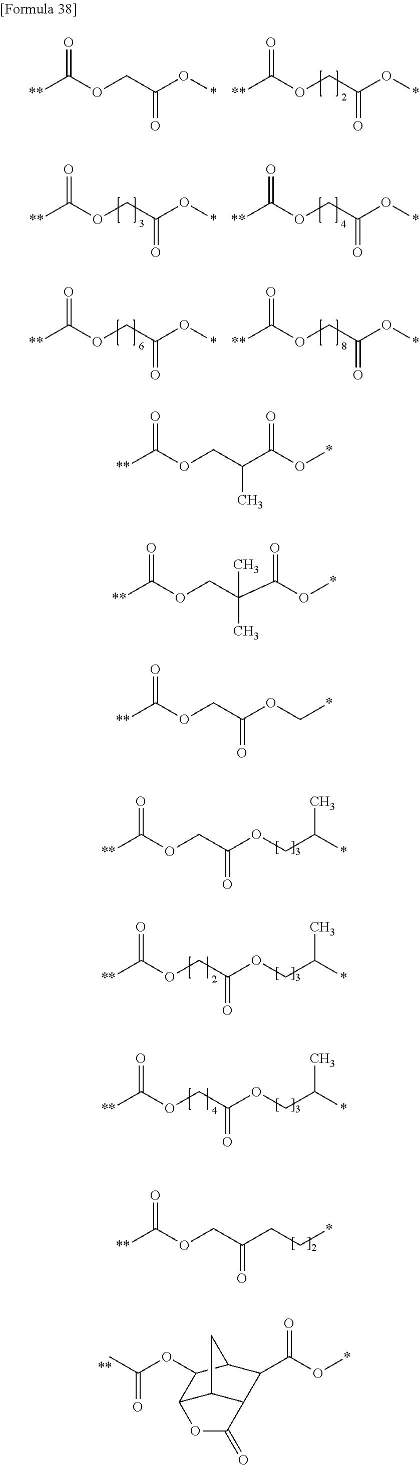

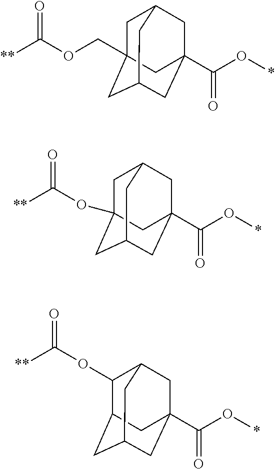

Examples of the group represented by formula (b1-6) include the following.

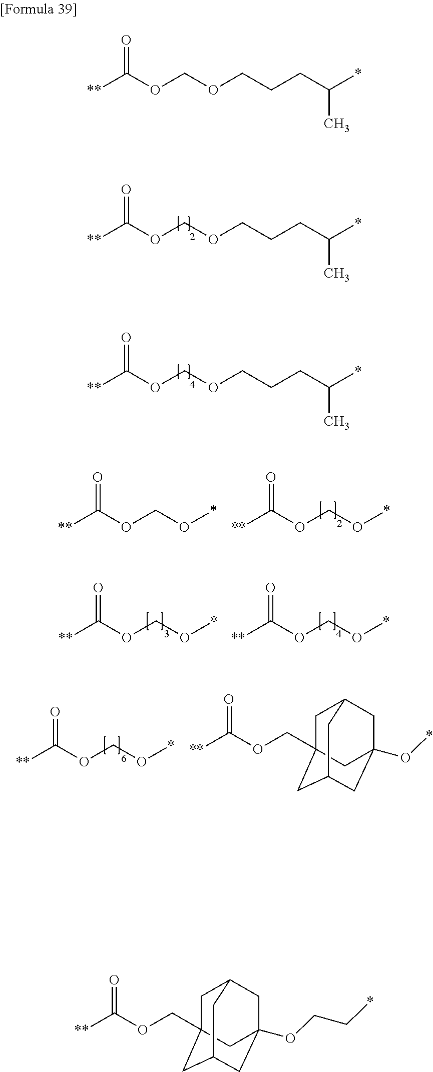

Examples of the group represented by formula (b1-7) include the following.

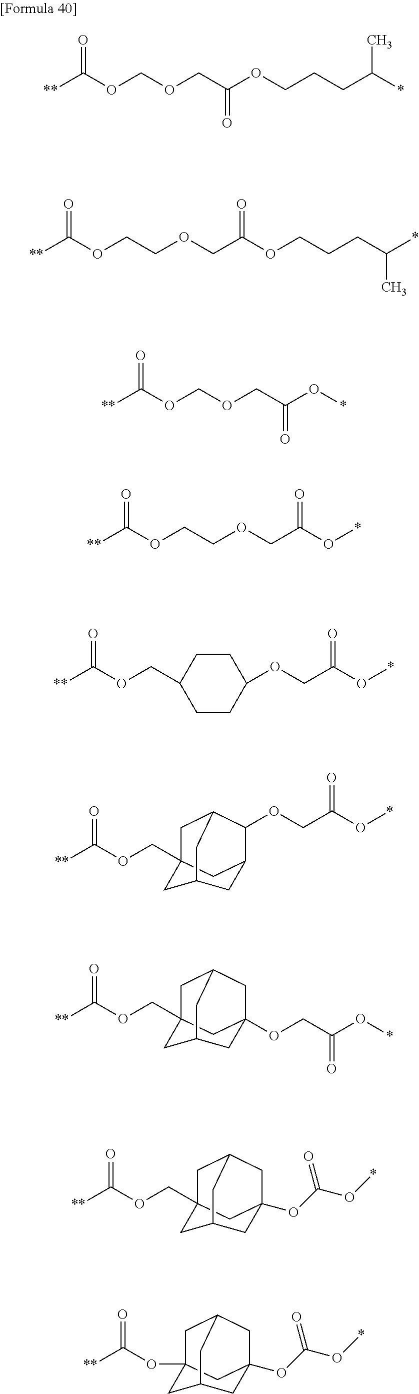

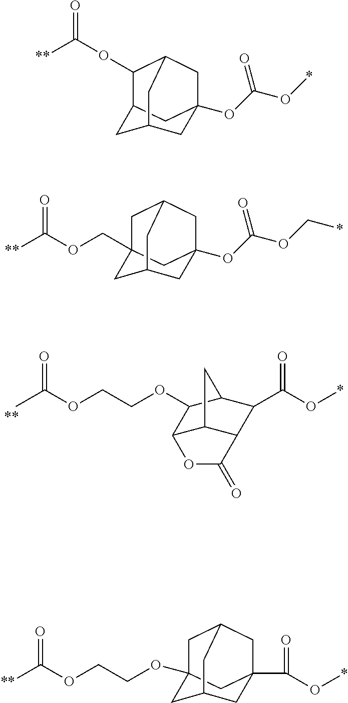

Examples of the group represented by formula (b1-8) include the following.

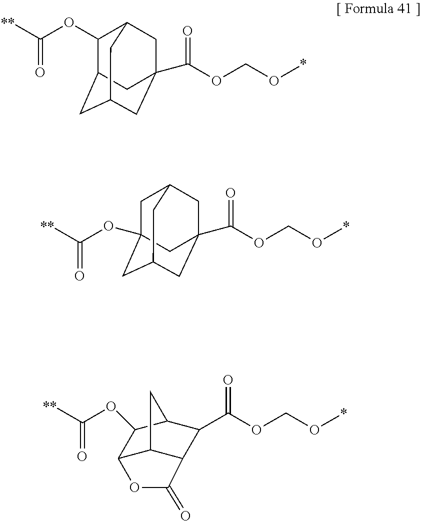

Examples of the group represented by formula (b1-2) include the following.

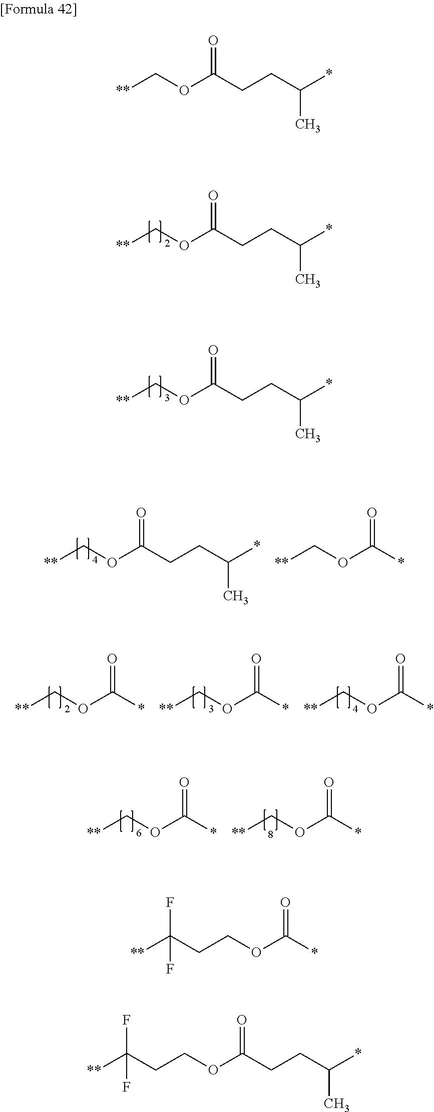

Examples of the group represented by formula (b1-9) include the following.

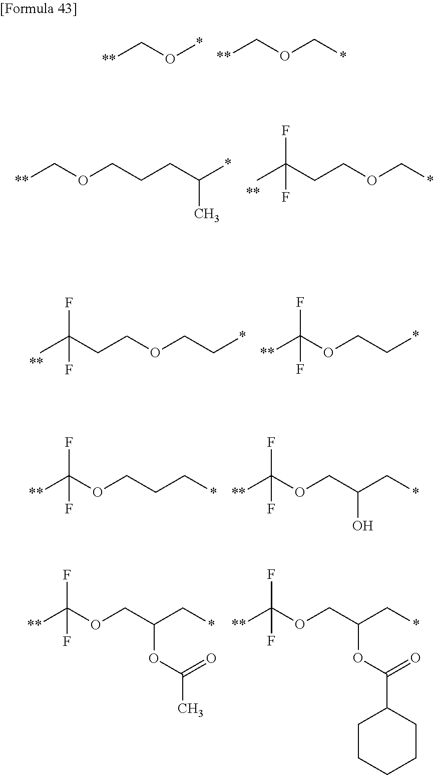

Examples of the group represented by formula (b1-10) include the following.

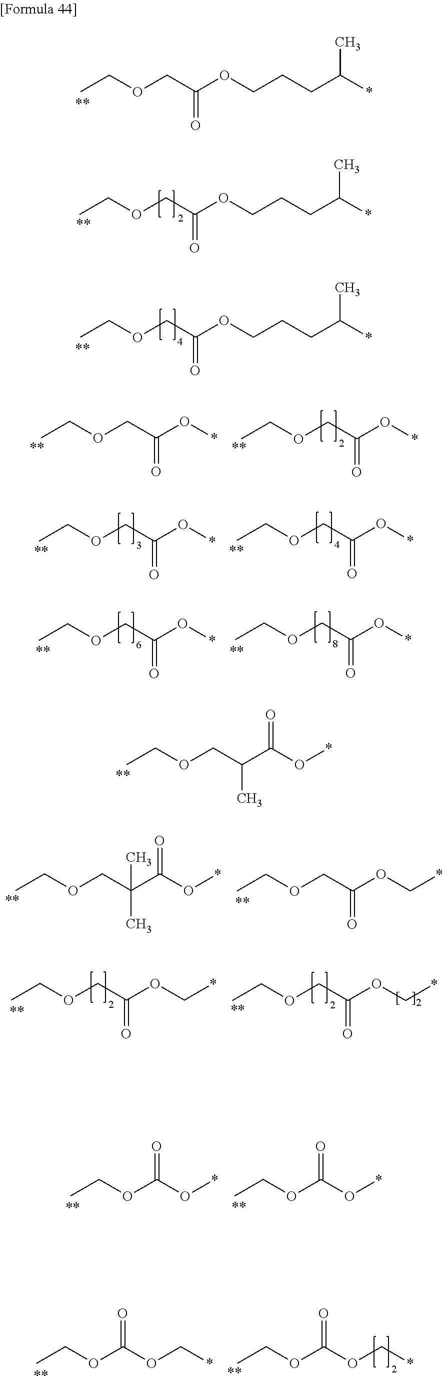

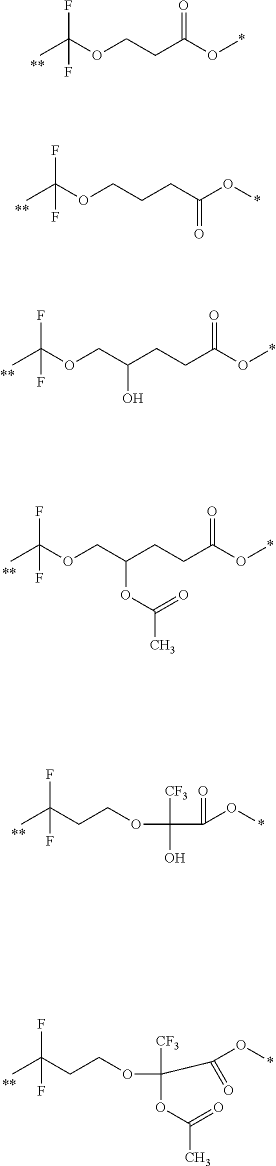

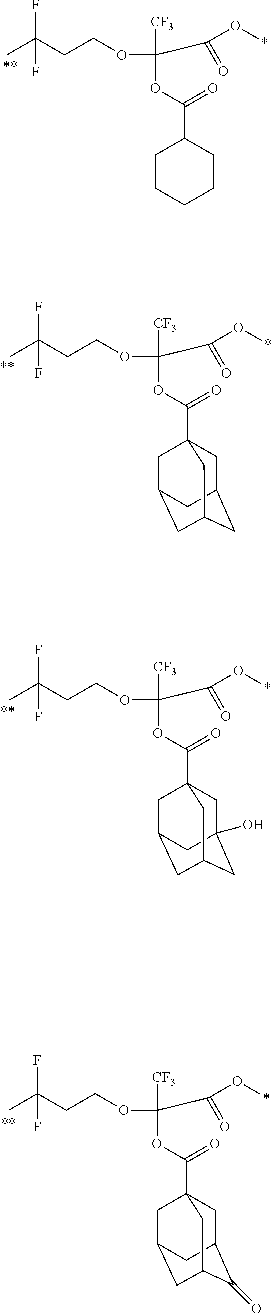

Examples of the group represented by formula (b1-11) include the following.

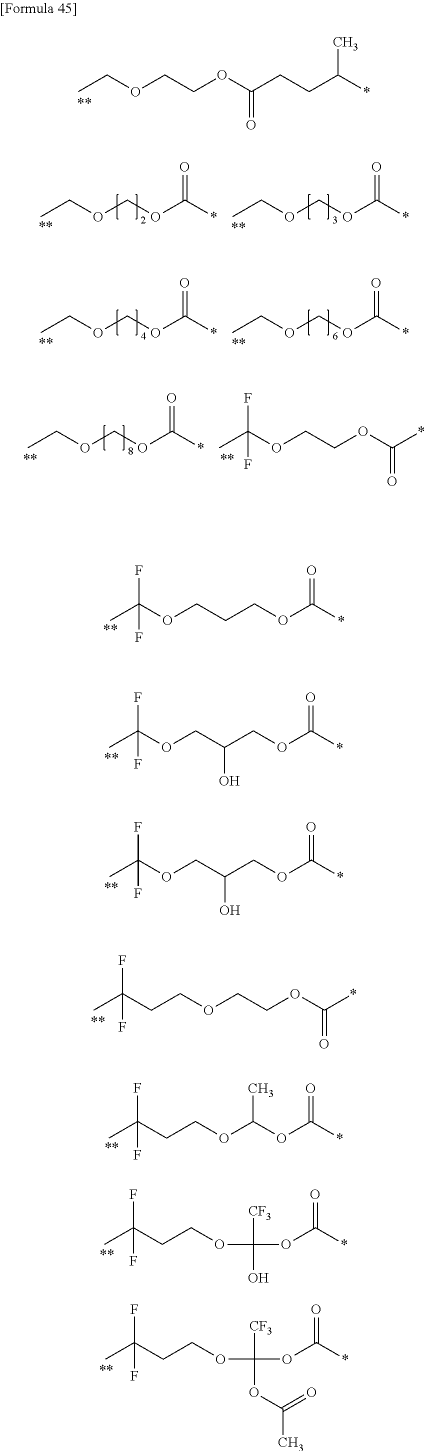

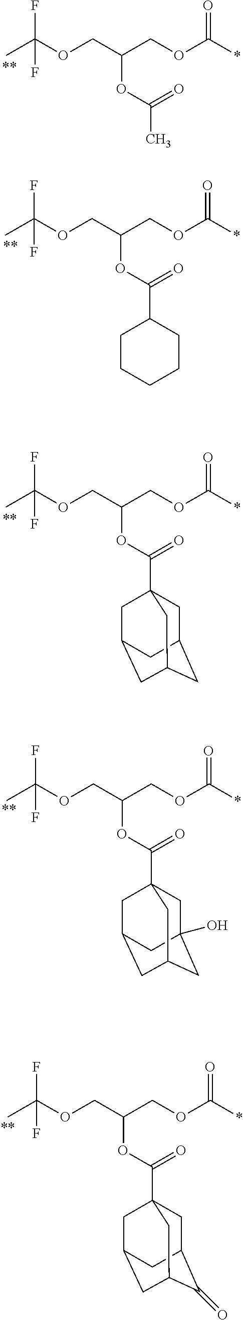

Examples of the substituent that the saturated hydrocarbon group in L^{b1} optionally has include a halogen atom, a hydroxy group, a glycidyloxy group, a —(CH₂)ⱼₐ—CO—O—R^{b1} group, or a —(CH₂)ⱼₐ—O—CO—R^{b1} group (wherein R^{b1} represents an alkyl group having 1 to 16 carbon atoms, an alicyclic hydrocarbon group having 3 to 16 carbon atoms, or a group combining these. ja represents an integer of 0 to 4). Examples of these groups include the same as the substituents in the alicyclic hydrocarbon group in Y^{b1}. Among these, a fluorine atom or a hydroxy group is preferable.

Y^{b1} represents an aliphatic hydrocarbon group having 1 to 18 carbon atoms and optionally having a substituent, or an aromatic hydrocarbon group having 6 to 24 carbon atoms and optionally having a substituent. Among the aliphatic hydrocarbon groups, an alkyl group having 1 to 6 carbon atoms, or an alicyclic hydrocarbon group having 3 to 12 carbon atoms is preferable.

Examples of the alkyl group include a methyl group, an ethyl group, an n-propyl group, an isopropyl group, an n-butyl group, a sec-butyl group, a tert-butyl group, an n-pentyl group, an n-hexyl group, an n-heptyl group, a 2-ethylhexyl group, an n-octyl group, an n-nonyl group, an n-decyl group, an n-undecyl group, and an n-dodecyl group. The alkyl group preferably has 1 to 12 carbon atoms, more preferably 1 to 8 carbon atoms, and still more preferably 1 to 6 carbon atoms.

The alicyclic hydrocarbon group may be either monocyclic or polycyclic, and examples of the monocyclic alicyclic hydrocarbon group include a monocyclic cycloalkyl group such as a cyclopropyl group, a cyclobutyl group, a cyclopentyl group, a cyclohexyl group, a cycloheptyl group, a cyclooctyl group, a cyclononyl group, a cyclodecyl group, and a cyclododecyl group.

Examples of the polycyclic alicyclic hydrocarbon group include a polycyclic cycloalkyl group such as a decahydronaphthyl group, an adamantly group, and a norbornyl group. The alicyclic hydrocarbon group preferably has 3 to 16 carbon atoms, more preferably 3 to 12 carbon atoms, and still more preferably 3 to 10 carbon atoms.

Specific examples of the alicyclic hydrocarbon group include the group shown below. The bonding site can be any position.

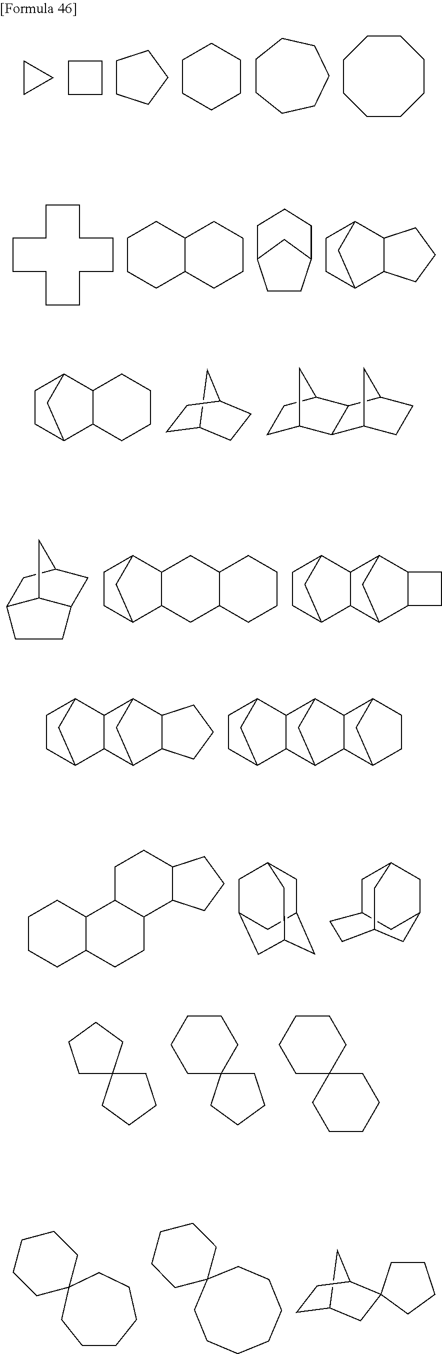

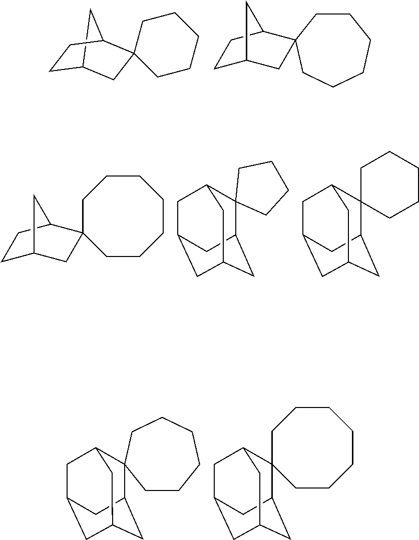

Examples of the aromatic hydrocarbon group include an aryl group such as a phenyl group, a naphthyl group, a biphenyl group, an anthryl group, a phenanthryl group, and a binaphthyl group. The aromatic hydrocarbon group preferably has 6 to 18 carbon atoms, more preferably 6 to 14 carbon atoms, and still more preferably 6 to 10 carbon atoms.

Examples of the substituent that the aliphatic hydrocarbon group having 1 to 18 carbon atoms and the aromatic hydrocarbon group having 6 to 24 carbon atoms represented by Y^{b1} optionally have include a halogen atom, a hydroxy group, an alicyclic hydrocarbon group having 3 to 16 carbon atoms, an aromatic hydrocarbon group having 6 to 18 carbon atoms, a glycidyloxy group, a —(CH₂)ⱼₐ—CO—O—R^{b1} group, or a —(CH₂)ⱼₐ—O—CO—R^{b1} group (wherein R^{b1} represents an alkyl group having 1 to 16 carbon atoms, an alicyclic hydrocarbon group having 3 to 16 carbon atoms, an aromatic hydrocarbon group having 6 to 18 carbon atoms, or a combination thereof. ja represents an integer of 0 to 4. The —CH₂— included in the alkyl group and the alicyclic hydrocarbon group are optionally replaced with —O—, —SO₂— or —CO—, and the hydrogen atoms included in the alkyl group, the alicyclic hydrocarbon group, and the aromatic hydrocarbon group are optionally replaced with a hydroxy group or a fluorine atom).

Examples of the halogen atom include a fluorine atom, a chlorine atom, a bromine atom, and an iodine atom.

Examples of the alicyclic hydrocarbon group include a cyclopentyl group, a cyclohexyl group, a methylcyclohexyl group, a dimethylcyclohexyl group, a cycloheptyl group, a cyclooctyl group, a norbornyl group, and an adamantyl group. The alicyclic hydrocarbon group optionally has a chain hydrocarbon group, and examples of the group include a methylcyclohexyl group and a dimethylcyclohexyl group. The alicyclic hydrocarbon group preferably has 3 to 12 carbon atoms, and more preferably 3 to 10 carbon atoms.

Examples of the aromatic hydrocarbon group include an aryl group such as a phenyl group, a naphthyl group, an anthryl group, a biphenyl group, and a phenanthryl group. The aromatic hydrocarbon group optionally has a chain hydrocarbon group or an alicyclic hydrocarbon group, and examples thereof include an aromatic hydrocarbon group having a chain hydrocarbon group with 1 to 18 carbon atoms (tolyl group, xylyl group, cumenyl group, mesityl group, p-methylphenyl group, p-ethylphenyl group, p-tert-butylphenyl group, 2,6-diethylphenyl group, 2-methyl-6-ethylphenyl group, and the like) and an aromatic hydrocarbon group having an alicyclic hydrocarbon group with 3 to 18 carbon atoms (p-cyclohexylphenyl group, p-adamantylphenyl group, and the like). The aromatic hydrocarbon group preferably has 6 to 14 carbon atoms, and more preferably 6 to 10 carbon atoms.

Examples of the alkyl group include a methyl group, an ethyl group, a propyl group, an isopropyl group, a butyl group, a sec-butyl group, a tert-butyl group, a pentyl group, a hexyl group, a heptyl group, a 2-ethylhexyl group, an octyl group, a nonyl group, a decyl group, an undecyl group, and a dodecyl group. The alkyl group preferably has 1 to 12 carbon atoms, more preferably 1 to 6 carbon atoms, and still more preferably 1 to 4 carbon atoms.

Examples of the alkyl group replaced with a hydroxy group include a hydroxyalkyl group such as a hydroxymethyl group and a hydroxyethyl group.

Examples of the aralkyl group include a benzyl group, a phenethyl group, a phenylpropyl group, a naphthylmethyl group, and a naphthylethyl group.

Examples of the group in which —CH₂— in the alkyl group is replaced with —O—, —SO₂—, or —CO— include an alkoxy group, an alkylsulfonyl group, an alkoxycarbonyl group, an alkylcarbonyl group, an alkylcarbonyloxy group, or a combination thereof.

Examples of the alkoxy group include a methoxy group, an ethoxy group, a propoxy group, a butoxy group, a pentyloxy group, a hexyloxy group, a heptyloxy group, an octyloxy group, a decyloxy group, and a dodecyloxy group. The alkoxy group preferably has 1 to 12 carbon atoms, more preferably 1 to 6 carbon atoms, and still more preferably 1 to 4 carbon atoms.

Examples of the alkylsulfonyl group include a methylsulfonyl group, an ethylsulfonyl group, and a propylsulfonyl group. The alkylsulfonyl group preferably has 1 to 12 carbon atoms, more preferably 1 to 6 carbon atoms, and still more preferably 1 to 4 carbon atoms.

Examples of the alkoxycarbonyl group include a methoxycarbonyl group, an ethoxycarbonyl group, and a butoxycarbonyl group. The alkoxycarbonyl group preferably has 2 to 12 carbon atoms, more preferably 2 to 6 carbon atoms, and still more preferably 2 to 4 carbon atoms.

Examples of the alkylcarbonyl group include an acetyl group, a propionyl group, and a butyryl group. The alkylcarbonyl group preferably has 2 to 12 carbon atoms, more preferably 2 to 6 carbon atoms, and still more preferably 2 to 4 carbon atoms.

Examples of the alkylcarbonyloxy group include an acetyloxy group, a propionyloxy group, and a butyryloxy group. The alkylcarbonyloxy group preferably has 2 to 12 carbon atoms, more preferably 2 to 6 carbon atoms, and still more preferably 2 to 4 carbon atoms.

Examples of the combined group include a group combining an alkoxy group with an alkyl group, a group combining an alkoxy group with an alkoxy group, a group combining an alkoxy group with an alkylcarbonyl group, and a group combining an alkoxy group with an alkylcarbonyloxy group.

Examples of the group combining an alkoxy group with an alkyl group include an alkoxyalkyl group such as a methoxymethyl group, a methoxyethyl group, an ethoxyethyl group, and an ethoxymethyl group. The alkoxyalkyl group preferably has 2 to 12 carbon atoms, more preferably 2 to 6 carbon atoms, and still more preferably 2 to 4 carbon atoms.

Examples of the group combining an alkoxy group with an alkoxy group include an alkoxyalkoxy group such as a methoxymethoxy group, a methoxyethoxy group, an ethoxymethoxy group, and an ethoxyethoxy group. The alkoxyalkoxy group preferably has 2 to 12 carbon atoms, more preferably 2 to 6 carbon atoms, and still more preferably 2 to 4 carbon atoms.

Examples of the group combining an alkoxy group with an alkylcarbonyl group include an alkoxyalkylcarbonyl group such as a methoxyacetyl group, a methoxypropionyl group, an ethoxyacetyl group, and an ethoxypropionyl group. The alkoxyalkylcarbonyl group preferably has 3 to 13 carbon atoms, more preferably 3 to 7 carbon atoms, and still more preferably 3 to 5 carbon atoms.

Examples of the group combining an alkoxy group with an alkylcarbonyloxy group include an alkoxyalkylcarbonyloxy group such as a methoxyacetyloxy group, a methoxypropionyloxy group, an ethoxyacetyloxy group, and an ethoxypropionyloxy group. The alkoxyalkylcarbonyloxy group preferably has 3 to 13 carbon atoms, more preferably 3 to 7 carbon atoms, and still more preferably 3 to 5 carbon atoms.

As the sulfonate anion represented by formula (bA), anions represented by formulas (bA-a-1) to (bA-a-14) are preferable.

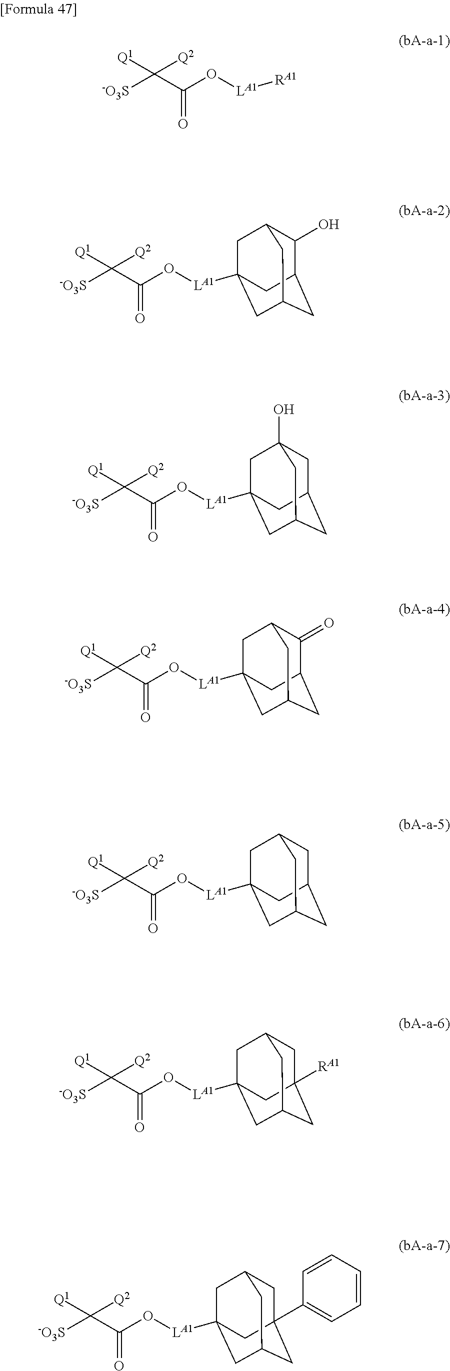

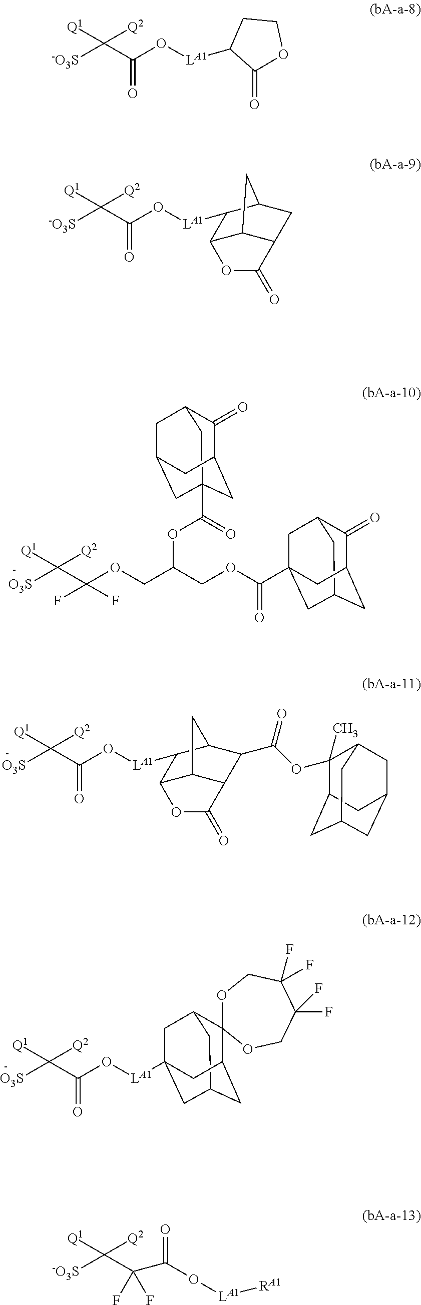

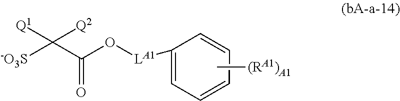

Herein, L^{bA1} is a single bond or an alkanediyl group having 1 to 4 carbon atoms. Q¹ and Q² have the same meaning as above. R^{A1} each independently represents an alkyl group having 1 to 6 carbon atoms.

Specific examples of the anion represented by formula (bA) include the anion disclosed in Japanese Patent Laid-Open No. 2010-204646.

Preferable examples of the sulfonate anion represented by formula (bA) include anions represented by formulas (bA-1) to (bA-27).

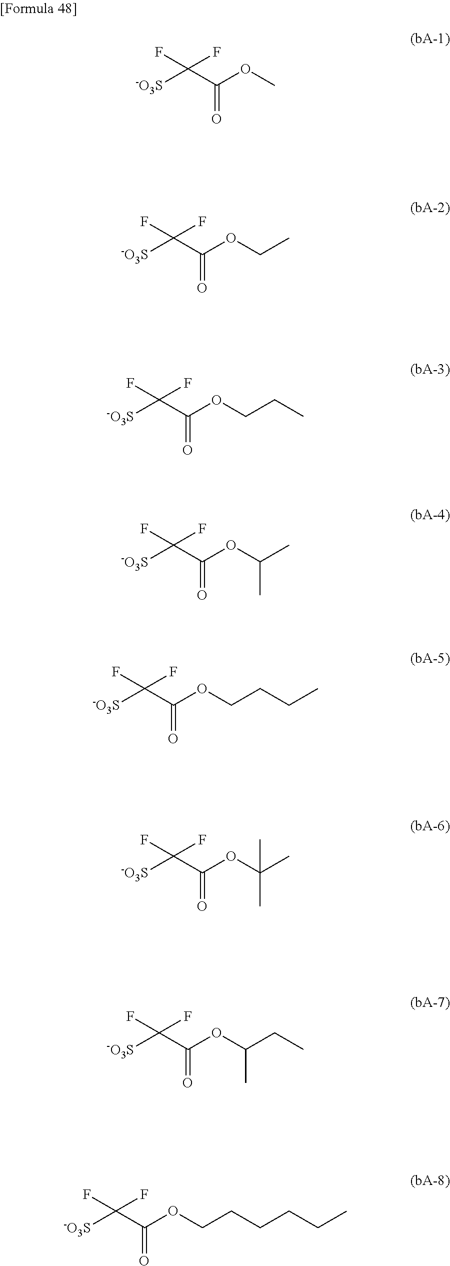

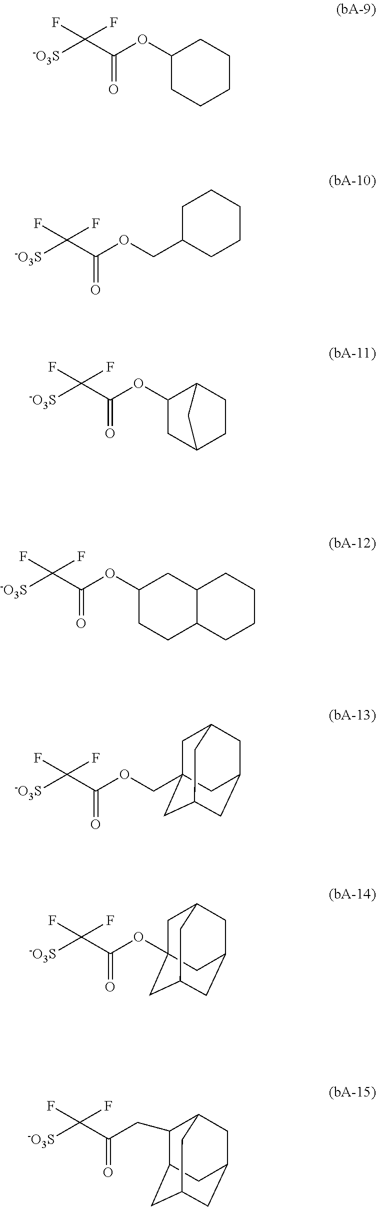

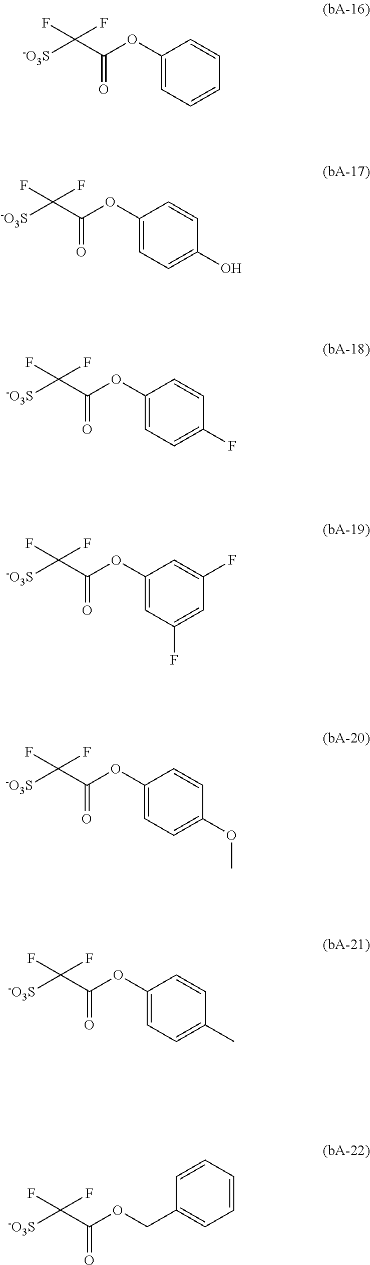

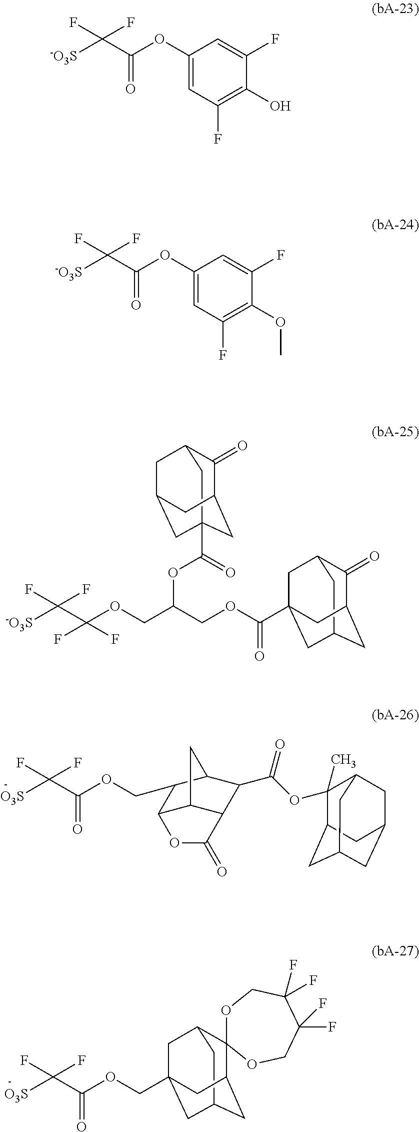

As the acid generator, the sulfonylimide anion shown below may be used instead of the sulfonate anion A⁻ of formula (b1).

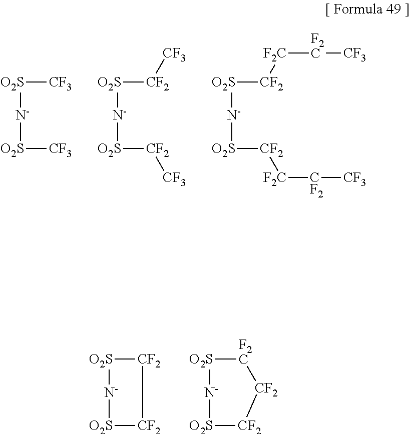 [SMILES: O=S(=O)([N-]S(=O)(=O)C(F)(F)F)C(F)(F)F ; O=S(=O)([N-]S(=O)(=O)C(F)(F)C(F)(F)F)C(F)(F)C(F)(F)F ; O=S(=O)([N-]S(=O)(=O)C(F)(F)C(F)(F)C(F)(F)C(F)(F)F)C(F)(F)C(F)(F)C(F)(F)C(F)(F)F ; O=S1(=O)[N-]S(=O)(=O)C(F)(F)C1(F)F ; O=S1(=O)[N-]S(=O)(=O)C(F)(F)C(F)(F)C1(F)F]

As the anion represented by A⁻, a sulfonylmethide anion shown below may be used.

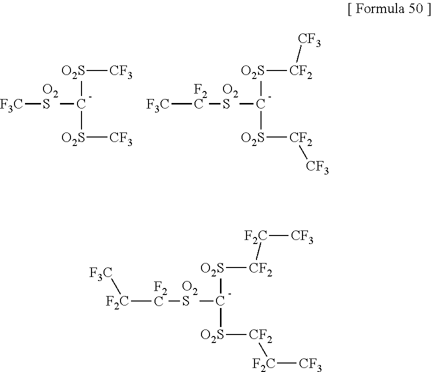 [SMILES: O=S(=O)(C(S(=O)(=O)C(F)(F)F)S(=O)(=O)C(F)(F)F)C(F)(F)F ; O=S(=O)(C(S(=O)(=O)C(F)(F)C(F)(F)F)S(=O)(=O)C(F)(F)C(F)(F)F)C(F)(F)C(F)(F)F ; O=S(=O)(C(S(=O)(=O)C(F)(F)C(F)(F)C(F)(F)F)S(=O)(=O)C(F)(F)C(F)(F)C(F)(F)F)C(F)(F)C(F)(F)C(F)(F)F]

As the anion represented by A⁻, a carboxylate anion shown below may be used.

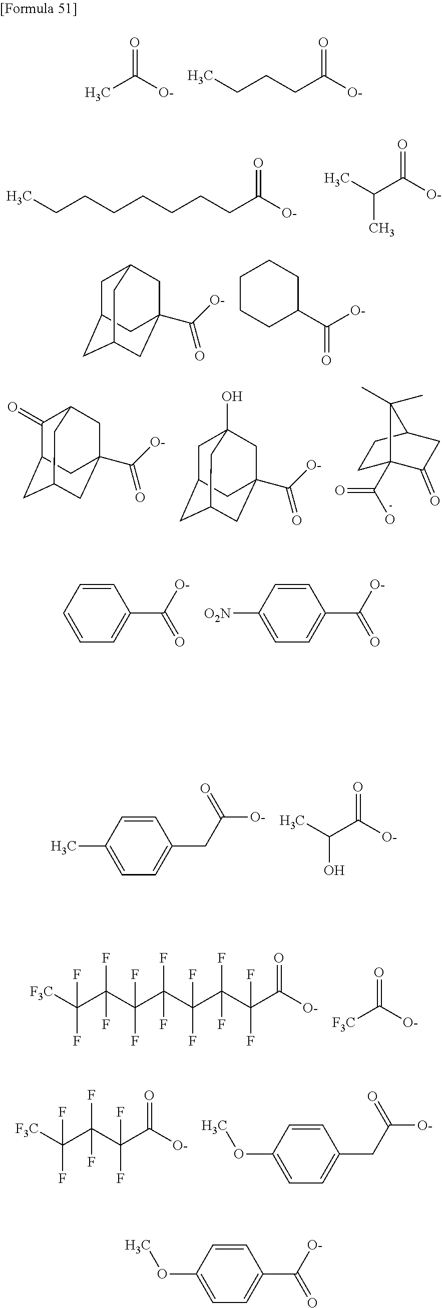

The acid generator represented by formula (b1) is, for example, a combination of the above organic cation and a sulfonate anion. The acid generator represented by formula (b1) can be synthesized, for example, by the method disclosed in Japanese Patent Laid-Open No. 2021-56504.

In the resist composition of the present invention, the content ratio of the acid generator is preferably 0.1 parts by mass or more and 40 parts by mass or less, more preferably 0.5 parts by mass or more and 30 parts by mass or less, still more preferably 1 parts by mass or more and 20 parts by mass or less, and even more preferably 1 parts by mass or more and 5 parts by mass or less, with respect to 100 parts by mass of resin (A). The resist composition of the present invention may contain acid generator (B) singly or in combinations.

### <Solvent (D)>

The content ratio of solvent (D) in the resist composition is typically 45% by mass or more, preferably 50% by mass or more, more preferably 55% by mass or more, and typically 99.9% by mass or less, preferably 99% by mass or less, more preferably 90% by mass or less. The content ratio of solvent (D) can be measured by known analysis means such as liquid chromatography or gas chromatography.

Examples of solvent (D) include: glycol ether esters such as ethyl cellosolve acetate, methyl cellosolve acetate, and propylene glycol monomethyl ether acetate; glycol ethers such as propylene glycol monomethyl ether; esters such as ethyl lactate, butyl acetate, amyl acetate, and ethyl pyruvate; ketones such as acetone, methyl isobutyl ketone, 2-heptanone, and cyclohexanone; and cyclic esters such as γ-butyrolactone. Solvent (D) may be contained singly or in combination of two or more.

### <Quencher (C)>

The quencher in the resist composition of the present invention may be a compound that has an acid diffusion suppressing effect, that is, an effect of trapping the acid generated from the acid generator upon exposure, and may be a compound that can generate an acid by itself in addition to this effect. Examples of quencher (C) include a basic nitrogen-containing organic compound and weak acid salt.

Examples of the basic nitrogen-containing organic compound include an amine and an ammonium salt. Examples of the amine include an aliphatic amine and an aromatic amine. Examples of the aliphatic amine include a primary amine, a secondary amine, and a tertiary amine.

Examples of the amine include compounds represented by any of formulas (C1) to (C8) and (C1-1), and preferably the compound represented by formula (C1-1).

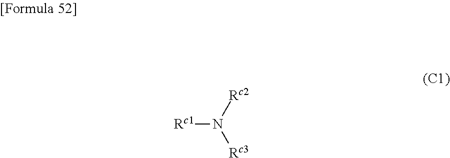

[In formula (C1), R^{c1}, R^{c2}, and R^{c3} each independently represent a hydrogen atom, an alkyl group having 1 to 6 carbon atoms, an alicyclic hydrocarbon group having 5 to 10 carbon atoms, or an aromatic hydrocarbon group having 6 to 10 carbon atoms, and the hydrogen atoms included in the alkyl group and the alicyclic hydrocarbon group are optionally replaced with a hydroxy group, an amino group, or an alkoxy group having 1 to 6 carbon atoms, and the hydrogen atom included in the aromatic hydrocarbon group is optionally replaced with an alkyl group having 1 to 6 carbon atoms, an alkoxy group having 1 to 6 carbon atoms, an alicyclic hydrocarbon group having 5 to 10 carbon atoms, or an aromatic hydrocarbon group having 6 to 10 carbon atoms]

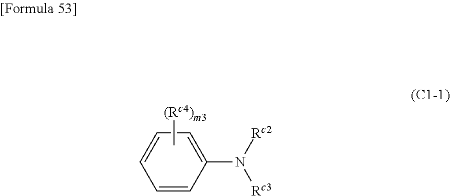

[In formula (C1-1), R^{c2} and R^{c3} have the same meaning as above.

R^{c4} represents an alkyl group having 1 to 6 carbon atoms, an alkoxy group having 1 to 6 carbon atoms, an alicyclic hydrocarbon group having 5 to 10 carbon atoms, or an aromatic hydrocarbon group having 6 to 10 carbon atoms.

m3 represents an integer of 0 to 3, and when m3 is 2 or more, a plurality of R^{c4}s are the same or different from each other]

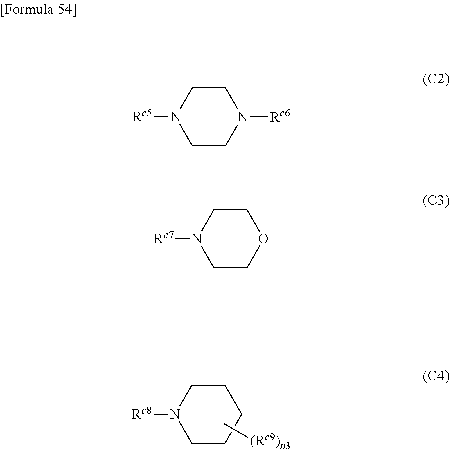

[In formula (C2), formula (C3), and formula (C4), R^{c5}, R^{c6}, R^{c7}, and R^{c8} each independently have the same meaning as R^{c1}.

R^{c9} represents an alkyl group having 1 to 6 carbon atoms, an alicyclic hydrocarbon group having 3 to 6 carbon atoms, or an alkanoyl group having 2 to 6 carbon atoms.

n3 represents an integer of 0 to 8, and when n3 is 2 or more, a plurality of R^{c9}s are the same or different from each other]

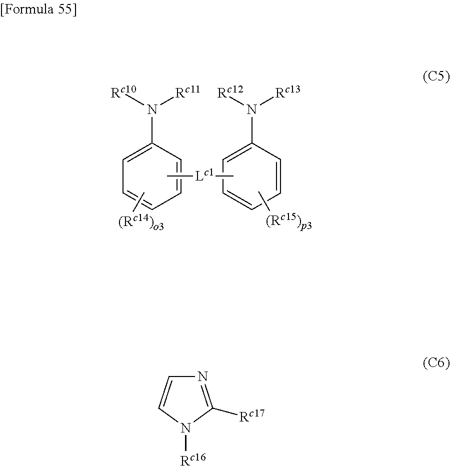

[In formula (C5) and formula (C6), R^{c10}, R^{c11}, R^{c12}, R^{c13}, and R^{c16} each independently represent the same as R^{c1}.

R^{c14}, R^{c15}, and R^{c17} each independently represent the same as R^{c4}.

o3 and p3 each independently represent an integer of 0 to 3, and when o3 is 2 or more, a plurality of R^{c14}s are the same or different from each other, and when p3 is 2 or more, a plurality of R^{c15}s are the same or different from each other.

L^{c1} represents an alkanediyl group having 1 to 6 carbon atoms, —CO—, —C(═NH)—, —S—, or a divalent group formed by combining these]

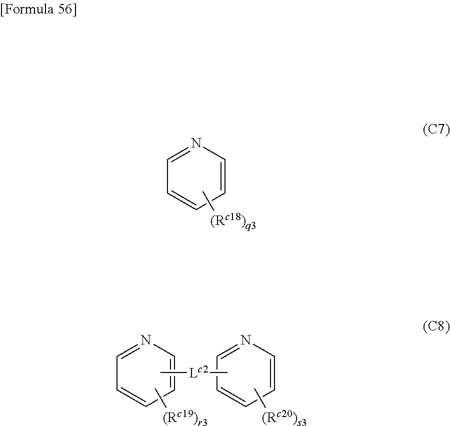

[In formula (C7) and formula (C8), R^{c1}, R^{c19}, and R^{c20} each independently represent the same as R^{c4}.

q3, r3, and s3 each independently represent an integer of 0 to 3, when q3 is 2 or more, a plurality of R^{c18}s are the same or different from each other, when r3 is 2 or more, a plurality of R^{c19}s are the same or different from each other, and when s3 is 2 or more, a plurality of R^{c20}s are the same or different from each other.

L^{c2} represents a single bond, an alkanediyl group having 1 to 6 carbon atoms, —CO—, —C(═NH)—, —S—, or a divalent group formed by combining these]

In formulas (C1) to (C8) and (C1-1), an alkyl group, an alicyclic hydrocarbon group, an aromatic hydrocarbon group, an alkoxy group, and an alkanediyl group are the same as those described above.

Examples of the alkanoyl group include an acetyl group, a 2-methylacetyl group, a 2,2-dimethylacetyl group, a propionyl group, a butyryl group, an isobutyryl group, a pentanoyl group, and a 2,2-dimethylpropionyl group.

The compound represented by formula (C1) includes 1-naphthylamine, 2-naphthylamine, aniline, diisopropylaniline, 2-, 3- or 4-methylaniline, 4-nitroaniline, N-methylaniline, N,N-dimethylaniline, diphenylamine, hexylamine, heptylamine, octylamine, nonylamine, decylamine, dibutylamine, dipentylamine, dihexylamine, diheptylamine, dioctylamine, dinonylamine, didecylamine, triethylamine, trimethylamine, tripropylamine, tributylamine, tripentylamine, trihexylamine, triheptylamine, trioctylamine, trinonylamine, tridecylamine, methyl dibutylamine, methyl dipentylamine, methyl dihexylamine, methyl dicyclohexylamine, methyl diheptylamine, methyl dioctylamine, methyl dinonylamine, methyl didecylamine, ethyl dibutylamine, ethyl dipentylamine, ethyl dihexylamine, ethyl diheptylamine, ethyl dioctylamine, ethyl dinonylamine, ethyl didecylamine, dicyclohexylmethylamine, tris[2-(2-methoxyethoxy)ethyl]amine, triisopropanolamine, ethylenediamine, tetramethylenediamine, hexamethylenediamine, 4,4′-diamino-1,2-diphenylethane, 4,4′-diamino-3,3′-dimethyldiphenylmethane, and 4,4′-diamino-3,3′-diethyldiphenylmethane, and diisopropylaniline is preferable, and 2,6-diisopropylaniline is particularly preferable.

Examples of the compound represented by formula (C2) include piperazine.

Examples of the compound represented by formula (C3) include morpholine.

Examples of the compound represented by formula (C4) include piperidine and a hindered amine compound having a piperidine skeleton as disclosed in Japanese Patent Laid-Open No. H11-52575.

Examples of the compound represented by formula (C5) include 2,2′-methylenebisaniline.

Examples of the compound represented by formula (C6) include imidazole and 4-methylimidazole.

Examples of the compound represented by formula (C7) include pyridine and 4-methylpyridine.

Examples of the compound represented by formula (C8) include 1,2-di(2-pyridyl)ethane, 1,2-di(4-pyridyl)ethane, 1,2-di(2-pyridyl)ethene, 1,2-di(4-pyridyl)ethene, 1,3-di(4-pyridyl)propane, 1,2-di(4-pyridyloxy)ethane, di(2-pyridyl)ketone, 4,4′-dipyridyl sulfide, 4,4′-dipyridyl disulfide, 2,2′-dipyridylamine, 2,2′-dipicolylamine, and bipyridine.

Examples of the ammonium salt include tetramethylammonium hydroxide, tetraisopropylammonium hydroxide, tetrabutylammonium hydroxide, tetrahexylammonium hydroxide, tetraoctylammonium hydroxide, phenyltrimethylammonium hydroxide, 3-(trifluoromethyl) phenyltrimethylammonium hydroxide, tetra-n-butylammonium salicylate, and choline.

Examples of the weak acid salt include a salt of acid weaker than an acid generated by the acid generator (B), such as a carboxylate and a sulfonate, and from another viewpoint, an intramolecular salt, preferably a salt represented by formula (C10).

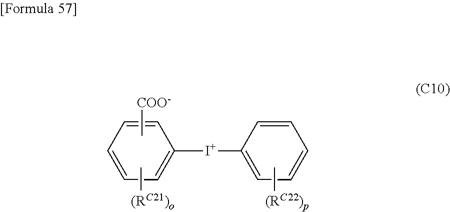

[In formula (C10),

o and p each independently represent an integer of 0 to 4.

R^{c21} and R^{c22} each independently represent a hydrocarbon group having 1 to 12 carbon atoms, an alkoxy group having 1 to 6 carbon atoms, an acyl group having 2 to 7 carbon atoms, an acyloxy group having 2 to 7 carbon atoms, an alkoxycarbonyl group having 2 to 7 carbon atoms, a nitro group, or a halogen atom.

When o is 2 or more, a plurality of R^{c21}s are the same or different from each other.

When p is 2 or more, a plurality of R^{c22}s are the same or different from each other]

Examples of the compound represented by formula (C10) include the following compound.

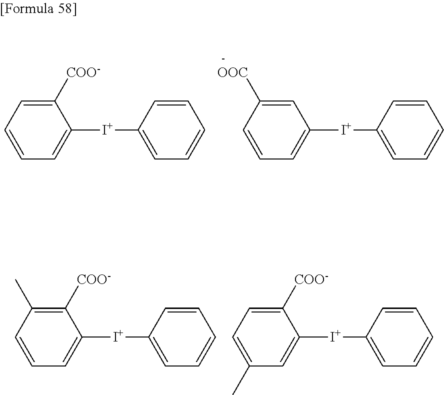

The content ratio of quencher (C) in the solid content of the resist composition is preferably 0.0001 to 5% by mass, more preferably 0.0001 to 4% by mass, still more preferably 0.001 to 3% by mass, and even more preferably 0.01 to 1.0% by mass.

### <Other Components>

The resist composition of the present invention may contain components other than those described above (hereinafter, may be referred to as “other components (F)”) as necessary. Other components (F) are not particularly limited, and an additive known in the resist field, such as a sensitizer, a dissolution inhibitor, a surfactant, a stabilizer, and a dye can be used.

When other components (F) are used, the content thereof is appropriately selected depending on the type of other components (F).

### 2. Preparation of Resist Composition

The resist composition of the present invention can be prepared by mixing resin (A1), resin (A2), acid generator (B), and, as necessary, resins other than resins (A1) and (A2), quencher (C), solvent (D), and other components (F). The order of mixing is arbitrary and is not particularly limited. An appropriate temperature for mixing can be selected from 10 to 40° C. depending on the type of resin and the like and the solubility of the resin and the like in solvent (D). An appropriate mixing time can be selected from 0.5 to 24 hours depending on the mixing temperature. The mixing means are not particularly limited, and stirring and mixing and the like can be used.

After mixing the components, filtration is preferable performed using a filter with a pore size of about 0.003 to 50 μm.

### 3. Method for Producing Resist Pattern

The method for producing a resist pattern of the present invention includes:
(1) a step of applying the resist composition of the present invention onto a substrate;
(2) a step of drying the applied resist composition to form a composition layer;
(3) a step of exposing the composition layer;
(4) a step of heating the exposed composition layer; and
(5) a step of developing the heated composition layer.

The resist composition can be applied onto a substrate by a commonly used apparatus such as a spin coater. Examples of the substrate include a silicon wafer. Before applying the resist composition, the substrate may be washed, and an anti-reflective film or the like may be formed on the substrate.

The applied composition is dried to remove a solvent and form a composition layer. Drying is performed, for example, by evaporating the solvent using a heating device such as a hot plate (so-called pre-baking), or by using a vacuum device. The heating temperature is preferably 50 to 200° C., and the heating time is preferably 30 to 600 seconds. In addition, the pressure during reduced pressure drying is preferably around 1 to 1.0×10⁵ Pa.

After drying, the film thickness of the composition obtained is preferably 1 to 30 μm, more preferably 1.5 to 20 μm.

The obtained composition layer is typically exposed using an exposure machine. Various types of exposure light sources can be used, such as: light sources that emit ultraviolet laser light such as KrF excimer laser (wavelength 248 nm), ArF excimer laser (wavelength 193 nm), and F₂ excimer laser (wavelength 157 nm); light sources that convert the wavelength of laser light from a solid-state laser light source (YAG or semiconductor laser) to emit harmonic laser light in the far ultraviolet or vacuum ultraviolet range; and light sources that irradiate electron beams or extreme ultraviolet light (EUV). In the present specification, irradiation with these types of radiation may be collectively referred to as “exposure”. During exposure, exposure is typically performed through a mask that corresponds to the desired pattern. When the exposure light source is an electron beam, exposure may be performed by direct drawing without using a mask.

The composition layer after exposure may be subjected to a heat treatment (so-called post-exposure bake) to promote the elimination reaction of the acid labile group of the resin (A). The heating temperature is typically approximately 50 to 200° C., preferably approximately 70 to 150° C. The heating time is typically 40 to 400 seconds, preferably 50 to 350 seconds.

The composition layer after heating is typically developed using a developing apparatus and a developer. The development methods include a dipping method, a paddle method, a spray method, a dynamic dispensing method, and the like. The development temperature is preferably, for example, 5 to 60° C., and the development time is preferably, for example, 5 to 600 seconds. Selecting the type of the developer as follows allows a positive resist pattern or a negative resist pattern to be produced.

When producing a positive resist pattern from the resist composition of the present invention, an alkaline developer is used as the developer. The alkaline developer may be any of the various alkaline aqueous solutions used in this field. Examples thereof include an aqueous solution of tetramethylammonium hydroxide of (2-hydroxyethyl)trimethylammonium hydroxide (commonly known as choline). The alkaline developer may include a surfactant.

It is preferable to wash the developed resist pattern with ultrapure water, and then remove water remaining on the substrate and the pattern.

When producing a negative resist pattern from the resist composition of the present invention, a developer including an organic solvent (hereinafter, may be referred to as an “organic developer”) is used as the developer.

Examples of the organic solvent included in the organic developer include: ketone solvents such as 2-hexanone and 2-heptanone; glycol ether ester solvents such as propylene glycol monomethyl ether acetate; ester solvents such as butyl acetate; glycol ether solvents such as propylene glycol monomethyl ether; amide solvents such as N,N-dimethylacetamide; and aromatic hydrocarbon solvents such as anisole.

The content rate of the organic solvent in the organic developer is preferably 90% by mass or more and 100% by mass or less, more preferably 95% by mass or more and 100% by mass or less, and still more preferably substantially only organic solvent.

Among these, a developer including butyl acetate and/or 2-heptanone is preferable as the organic developer. The total content rate of butyl acetate and 2-heptanone in the organic developer is preferably 50% by mass or more and 100% by mass or less, more preferably 90% by mass or more and 100% by mass or less, and still more preferably substantially only butyl acetate and/or 2-heptanone.

The organic developer may include a surfactant. In addition, the organic developer may include a trace amount of water.

During the development, the development may be stopped by replacing the organic developer with a different type of solvent.

It is preferable to wash the developed resist pattern with a rinse solution. The rinse solution is not particularly limited as long as it does not dissolve the resist pattern, and a solution including a general organic solvent can be used, preferably an alcohol solvent or an ester solvent.

After washing, it is preferable to remove the rinse solution remaining on the substrate and pattern.

Exposing the resist obtained using the resist composition of the present invention allows a resist pattern with a highly accurate shape to be formed.

### 4. Uses

The resist composition of the present invention is useful as a resist composition for KrF excimer laser exposure, a resist composition for electron beam (EB) irradiation, or a resist composition for EUV exposure. In particular, the resist composition of the present invention is useful as a resist composition for KrF excimer laser exposure, and further, the composition of the present invention can produce an excellent resist pattern in a resist film with a thickness of 1 to 20 μm, and thus is useful as a resist composition for producing three-dimensional structure devices.

### EXAMPLES

The present invention will be explained in more detail with reference to Examples. In the Examples, “%” and “parts” indicating the content or amount used are based on mass unless otherwise specified.

The weight average molecular weight is the value determined by gel permeation chromatography under the following conditions.
Column: TSKgel Multipore H_{XL}-M×3+guardcolumn (Tosoh Corporation)
Eluent: Tetrahydrofuran
Flow rate: 1.0 mL/min
Detector: RI detector
Column temperature: 40° C.
Injection volume: 100 μl
Molecular weight standard: Standard polystyrene (Tosoh Corporation)

### Synthesis Example 1 [Synthesis of Acid Generator (B-1)]

The compound represented by the following formula was synthesized by the method disclosed in Japanese Patent Laid-Open No. 2021-56504.

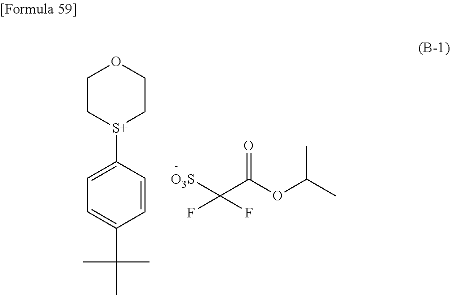

### Synthesis Example 2 [Synthesis of Acid Generator (B-2)]

The compound represented by the following formula was synthesized by the method disclosed in Japanese Patent Laid-Open No. 2016-130240.

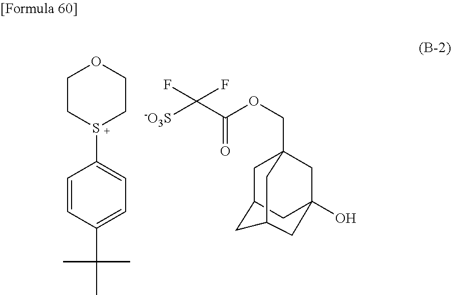

### Synthesis Example 3 [Synthesis of Acid Generator (B-3)]

The compound represented by the following formula was synthesized by the method disclosed in Japanese Patent Laid-Open No. 2021-56504.

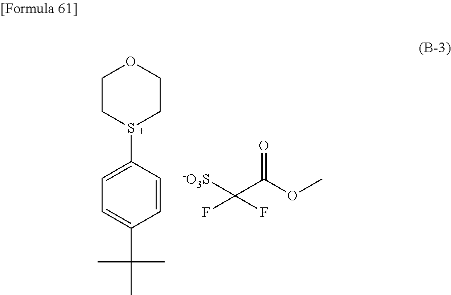

### Synthesis Example 4 [Synthesis of Acid Generator (B-X)]

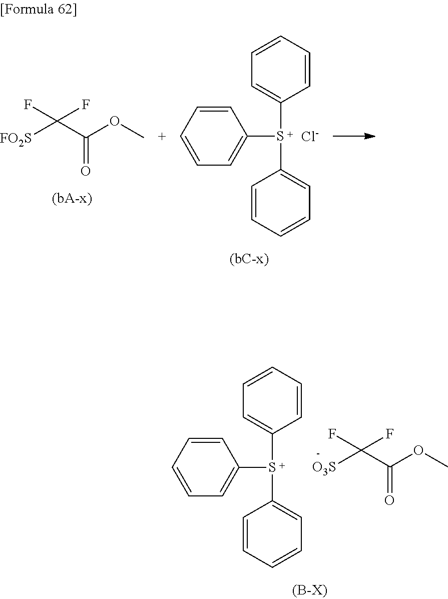

A mixed solution of 10.64 parts of triethylamine, 0.95 parts of ion-exchanged water, and 30.30 parts of chloroform was stirred on an ice bath, and a solution of 10.10 parts of a compound represented by formula (bA-x) dissolved in 31.25 parts of chloroform was dropped therein over 30 minutes, and further stirred at 23° C. for 1 hour. 76.52 parts of an aqueous solution (13.1%) containing a salt represented by formula (bC-x) was added to the obtained mixed solution at room temperature, stirred for 15 hours, concentrated, and then 85.01 parts of chloroform was added, and the organic layer was recovered by separation. 21 parts of ion-exchanged water was added to the recovered organic layer, stirred, and then separated, and the organic layer was recovered. This water washing was performed 8 times. 45.51 parts of tert-butyl methyl ether was added to the obtained concentrate, stirred, and filtered. 47 parts of ion-exchanged water was added to the obtained slurry, stirred, and filtered to provide 6.45 parts of a salt represented by formula (B-X). (Yield relative to the compound represented by formula (bA-x) is 27%)

### Synthesis of Resins (A1) and (A2)

The compounds (monomers) used in the synthesis of resins (A1) and (A2) are shown below.

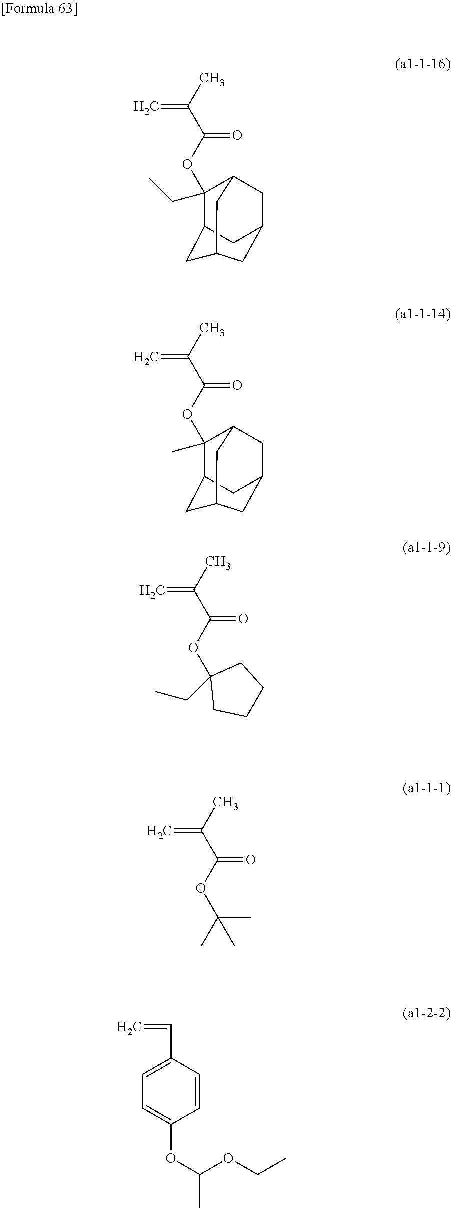

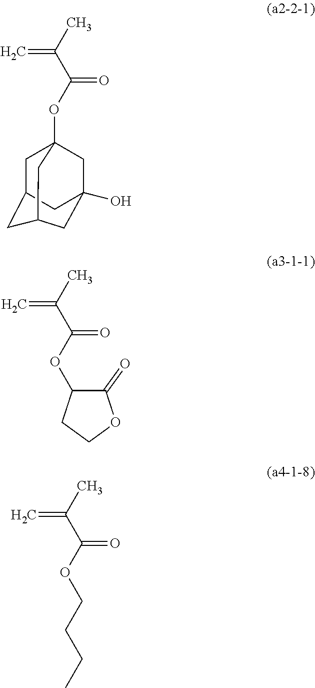

Hereinafter, the compounds are referred to as “monomer (a1-1-1)” and the like according to the formula symbol.

### Synthesis Example 5 [Synthesis of Resin (A1-1)]

Monomer (a1-1-16), monomer (a1-1-9), monomer (a2-2-1), monomer (a3-1-1), and monomer (a1-1-1) were charged in a molar ratio of 5:40:10:30:15. Then, propylene glycol monomethyl ether acetate was added in an amount of 2.0 times the total mass of all monomers. To the resulting mixture, azobisisobutyronitrile and azobis(2,4-dimethylvaleronitrile) were added as initiators in proportions of 0.7 mol % and 2.1 mol % with respect to the total molar number of all monomers, respectively, and the mixture was heated at 75° C. for approximately 5 hours. The reaction solution was then poured into a large amount of a mixed solvent of methanol and water (4:1) to cause precipitation three times, and purified to provide a copolymer with a weight-average molecular weight of approximately 11.8×10³ in a yield of 89%.

This copolymer has the following structural unit, and is designated as resin (A1-1).

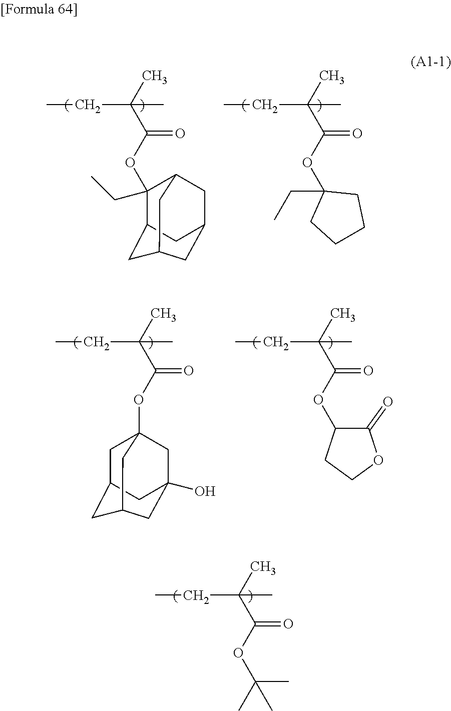

### Synthesis Example 6 [Synthesis of Resin (A1-2)]

Monomer (a1-1-14), monomer (a1-1-9), monomer (a2-2-1), monomer (a3-1-1), and monomer (a4-1-8) were charged in a molar ratio of 5:40:10:30:15. Then, propylene glycol monomethyl ether acetate was added in an amount of 1.5 times the total mass of all monomers. To the resulting mixture, azobisisobutyronitrile and azobis(2,4-dimethylvaleronitrile) were added as initiators in proportions of 0.75 mol % and 2.25 mol % with respect to the total molar number of all monomers, respectively, and the mixture was heated at 75° C. for approximately 5 hours. The reaction solution was then poured into a large amount of a mixed solvent of methanol and water (4:1) to cause precipitation three times, and purified to provide a copolymer with a weight-average molecular weight of approximately 15.6×10³ in a yield of 93%. This copolymer has the following structural unit, and is designated as resin (A1-2).

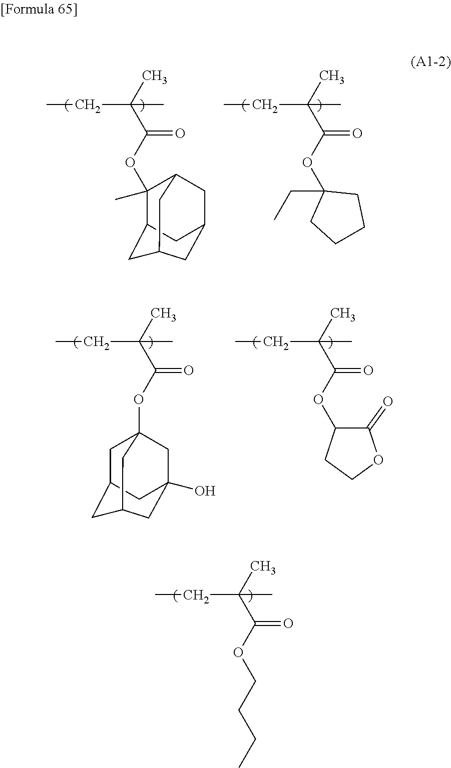

### Synthesis Example 7 [Synthesis of Resin (A1-3)]

Monomer (a1-1-16), monomer (a1-1-9), monomer (a2-2-1), monomer (a3-1-1), and monomer (a1-1-1) were charged in a molar ratio of 5:40:10:30:15. Then, propylene glycol monomethyl ether acetate was added in an amount of 1.5 times the total mass of all monomers. To the resulting mixture, azobisisobutyronitrile and azobis(2,4-dimethylvaleronitrile) were added as initiators in proportions of 0.4 mol % and 1.2 mol % with respect to the total molar number of all monomers, respectively, and the mixture was heated at 65° C. for approximately 5 hours. The reaction solution was then poured into a large amount of a mixed solvent of methanol and water (4:1) to cause precipitation three times, and purified to provide a copolymer with a weight-average molecular weight of approximately 24.7×10³ in a yield of 89%. This copolymer has the following structural unit, and is designated as resin (A1-3).

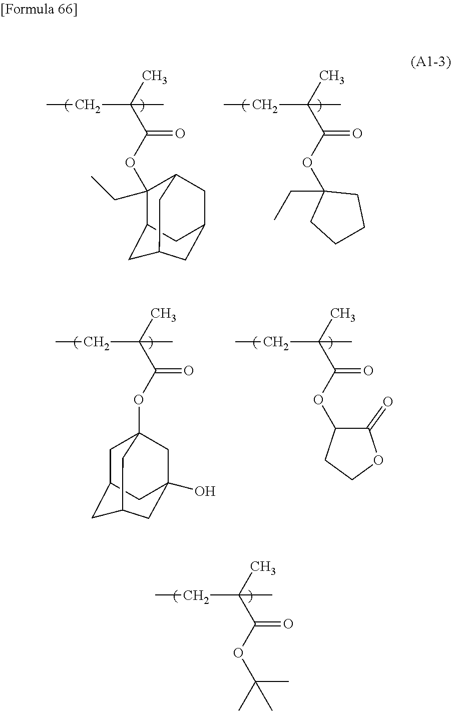

### Synthesis Example 8 [Synthesis of Resin (A1-4)]

Monomer (a1-1-9), monomer (a2-2-1), monomer (a3-1-1), and monomer (a1-1-1) were charged in a molar ratio of 45:10:30:15. Then, propylene glycol monomethyl ether acetate was added in an amount of 1.5 times the total mass of all monomers. To the resulting mixture, azobisisobutyronitrile and azobis(2,4-dimethylvaleronitrile) were added as initiators in proportions of 0.6 mol % and 1.8 mol % with respect to the total molar number of all monomers, respectively, and the mixture was heated at 65° C. for approximately 5 hours. The reaction solution was then poured into a large amount of a mixed solvent of methanol and water (4:1) to cause precipitation three times, and purified to provide a copolymer with a weight-average molecular weight of approximately 19.9×10³ in a yield of 92%. This copolymer has the following structural unit, and is designated as resin (A1-4).

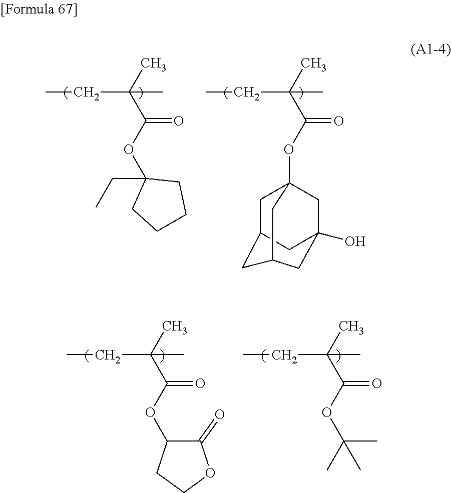

### Synthesis Example 9 [Synthesis of Resin (A1-5)]

Monomer (a1-1-16), monomer (a1-1-9), monomer (a2-2-1), and monomer (a3-1-1) were charged in a molar ratio of 5:55:10:30. Then, propylene glycol monomethyl ether acetate was added in an amount of 1.5 times the total mass of all monomers. To the resulting mixture, azobisisobutyronitrile and azobis(2,4-dimethylvaleronitrile) were added as initiators in proportions of 0.6 mol % and 1.8 mol % with respect to the total molar number of all monomers, respectively, and the mixture was heated at 65° C. for approximately 5 hours. The reaction solution was then poured into a large amount of a mixed solvent of methanol and water (4:1) to cause precipitation three times, and purified to provide a copolymer with a weight-average molecular weight of approximately 21.3×10³ in a yield of 85%. This copolymer has the following structural unit, and is designated as resin (A1-5)

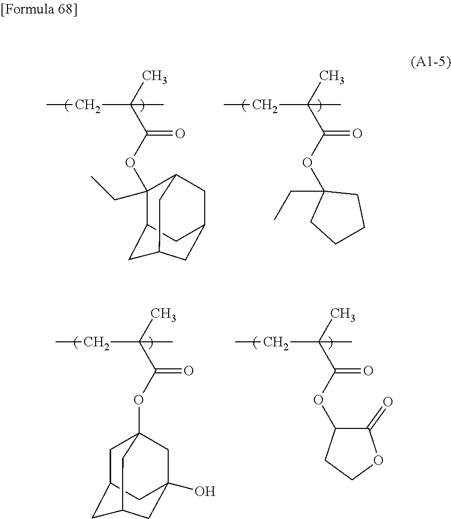

### Synthesis Example 10 [Synthesis of Resin (A2-1)]

Monomer (a1-2-2), monomer (a1-1-16), and monomer (a1-1-1) were charged in a molar ratio of 70:15:15. Then, 1.5 times the mass of propylene glycol monomethyl ether acetate was added with respect to the total mass of all monomers. Azobisisobutyronitrile was added as an initiator to the resulting mixture in an amount of 0.7 mol % with respect to the total moles of all monomers, and the mixture was heated at 75° C. for approximately 5 hours. Thereafter, an aqueous solution of p-toluenesulfonic acid was added to the polymerization reaction solution, and the mixture was stirred for 6 hours, and then separated. The obtained organic layer was poured into a large amount of methanol to precipitate the resin, which was then filtered and collected to provide a copolymer with a weight-average molecular weight of approximately 36.3×10³ in a yield of 46%. This copolymer has the following structural unit, and is designated as resin (A2-1).

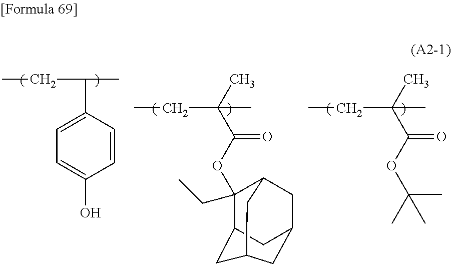

### Synthesis Example 11 [Synthesis of Resin (A2-X)]

30 parts of polyvinylphenol (“VP-30000” manufactured by Nippon Soda Co., Ltd.) and 360 parts of methyl isobutyl ketone were charged, and then 1.75 parts of a 0.2% p-toluenesulfonic acid solution in methyl isobutyl ketone was added and stirred, followed by concentration to provide 120 parts of a methyl isobutyl ketone solution. 6.45 parts of ethyl vinyl ether was added dropwise to this solution and stirred for 3 hours. Thereafter, 50 parts of ion-exchanged water and 0.005 parts of triethylamine were added to the reaction solution, and the mixture was stirred and separated. Then, 50 parts of ion-exchanged water was added to the organic layer and the separation was repeated four times. After washing, the organic layer was concentrated, and 260 parts of propylene glycol monomethyl ether acetate was added and concentrated again to provide 120 parts of a propylene glycol monomethyl ether acetate solution of resin A2-1 (27% solids). The weight-average molecular weight of resin (A2-X) was 39.3×10³, and the protection rate of the ethoxyethyl group was 31.5%. This copolymer has the following structural unit, and is designated as the resin (A2-X).

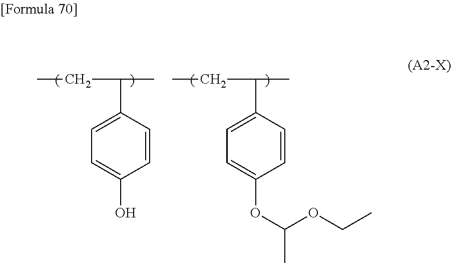

### <Preparation of Resist Composition>

The components shown in Table 1 were mixed and dissolved to provide a mixture, which was then filtered through a fluororesin filter with a pore size of 5 μm to prepare a resist composition.

TABLE 1

| Resist | Resin (A1) and | | | |
|---|---|---|---|---|
| composition | Resin (A2) | Acid generator (B) | Quencher (C) | Solvent (D) |
| Composition 1 | (A1-1) = 8.40 parts | (B-1) = 0.206 parts | (C-1) = 0.01 parts | (D-1) = 18.0 |
| | (A2-1) = 5.60 parts | | | (D-2) = 0.3 |
| | | | | (D-3) = 8.0 |
| | | | | (D-4) = 0.5 |
| Composition 2 | (A1-2) = 11.2 parts | (B-1) = 0.103 parts | (C-1) = 0.01 parts | (D-1) = 9.0 |
| | (A2-1) = 2.8 parts | (B-2) = 0.123 parts | | (D-2) = 0.3 |
| | | | | (D-3) = 14.0 |
| | | | | (D-4) = 0.3 |
| Composition 3 | (A1-2) = 8.4 parts | (B-1) = 0.103 parts | (C-1) = 0.01 parts | (D-1) = 9.0 |
| | (A2-1) = 5.6 parts | (B-2) = 0.123 parts | | (D-2) = 0.3 |
| | | | | (D-3) = 14.0 |
| | | | | (D-4) = 0.3 |
| Composition 4 | (A1-2) = 5.6 parts | (B-1) = 0.103 parts | (C-1) = 0.01 parts | (D-1) = 15.0 |
| | (A2-1) = 8.4 parts | (B-2) = 0.123 parts | | (D-2) = 0.3 |
| | | | | (D-3) = 11.0 |
| | | | | (D-4) = 0.3 |
| Composition 5 | (A1-3) = 8.4 parts | (B-1) = 0.206 parts | (C-1) = 0.01 parts | (D-1) = 11.0 |
| | (A2-1) = 5.6 parts | | | (D-2) = 0.3 |
| | | | | (D-3) = 16.0 |
| | | | | (D-4) = 0.3 |
| Composition 6 | (A1-4) = 8.4 parts | (B-1) = 0.206 parts | (C-1) = 0.01 parts | (D-1) = 10.5 |
| | (A2-1) = 5.6 parts | | | (D-2) = 0.3 |
| | | | | (D-3) = 15.0 |
| | | | | (D-4) = 0.3 |
| Composition 7 | (A1-1) = 8.40 parts | (B-3) = 0.206 parts | (C-1) = 0.01 parts | (D-1) = 18.0 |
| | (A2-1) = 5.60 parts | | | (D-2) = 0.3 |
| | | | | (D-3) = 8.0 |
| | | | | (D-4) = 0.5 |
| Composition 8 | (A1-5) = 8.4 parts | (B-1) = 0.206 parts | (C-1) = 0.01 parts | (D-1) = 10.5 |
| | (A2-1) = 5.6 parts | | | (D-2) = 0.3 |
| | | | | (D-3) = 15.0 |
| | | | | (D-4) = 0.3 |
| Comparative | (A1-1) = 8.4 parts | (B-X) = 0.206 parts | (C-1) = 0.01 parts | (D-1) = 13.3 |
| Example | (A2-1) = 5.6 parts | | | (D-2) = 0.3 |
| composition 1 | | | | (D-3) = 6.0 |
| | | | | (D-4) = 0.3 |
| Comparative | (A1-1) = 8.4 parts | (B-1) = 0.206 parts | (C-1) = 0.01 parts | (D-1) = 13.3 |
| Example | (A2-X) = 5.6 parts | | | (D-2) = 0.3 |
| composition 2 | | | | (D-3) = 6.0 |
| | | | | (D-4) = 0.3 |
| Comparative | (A2-1) = 14.0 parts | (B-1) = 0.206 parts | (C-1) = 0.01 parts | (D-1) = 21.5 |
| Example | | | | (D-2) = 0.3 |
| composition 3 | | | | (D-3) = 10.3 |
| | | | | (D-4) = 0.8 |
| Comparative | (A1-2) = 14.0 parts | (B-1) = 0.206 parts | (C-1) = 0.01 parts | (D-1) = 12.0 |
| Example | | | | (D-2) = 0.3 |
| composition 4 | | | | (D-3) = 10.3 |
| | | | | (D-4) = 0.8 |

### <Resin>

(A1-1): Resin (A1-1)
(A1-2): Resin (A1-2)
(A1-3): Resin (A1-3)
(A1-4): Resin (A1-4)
(A1-5): Resin (A1-5)
(A2-1): Resin (A2-1)
(A2-X): Resin (A2-X)

### <Acid Generator (B)>

(B-1): Acid generator (B-1)
(B-2): Acid generator (B-2)
(B-3): Acid generator (B-3)
(B-X): Acid generator (B-X)

### <Quencher (C)>

(C-1): N,N-dicyclohexylmethylamine (Sigma-Aldrich Co. LLC)

### <Solvent (D)>

(D-1): Propylene glycol monomethyl ether acetate
(D-2): γ-butyrolactone
(D-3): n-butyl acetate
(D-4): propylene glycol monomethyl ether

### Examples 1 to 8 and Comparative Examples 1 to 4

### (KrF Exposure Evaluation of Resist Composition)

A 4-inch silicon wafer was treated with hexamethyldisilazane on a direct hot plate at 90° C. for 60 seconds. The resist composition was spin-coated on the silicon wafer such that the composition layer had a thickness of 16 μm. The wafer was then pre-baked on a direct hot plate at 150° C. for 90 seconds to form a composition layer. The composition layer formed on the wafer was exposed through a mask to form a trench pattern (trench width 3 μm) using a KrF excimer laser exposure machine [NSR-2250EX12B, manufactured by Nikon Corporation, NA=0.55, conventional, σ=0.80], with the exposure amount changed stepwise.

After exposure, the wafer was post-exposure baked on a hot plate at 120° C. for 90 seconds, and then paddle-developed with a 2.38% by mass tetramethylammonium hydroxide aqueous solution for 90 seconds to provide a resist pattern.

The resist pattern obtained after development was observed with a scanning electron microscope, and the exposure dose at which a 3 μm width trench pattern was obtained was determined to be the effective sensitivity.

### <Resolution Evaluation>

The resist patterns obtained at the effective sensitivity were observed with a scanning electron microscope. Those that could not form a 3 μm trench pattern were marked with an “x”, those that could form a 3 μm trench pattern but left residues were marked with a “Δ”, and those that left no residues were marked with a “◯”.

### <Shape Evaluation>

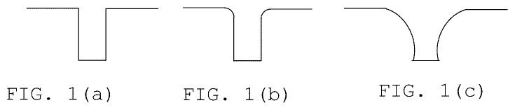

The 3 μm trench patterns obtained at the effective sensitivity were observed with a scanning electron microscope. Those with a top shape and bottom shape close to a rectangle and in favorable condition [FIG. 1(a)] were marked with a “⊙”, those with a round top [FIG. 1(b)] were marked with a “◯”, and those with a round top and a notch at the bottom [FIG. 1(c)] were marked with a “x”. The results are shown in Table 2.

### <Crack Evaluation>

The patterned silicon wafer obtained after development was visually checked for the presence or absence of cracks. Those without cracks were marked with a “◯”, and those in which cracks were confirmed to have occurred were marked with a “x”.

TABLE 2

| | Resist composition | Resolution | Shape | Crack |
|---|---|---|---|---|
| Example 1 | Composition 1 | ◯ | ◯ | ◯ |
| Example 2 | Composition 2 | ◯ | ◯ | ◯ |
| Example 3 | Composition 3 | ◯ | ◯ | ◯ |
| Example 4 | Composition 4 | ◯ | ⊙ | ◯ |
| Example 5 | Composition 5 | ◯ | ◯ | ◯ |
| Example 6 | Composition 6 | ◯ | ⊙ | ◯ |
| Example 7 | Composition 7 | ◯ | ◯ | ◯ |
| Example 8 | Composition 8 | ◯ | ⊙ | ◯ |
| Comparative | Comparative Example | X | — | — |
| Example 1 | composition 1 | | | |
| Comparative | Comparative Example | Δ | ◯ | ◯ |
| Example 2 | composition 2 | | | |
| Comparative | Comparative Example | ◯ | ◯ | X |
| Example 3 | composition 3 | | | |
| Comparative | Comparative Example | ◯ | X | X |
| Example 4 | composition 4 | | | |

### INDUSTRIAL APPLICABILITY

The resist composition of the present invention allows production of resist patterns with excellent resolution, favorable shape, and resistance to cracking, and is suitable for semiconductor microfabrication and extremely useful industrially.

1. A resist composition comprising:
resin (A) including a structural unit having an acid labile group and acid generator (B) represented by formula (b1),
wherein
the resin (A) is a resist composition including resin (A1) and resin (A2),
the resin (A1) is resin including a structural unit represented by formula (a1-1) and a structural unit represented by formula (a2-2), but not including a structural unit represented by formula (a1-2) or a structural unit represented by formula (a2-1),
the resin (A2) is resin including a structural unit represented by formula (a1-1) and a structural unit represented by formula (a2-1), but not including a structural unit represented by formula (a1-2), 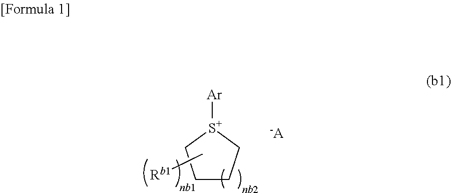
wherein
R^{b1} represents a hydroxy group or a hydrocarbon group having 1 to 12 carbon atoms, and —CH₂— included in the hydrocarbon group is optionally replaced with —O— or —CO—,
Ar represents an aromatic hydrocarbon group having 6 to 18 carbon atoms and optionally having a substituent,
—CH₂— included in a ring constituting a cation is optionally replaced with —O—, —S—, or —CO—,
nb1 represents an integer of 0 to 3 and when nb1 is 2 or more, a plurality of R^{b1}s are the same or different,
nb2 represents an integer of 1 to 3,
A⁻ represents a sulfonate anion, 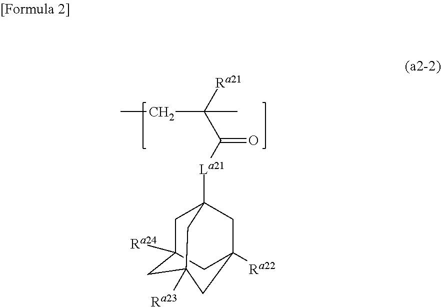
wherein
R^{a21} represents a hydrogen atom or a methyl group,
L^{a21} represents —O— or *—O—(CH₂)ₖ₀₁—CO—O—, k01 represents an integer of 1 to 7, and * represents a bonding site with —CO—,
R^{a22} represents a hydroxy group or a carboxy group,
R^{a23} and R^{a24} each independently represent a hydrogen atom, a methyl group, a hydroxy group, or a carboxy group, 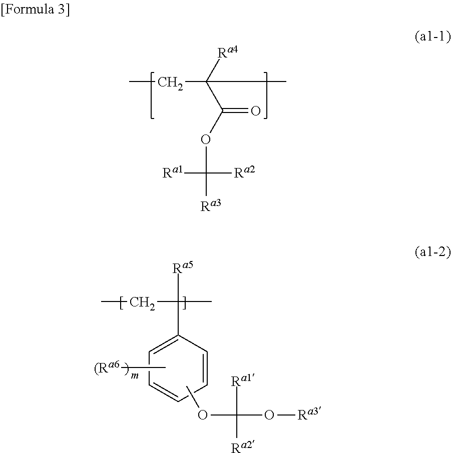
wherein
R^{a1}, R^{a2}, and R^{a3} each independently represent an alkyl group having 1 to 8 carbon atoms or an alicyclic hydrocarbon group having 3 to 20 carbon atoms, or Rai and R^{a2} are bonded to each other to form a ring having 3 to 20 carbon atoms together with carbon atoms to which they are bonded, and R^{a3} represents an alkyl group having 1 to 8 carbon atoms or an alicyclic hydrocarbon group having 3 to 20 carbon atoms,
R^{a1′} and R^{a2′} each independently represent a hydrogen atom or a hydrocarbon group having 1 to 20 carbon atoms, R^{a3′} represents a hydrocarbon group having 1 to 20 carbon atoms, or R^{a1′} represents a hydrogen atom or a hydrocarbon group having 1 to 20 carbon atoms, and R^{a2′} and R^{a3′} are bonded to each other to form a heterocycle having 3 to 20 carbon atoms together with carbon atoms and oxygen atoms to which they are bonded, the —CH₂— included in the hydrocarbon group having 1 to 20 carbon atoms and the heterocycle having 3 to 20 carbon atoms is optionally replaced with —O— or —S—,
L^{a01} represents —O— or *—O—(CH₂)ₖ₀₁—CO—O—, where k01 represents an integer of 1 to 7, and * represents a bonding site with —CO—,
R^{a4} and R^{a5} each independently represent a hydrogen atom or a methyl group,
R^{a6} represents an alkyl group having 1 to 6 carbon atoms or an alkoxy group having 1 to 6 carbon atoms,
m represents an integer of 0 to 4, and when m is 2 or more, a plurality of R^{a6}s are the same or different from each other, 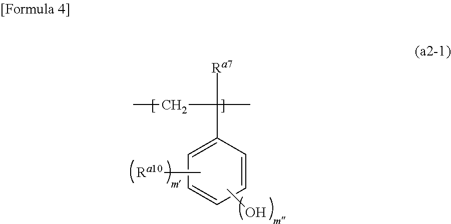
wherein
R^{a7} represents a hydrogen atom or a methyl group,
R^{a10} represents a hydroxy group, a carboxy group, an alkyl group having 1 to 6 carbon atoms, or an alkoxy group having 1 to 6 carbon atoms,
m′ represents an integer of 0 to 4, and when m′ is 2 or more, a plurality of R^{a10}s are the same or different from each other,
m″ represents an integer of 1 to 4, and
with the proviso that a total of m′ and m″ is 5 or less.

2. The resist composition according to claim 1, wherein A⁻ in formula (b1) is represented by formula (bA), 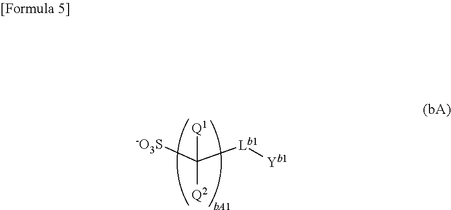
wherein
Q¹ and Q² each independently represent a hydrogen atom, a fluorine atom, an alkyl group having 1 to 6 carbon atoms, or a perfluoroalkyl group having 1 to 6 carbon atoms,
L^{b1} represents a saturated hydrocarbon group having 1 to 24 carbon atoms and optionally having a substituent, and —CH₂— included in the saturated hydrocarbon group is optionally replaced with —O— or —CO—,
Y^{b1} represents an aliphatic hydrocarbon group having 1 to 18 carbon atoms and optionally having a substituent, or an aromatic hydrocarbon group having 6 to 24 carbon atoms and optionally having a substituent, —CH₂— included in the aliphatic hydrocarbon group is optionally replaced with —O—, —S—, —CO—, or —SO₂—,
bA1 represents an integer of 1 to 6, and when bA1 is 2 or more, a plurality of groups in parentheses are the same or different from each other.

3. The resist composition according to claim 1, wherein a content of the resin (A1) is 40% by mass or more and 80% by mass or less with respect to a total amount of the resins.

4. A method for producing a resist pattern, comprising:
(1) a step of applying the resist composition according to any one of claims 1 to 3 onto a substrate;
(2) a step of drying the applied resist composition to form a composition layer;
(3) a step of exposing the composition layer;
(4) a step of heating the composition layer after exposure; and
(5) a step of developing the composition layer after heating.
